(19) United States
(12) Patent Application Publication
(10) Pub. No.: US 2026/0223405 A1
(43) Pub. Date: Jul. 30, 2026

(54) SEMICONDUCTOR DEVICE

(71) Applicant: Semiconductor Energy Laboratory Co., Ltd., Atsugi-shi, Kanagawa-ken (JP)

(72) Inventors: Yukinori SHIMA, Tatebayashi (JP); Masami JINTYOU, Shimotsuga (JP); Junichi KOEZUKA, Tochigi (JP); Hironori MATSUMOTO, Tochigi (JP); Masataka NAKADA, Tochigi (JP); Kanako KOJIMA, Atsugi (JP)

(21) Appl. No.: 19/146,947

(22) PCT Filed: Jan. 18, 2024
(86) PCT No.: PCT/IB2024/050467

§ 371 Date: Jul. 10, 2025

(30) Foreign Application Priority Data
Jan. 25, 2023 (JP) 2023-009139
Jan. 25, 2023 (JP) 2023-009141

(51) Int. Cl. H10D 30/67; G02F 1/1368; H10K 59/12; H10K 59/121

(52) U.S. Cl. CPC H10D 30/6755; G02F 1/1368; H10D 30/6728; H10D 30/6731; H10D 30/6757; H10K 59/1201; H10K 59/1213

(57) ABSTRACT

A transistor that can be miniaturized is provided. A transistor with reduced parasitic capacitance is provided. A semiconductor device includes a transistor and a first insulating layer. The transistor includes a first conductive layer, a second conductive layer, a third conductive layer, a semiconductor layer, and a second insulating layer. The first insulating layer is positioned over the first conductive layer and includes a first opening. The second conductive layer is positioned over the first insulating layer. The semiconductor layer includes a portion in contact with the first conductive layer, a portion in contact with the second conductive layer, and a portion in contact with a side surface of the first insulating layer inside the first opening. The second insulating layer covers the semiconductor layer in the first opening. The third conductive layer covers the second insulating layer in the first opening. The first conductive layer includes a portion overlapping with neither the third conductive layer nor the semiconductor layer in the first opening.

### TECHNICAL FIELD

One embodiment of the present invention relates to a semiconductor device and a manufacturing method thereof. One embodiment of the present invention relates to a transistor and a manufacturing method thereof. One embodiment of the present invention relates to a display device that includes a semiconductor device.

Note that one embodiment of the present invention is not limited to the above technical field. Examples of the technical field of one embodiment of the present invention disclosed in this specification and the like include a semiconductor device, a display device, a light-emitting apparatus, a power storage device, a memory device, an electronic device, a lighting device, an input device, an input/output device, a driving method thereof, and a manufacturing method thereof. A semiconductor device refers to any device that can function by utilizing semiconductor characteristics.

### BACKGROUND ART

Miniaturization of transistors has been required. For example, a display device in which a transistor occupies only a small area of a pixel can have downsized pixels, leading to high resolution. In addition, in such a display device, the number of transistors provided per unit area can be increased, that is, a large number of transistors can be provided in the pixel without increasing the pixel size, so that a correction function or the like can be added to the pixel, for example.

In recent years, the resolution of display panels has been increased. As a device that requires a high-resolution display panel, a device for virtual reality (VR) or augmented reality (AR) has been actively developed in recent years besides a tablet terminal, a smartphone, and a watch-type terminal. For a high-resolution display panel, a light-emitting element such as an organic electroluminescence (EL) element or a light-emitting diode (LED) is mainly used.

Patent Document 1 discloses a high-resolution display device that includes an organic EL device (also referred to as an organic EL element).

### REFERENCE

### Patent Document

[Patent Document 1] PCT International Publication No. 2016/038508

### SUMMARY OF THE INVENTION

### Problems to be Solved by the Invention

An object of one embodiment of the present invention is to provide a transistor that can be miniaturized. Another object is to provide a transistor having favorable electrical characteristics. Another object is to provide a transistor in which large amount of current can flow. Another object is to provide a transistor having an extremely short channel length. Another object is to provide a transistor with reduced parasitic capacitance. Another object is to provide a transistor that occupies a small area. Another object is to provide a display device that can easily achieve higher resolution. Another object is to provide a transistor, a semiconductor device, or a display device having high reliability.

An object of one embodiment of the present invention is to provide a semiconductor device, a display device, a memory device, or an electronic device that has a novel structure. An object of one embodiment of the present invention is to at least alleviate at least one of problems of the conventional technique.

Note that the description of these objects does not preclude the existence of other objects. One embodiment of the present invention does not necessarily achieve all these objects. Other objects can be derived from the description of the specification, the drawings, the claims, and the like.

### Means for Solving the Problems

One embodiment of the present invention is a semiconductor device including a transistor and a first insulating layer. The transistor includes a first conductive layer, a second conductive layer, a third conductive layer, a semiconductor layer, and a second insulating layer. The first insulating layer is positioned over the first conductive layer and includes a first opening. The second conductive layer is positioned over the first insulating layer. The semiconductor layer includes a portion in contact with the first conductive layer, a portion in contact with the second conductive layer, and a portion in contact with a side surface of the first insulating layer inside the first opening. The second insulating layer covers the semiconductor layer in the first opening. The third conductive layer covers the second insulating layer in the first opening. The semiconductor device includes a portion where the first conductive layer and the third conductive layer do not overlap with each other and the first conductive layer and the semiconductor layer do not overlap with each other in a region overlapping with the first opening.

One embodiment of the present invention is a semiconductor device including a transistor, a base insulating layer, and a first insulating layer. The transistor includes a first conductive layer, a second conductive layer, a third conductive layer, a semiconductor layer, and a second insulating layer. The first insulating layer is positioned over the first conductive layer and includes a first opening. The first conductive layer is positioned over the base insulating layer and includes a second opening. The second opening is positioned inside the first opening in the plan view. The second conductive layer is positioned over the first insulating layer. The semiconductor layer includes a portion in contact with the first conductive layer, a portion in contact with the second conductive layer, and a portion in contact with a side surface of the first insulating layer inside the first opening and includes a third opening positioned inside the first opening in a plan view. The second insulating layer includes a portion covering the semiconductor layer in the first opening and a portion in contact with the base insulating layer in a position overlapping with the second opening and the third opening. The third conductive layer covers the second insulating layer in the first opening.

In the above, it is preferable that the second opening be smaller than the third opening and be positioned inside the third opening in a plan view. Furthermore, the second insulating layer is preferably in contact with the top surface of the first conductive layer and the side surface of the first conductive layer in the second opening.

In the above, it is preferable that the third opening be smaller than the second opening and be positioned inside the second opening in a plan view. Furthermore, the semiconductor layer is preferably in contact with a top surface of the first conductive layer, a side surface of the first conductive layer in the second opening, and a base insulating layer.

One embodiment of the present invention is a semiconductor device including a transistor and a first insulating layer. The transistor includes a first conductive layer, a second conductive layer, a third conductive layer, a semiconductor layer, and a second insulating layer. The first insulating layer is positioned over the first conductive layer and includes a first opening. The second conductive layer is positioned over the first insulating layer. The semiconductor layer includes a portion in contact with the first conductive layer, a portion in contact with the second conductive layer, and a portion in contact with a side surface of the first insulating layer inside the first opening. The second insulating layer covers the semiconductor layer in the first opening. The third conductive layer covers the second insulating layer in the first opening and includes a second opening positioned inside the first opening in a plan view.

In the above, a third insulating layer over the second conductive layer is included. The third conductive layer preferably includes a portion overlapping with the second conductive layer with the third insulating layer provided therebetween. In that case, a fourth conductive layer is preferably included over the third insulating layer. It is preferable that the fourth conductive layer be electrically connected to the third conductive layer and has a function of a wiring.

In any of the above, an angle formed between the side surface of the first insulating layer in the first opening and the bottom surface of the first insulating layer is preferably greater than or equal to 75° and less than or equal to 90°.

In any of the above, it is preferable that the semiconductor layer include a metal oxide, the first insulating layer has a stacked-layer structure in which a first insulating film, a second insulating film, and a third insulating film are stacked in this order, the first insulating film and the third insulating film each include a nitride, and the second insulating film include an oxide. In that case, it is preferable that the first insulating film and the third insulating film include silicon nitride and the second insulating film include silicon oxide.

### Effect of the Invention

According to one embodiment of the present invention, a transistor that can be miniaturized can be provided. Alternatively, a transistor having favorable electrical characteristics can be provided. Alternatively, a transistor in which a large amount of current can flow can be provided. A transistor having an extremely small channel length can be provided. Alternatively, a transistor with reduced parasitic capacitance can be provided. Alternatively, a transistor that occupies a small area can be provided. Alternatively, a display device that can easily achieve higher resolution can be provided. Alternatively, a transistor, a semiconductor device, or a display device having high reliability can be provided.

According to one embodiment of the present invention, a semiconductor device, a display device, a memory device, or an electronic device that has a novel structure can be provided. According to one embodiment of the present invention, at least one of problems of the conventional technique can be at least alleviated.

Note that the description of these effects does not preclude the existence of other effects. One embodiment of the present invention does not need to have all these effects. Note that effects other than these can be derived from the description of the specification, the drawings, the claims, and the like.

### BRIEF DESCRIPTION OF THE DRAWINGS

FIG. 1A and FIG. 1B are diagrams illustrating a structure example of a semiconductor device.

FIG. 2A to FIG. 2C are diagrams illustrating a structure example of a semiconductor device.

FIG. 3A and FIG. 3B are diagrams illustrating a structure example of a semiconductor device.

FIG. 4A and FIG. 4B are diagrams illustrating structure examples of a semiconductor device.

FIG. 5A to FIG. 5C are diagrams illustrating structure examples of a semiconductor device.

FIG. 6 is a diagram illustrating a structure example of a semiconductor device.

FIG. 7A to FIG. 7C are diagrams illustrating structure examples of a semiconductor device.

FIG. 8A to FIG. 8D are diagrams illustrating a method for manufacturing a semiconductor device.

FIG. 9A and FIG. 9B are diagrams illustrating a structure example of a semiconductor device.

FIG. 10A to FIG. 10C are diagrams illustrating a structure example of a semiconductor device.

FIG. 11A and FIG. 11B are diagrams illustrating a structure example of a semiconductor device.

FIG. 12 is a diagram illustrating a structure example of a semiconductor device.

FIG. 13A to FIG. 13C are diagrams illustrating structure examples of a semiconductor device.

FIG. 14A and FIG. 14B are diagrams illustrating structure examples of a semiconductor device.

FIG. 15 is a diagram illustrating a structure example of a display device.

FIG. 16 is a diagram illustrating a structure example of a display device.

FIG. 17 is a diagram illustrating a structure example of a display device.

FIG. 18 is a diagram illustrating a structure example of a display device.

FIG. 19 is a diagram illustrating a structure example of a display device.

FIG. 20A to FIG. 20F are diagrams illustrating a method for manufacturing a display device.

FIG. 21A to FIG. 21D are diagrams illustrating structure examples of electronic devices.

FIG. 22A to FIG. 22F are diagrams illustrating structure examples of electronic devices.

FIG. 23A to FIG. 23G are diagrams illustrating structure examples of electronic devices.

### MODE FOR CARRYING OUT THE INVENTION

Embodiments will be described below with reference to the drawings. Note that the embodiments can be implemented with many different modes, and it will be readily understood by those skilled in the art that modes and details thereof can be changed in various ways without departing from the spirit and scope thereof. Therefore, the present invention should not be construed as being limited to the description of embodiments below.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

Note that in each drawing described in this specification, the size, the layer thickness, or the region of each component is exaggerated for clarity in some cases. Therefore, the size, the layer thickness, or the region is not limited to the illustrated scale.

Note that in this specification and the like, ordinal numbers such as “first” and “second” are used in order to avoid confusion among components and do not limit the number.

A transistor is a kind of semiconductor elements and can achieve a function of amplifying current or voltage, a switching operation for controlling conduction or non-conduction, and the like. An IGFET (Insulated Gate Field Effect Transistor) and a thin film transistor (TFT) are in the category of a transistor in this specification.

The functions of a “source” and a “drain” are sometimes replaced with each other when a transistor of different polarity is used or when the direction of current flow is changed in circuit operation, for example. Thus, the terms “source” and “drain” can be used interchangeably in this specification.

Note that in this specification and the like, the top-view shape of a component means the shape of the outline of the component in a plan view. A plan view means a view to observe the component from a normal direction of a surface where the component is formed or from a normal direction of a surface of a support (e.g., a substrate) where the component is formed.

In this specification and the like, the expression “having substantially the same top-view shapes” means that the outlines of stacked layers at least partly overlap with each other. For example, the case of processing an upper layer and a lower layer with the use of the same mask pattern or mask patterns that are partly the same is included. The expression “having substantially the same top surface shapes” also sometimes includes the case where the outlines do not completely overlap with each other; for instance, the edge of the upper layer may be positioned on the inner side or the outer side of the edge of the lower layer.

Note that the expressions indicating directions such as “over” and “under” are basically used to correspond to the directions of drawings. However, in some cases, the direction indicating “over” or “under” in the specification does not correspond to the direction in the drawings for the purpose of description simplicity or the like. For example, when a stacking order (or a formation order) of a stacked body or the like is described, even in the case where a surface on which the stacked body is provided (e.g., a formation surface, a support surface, an adhesion surface, or a planar surface) is positioned above the stacked body in the drawings, the following expressions are used in some cases: the formation surface is positioned below the stacked body or the stacked body is positioned above the formation surface.

In this specification and the like, the term “film” and the term “layer” can be interchanged with each other. For example, in some cases, the term “insulating layer” can be interchanged with the term “insulating film”.

In this specification and the like, a display panel that is one embodiment of a display device has a function of displaying (outputting) an image or the like on (to) a display surface. Therefore, the display panel is one embodiment of an output device.

In this specification and the like, a structure where a connector such as an FPC(Flexible Printed Circuit) or a TCP (Tape Carrier Package) is attached to a substrate of a display panel, or a structure where an IC is mounted on the substrate by a COG (Chip On Glass) method or the like is referred to as a display panel module or a display module, or simply as a display panel or the like in some cases.

Note that in this specification and the like, a touch panel that is one embodiment of a display device has a function of displaying an image or the like on a display surface and a function of a touch sensor capable of detecting the contact, press, approach, or the like of a sensing target such as a finger or a stylus with or to the display surface. Thus, the touch panel is one embodiment of an input/output device.

A touch panel can also be referred to as, for example, a display panel (or a display device) with a touch sensor, or a display panel (or a display device) having a touch sensor function. A touch panel can include a display panel and a touch sensor panel. Alternatively, a touch panel can have a function of a touch sensor in the display panel or on the surface of the display panel.

In this specification and the like, a structure in which a connector or an IC is mounted on a substrate of a touch panel is referred to as a touch panel module or a display module, or simply as a touch panel or the like in some cases.

### Embodiment 1

In this embodiment, a semiconductor device of one embodiment of the present invention is described. As examples of the semiconductor device, structure examples of a transistor and examples of a manufacturing method thereof will be described below.

The transistor of one embodiment of the present invention includes a semiconductor layer, a gate insulating layer, a gate electrode, a first electrode, and a second electrode. The first electrode functions as one of a source electrode and a drain electrode, and the second electrode functions as the other.

The second electrode is provided over the first electrode. Between the first electrode and the second electrode, an insulating layer functioning as a spacer is provided. An opening reaching the first electrode is provided in the spacer, and the semiconductor layer is provided in contact with the first electrode, the second electrode, and a side wall (also referred to as a side surface) of the insulating layer in the opening. The gate insulating layer and the gate electrode are provided to cover the semiconductor layer.

In the transistor having the above structure, the source electrode and the drain electrode are positioned at different heights, so that the current flowing through the semiconductor layer flows in the height direction. In other words, the channel length direction can be regarded as having a component of the height direction (the vertical direction); accordingly, the transistor of one embodiment of the present invention can also be referred to as a VFET (Vertical Field Effect Transistor), a vertical transistor, a vertical-channel transistor, and the like. Since the transistor can be provided with two or more of the source electrode, the semiconductor layer, and the drain electrode provided to overlap with each other, the area occupied by the transistor can be significantly reduced as compared with that occupied by what is called a planar transistor (also referred to as a lateral transistor, an LFET (Lateral FET), or the like) in which a semiconductor layer is positioned over a flat plane.

A display device employing the above-described vertical transistor can reduce the area occupied by transistors as compared to a display device including a conventional lateral transistor, and accordingly achieves a smaller pixel, more multi-functional pixels, and a higher aperture ratio, for example. Accordingly, the display device can achieve higher resolution, higher reliability lower power consumption, and the like than a conventional display device.

Here, it is preferable that capacitance between the source electrode and the gate electrode or between the drain electrode and the gate electrode be as small as possible because the speed of switching operation of the transistor can be increased. Thus, capacitance between the gate electrode and the first electrode at the bottom portion of the opening in the insulating layer functioning as the spacer is focused on. In one embodiment of the present invention, a region where the gate electrode and the first electrode do not overlap with each other is provided at the bottom portion of the opening in the insulating layer.

Furthermore, in the case where part of the semiconductor layer positioned at the bottom portion of the opening in the insulating layer functions as a source region or a drain region, capacitance can be formed not only between the first electrode and the gate electrode but also between the semiconductor layer and the gate electrode. Thus, a region where the gate electrode and the semiconductor layer do not overlap with each other is provided at the bottom portion of the opening in the insulating layer.

More specifically, for example, the first electrode includes a second opening positioned inside the opening (first opening) in the insulating layer functioning as the spacer in a plan view. Furthermore, the semiconductor layer has a structure including a third opening positioned inside the first opening in a plan view. The second opening and the third opening partly overlap with each other. Thus, in the first opening, a portion where the second opening and the third opening overlap with each other corresponds to a portion where the gate electrode overlaps with neither the first electrode nor the semiconductor layer. Thus, the capacitance between the gate electrode and the first electrode can be reduced as compared with the case where neither the second opening nor the third opening is provided.

More specific structure examples are described below with reference to drawings.

### Structure Example

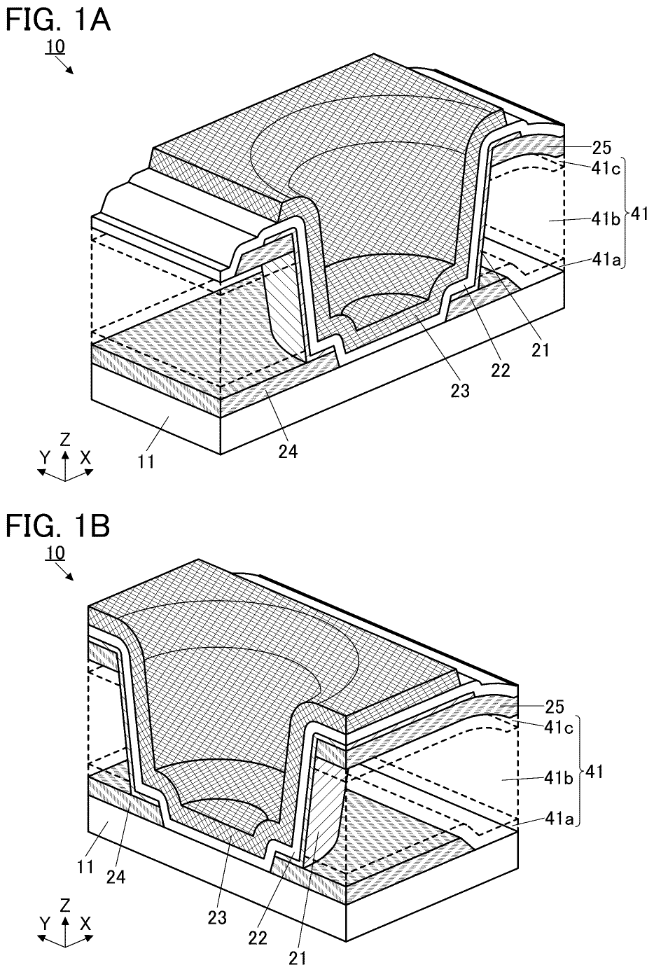

FIG. 1A and FIG. 1B illustrate schematic perspective views of a transistor 10. In FIG. 1A and FIG. 1B, directions X, Y, and Z are indicated by arrows. FIG. 1A is a perspective view including a cross section of the transistor 10 cut along the X-Z plane, and FIG. 1B is a perspective view including a cross section of the transistor 10 cut along the Y-Z plane.

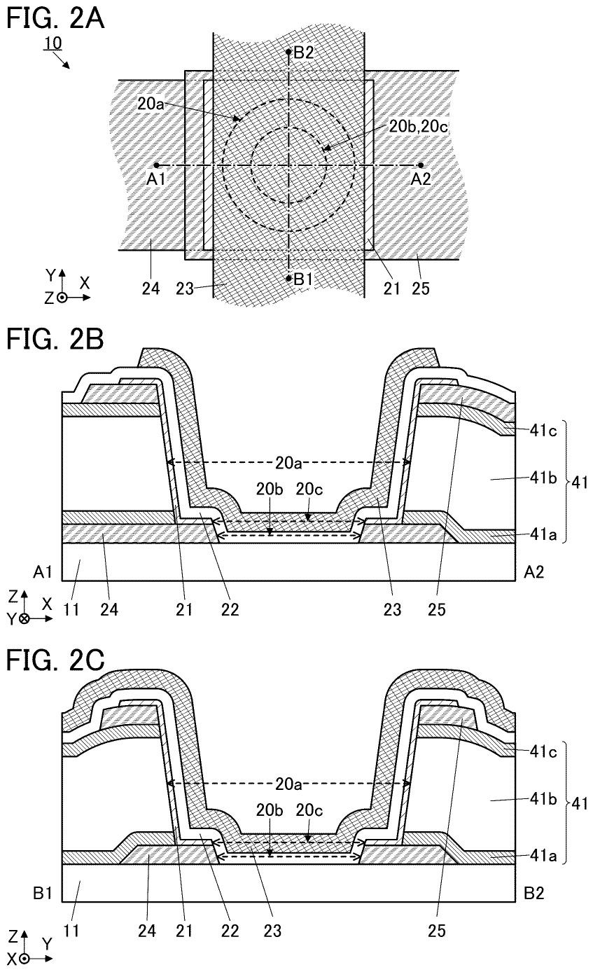

FIG. 2A is a plan view of the transistor 10, and FIG. 2B and FIG. 2C are schematic cross-sectional views along the cutting line A1-A2 and the cutting line B1-B2, respectively, in FIG. 2A. Note that some components (e.g., insulating layers) are omitted in FIG. 2A.

The transistor 10 is provided over an insulating layer 11 provided over a substrate (not illustrated). The insulating layer 11 functions as a base insulating layer. The transistor 10 includes a semiconductor layer 21, an insulating layer 22 partly functioning as a gate insulating layer, a conductive layer 23 partly serving as a gate electrode, a conductive layer 24 partly serving as one of a source electrode and a drain electrode, and a conductive layer 25 partly serving as the other of the source electrode and the drain electrode.

The conductive layer 24 is provided over the insulating layer 11, and an insulating layer 41 is provided over the conductive layer 24. The conductive layer 25 is provided over the insulating layer 41. The insulating layer 41 has an opening 20a reaching the conductive layer 24. The conductive layer 24 includes an opening 20b. The opening 20b is positioned inside the opening 20a in a plan view.

The semiconductor layer 21 includes a portion in contact with the top surface of the conductive layer 25, a portion in contact with a side surface of the conductive layer 25, a portion in contact with the side surface (also referred to as an inner wall or a sidewall) of the insulating layer 41 in the opening 20a, and a portion in contact with a top surface of the conductive layer 24. The semiconductor layer 21 includes an opening 20c. The opening 20c is positioned inside the opening 20a in a plan view. Here, the case where the opening 20b and the opening 20c have substantially the same top-view shapes is illustrated.

The insulating layer 22 is provided to cover the insulating layer 41, the conductive layer 25, the semiconductor layer 21, the conductive layer 24, and the insulating layer 11. A portion of the insulating layer 22 positioned inside the opening 20a is provided along the top surface of the semiconductor layer 21. A portion of the insulating layer 22 positioned inside the opening 20c and the opening 20b is in contact with a side surface (also referred to as an inner wall or a sidewall) of the conductive layer 24 and the top surface of the insulating layer 11.

The conductive layer 23 is provided to cover the insulating layer 22. In this case, since the conductive layer 24 and the semiconductor layer 21 include the opening 20b and the opening 20c, respectively, which are positioned inside the opening 20a, the conductive layer 23 can include a portion overlapping with neither the conductive layer 24 nor the semiconductor layer 21 inside the opening 20a. Thus, capacitance (also referred to as parasitic capacitance) between the conductive layer 23 and the conductive layer 24 can be reduced.

Moreover, since the channel length of the transistor 10 can be precisely controlled by the thickness of the insulating layer 41, a variation in the channel length can be made extremely reduced as compared with that of a planar transistor. Furthermore, by reducing the thickness of the insulating layer 41, a transistor with an extremely short channel length can be manufactured. For example, a transistor with a channel length of less than or equal to 2 μm, less than or equal to 1 μm, less than or equal to 500 nm, less than or equal to 300 nm, less than or equal to 200 nm, less than or equal to 100 nm, less than or equal to 50 nm, less than or equal to 30 nm, or less than or equal to 20 nm and greater than or equal to 5 nm, greater than or equal to 7 nm, or greater than or equal to 10 nm can be manufactured. Thus, it is possible to obtain a transistor with an extremely short channel length that could not be obtained with the use of a conventional light-exposure apparatus for mass production of flat panel displays (the minimum line width: approximately 2 μm or approximately 1.5 μm, for example). Moreover, a transistor with a channel length of less than 10 nm can also be achieved without using an extremely expensive light-exposure apparatus used in the latest LSI technology.

A variety of semiconductor materials can be used for the semiconductor layer 21; in particular, an oxide semiconductor including a metal oxide is preferably used. The use of an oxide semiconductor formed under an appropriate condition allows a transistor having both a high on-state current and an extremely low off-state current to be achieved at a low cost. Described below are preferable structure examples of the case where an oxide semiconductor is used for the semiconductor layer 21 unless otherwise specified.

Each of the top surfaces of the conductive layer 24 and the conductive layer 25 is in contact with the semiconductor layer 21. Hence, in the case where an oxide semiconductor is used for the semiconductor layer 21, the exposed surfaces of the conductive layer 24 and the conductive layer 25 and vicinities thereof might be oxidized by the effect of heat or the like generated in a formation step of a semiconductor film to be the semiconductor layer 21 or a later step, so that an insulating oxide film might be formed between the conductive layers 24 and 25 and the semiconductor layer 21, increasing the contact resistance. Thus, an oxide conductor including a conductive oxide is preferably used at least for the uppermost portions of the conductive layer 24 and the conductive layer 25. This can prevent an increase in the contact resistance due to the oxidation of the surfaces of the conductive layer 24 and the conductive layer 25. The conductive layer 24 and the conductive layer 25 can also be referred to as an oxide layer, a metal oxide layer, an oxide conductive layer, or the like.

Part of the conductive layer 24 can be used as one of a source wiring and a drain wiring. Part of the conductive layer 25 can be used as the other of the source wiring and the drain wiring. In the case where one or both of the conductive layer 24 and the conductive layer 25 are used as a wiring in this manner, they preferably have low electric resistance. Thus, a material having higher conductivity than an oxide conductor, such as a metal, an alloy, or a nitride thereof, is preferably used. One or both of the conductive layer 24 and the conductive layer 25 preferably have a stacked-layer structure including a layer of the material having high conductivity, where the above-described oxide conductor is preferably used at least for the uppermost part, in particular.

The transistor 10 is provided at the intersection of the conductive layer 23 serving as a gate wiring and the conductive layer 24 serving as the source wiring or the drain wiring. However, in one embodiment of the present invention, since the conductive layer 23 includes a portion overlapping with neither the conductive layer 24 nor the semiconductor layer 21 at the bottom portion of the opening 20a, the parasitic capacitance is significantly reduced as compared with the case where such a portion is not provided (e.g., the case where either the opening 20b or the opening 20c is not provided). The parasitic capacitance between the gate wiring and the source wiring or the drain wiring is small; thus, when the transistor is applied to a display device, effects such as increasing the frame frequency and definition can be obtained.

The insulating layer 41 functions as an interlayer insulating layer (spacer) which insulates the conductive layer 24 from the conductive layer 25. Here, the case where a stacked-layer film of an insulating layer 41a, an insulating layer 41b, and an insulating layer 41c is used as the insulating layer 41 is illustrated.

The semiconductor layer 21 is provided in contact with the inner wall of the opening 20a in the insulating layer 41b. An oxide insulating film is preferably used as the insulating layer 41b. Particularly, an oxide insulating film from which oxygen is released by heating is preferably used. Furthermore, the insulating layer 41b is preferably sandwiched between the insulating layers 41a and 41c having a barrier property against oxygen. This enables oxygen included in the insulating layer 41b to be enclosed in a region surrounded by the insulating layer 41a, the insulating layer 41c, and the semiconductor layer 21 and prevents oxygen in the insulating layer 41b from being released and decreased in the process, so that oxygen can be supplied to the semiconductor layer 21 more efficiently.

A part of the semiconductor layer 21 that is in contact with the insulating layer 41b is a region where oxygen vacancies are reduced, i.e., an i-type region. The other part of the semiconductor layer 21 that is not in contact with the insulating layer 41b is preferably an n-type region including a large amount of carriers. That is, the part of the semiconductor layer 21 that is in contact with the insulating layer 41b can be referred to as a channel formation region and regions of the outer side of the channel formation region can be referred to as low-resistance regions (or a source region or a drain region).

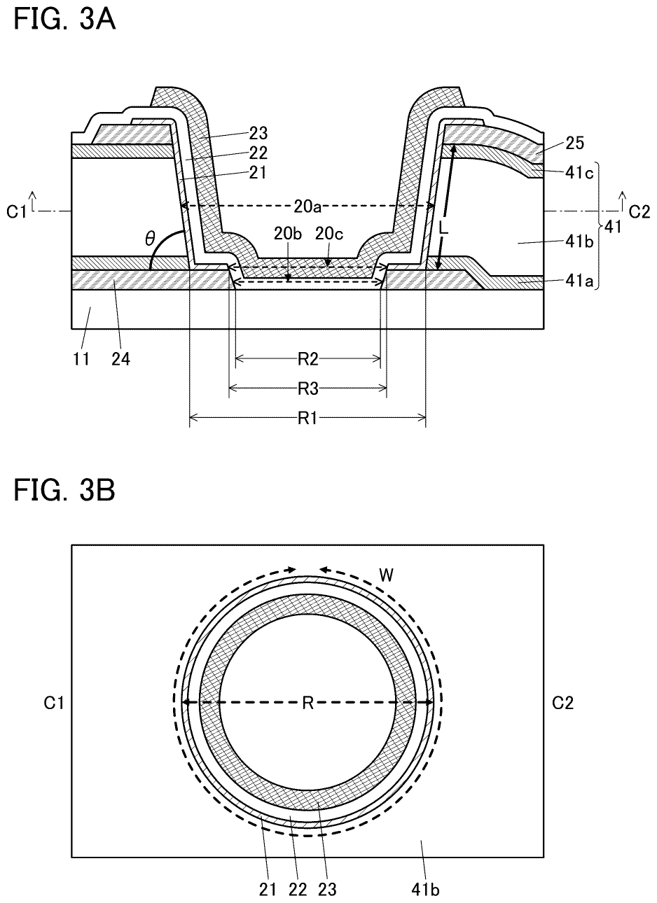

A channel length, a channel width, and the like are described with reference to FIG. 3A and FIG. 3B. FIG. 3A illustrates a schematic cross-sectional view similar to FIG. 2B.

A channel length L of the transistor 10 can be defined as, as illustrated in FIG. 3A, the length of a portion of the semiconductor layer 21 that is in contact with the insulating layer 41 on the shortest path connecting a portion in contact with the conductive layer 24 and a portion in contact with the conductive layer 25. When the opening 20a in the insulating layer 41 has a sidewall angle (θ) of 90°, the channel length L is equal to the thickness of the insulating layer 41. The channel length L can be larger than the thickness of the insulating layer 41 when 0 is smaller (or larger) than 90°. Note that although the channel region of the semiconductor layer 21 is a portion in contact with the insulating layer 41 here, the portion can be replaced with a portion in contact with the insulating layer 41b.

Diameters of the opening 20a, the opening 20b, and the opening 20c are denoted as R1, R2, and R3, respectively. As illustrated in FIG. 3A, a diameter at the lower end of each layer can serve as the diameter of the opening in each layer. Furthermore, in FIG. 3A, the end portions of the conductive layer 24 and the semiconductor layer 21 each have a tapered shape; thus, the diameter R3 of the opening 20c is larger than the diameter R2 of the opening 20b. Note that the diameter of the opening in a certain layer is not limited to the diameter at the lower end of the layer and may be the diameter of the upper end or the diameter of the center of the layer, or may be an average value or a median value.

Since the opening 20b and the opening 20c are positioned inside the opening 20a, the diameters R2 and R3 are each smaller than the diameter R1 of the opening 20a. The larger R2 and R3 are, the larger the area of the portion where the conductive layer 23 overlaps with neither the conductive layer 24 nor the semiconductor layer 21 is; thus, the effect of reducing the parasitic capacitance can be enhanced. For example, the diameter R2 of the opening 20b and the diameter R3 of the opening 20c are each independently greater than or equal to 50%, preferably greater than or equal to 60%, further preferably greater than or equal to 70%, still further preferably greater than or equal to 80%, yet still further preferably greater than or equal to 90% and less than 100% of the diameter R1 of the opening 20a.

A channel width W of the transistor 10 depends on the shape of the opening 20a. FIG. 3B is a plan view seen in the Z direction of a cross section along the cutting line C1-C2 positioned at a height where the insulating layer 41b is provided in FIG. 3A. Here, the case where the opening 20a has a circular shape in the plan view is illustrated. When the outline of the opening 20a is a circle with a diameter R, the channel width W can be regarded as the circumference of the opening 20a (i.e., π×R). Here, the circumference of the opening 20a varies with the height if the sidewall angle θ of the opening 20a in the insulating layer 41b shifts from 90°. In that case, the circumference at a height where the opening 20a has the minimum diameter (at the lower end here) can be regarded as the channel width W. Note that the circumference at a height of the upper end of the opening 20a may be regarded as the channel width W.

The shape of the opening 20a in a plan view can be typically a circular shape. However, the shape of the opening 20a is not limited to a circular shape and can be a variety of shapes. Besides the circular shape, for example, an elliptical shape or a quadrangular shape with rounded corners can be employed. Alternatively, a regular polygonal shape such as a regular triangular shape, a square shape, or a regular pentagonal shape or a polygonal shape other than the regular polygonal shape may be employed. By employing a concave polygonal shape in which at least one interior angle is greater than 180°, such as a star polygonal shape, the channel width can be increased. Alternatively, an elliptical shape, a polygonal shape with rounded corners, a closed curve in which a straight line and a curve are combined, or the like can be employed.

There is no limitation on the shape of the opening 20b and the opening 20c as long as the opening 20b and the opening 20c are positioned inside the opening 20a regardless of the shape of the opening 20a. However, it is preferable that the shape of the opening 20b and the opening 20c be similar or close to the shape of the opening 20a, in which case a difference between the area of the opening 20a and the area of the opening 20b or the opening 20c can be reduced, resulting in a reduction in the area of the opening 20a itself.

Since the semiconductor layer 21 and the insulating layer 22 are formed along the inner wall of the opening 20a in the insulating layer 41b, the thicknesses of the layers are sometimes reduced in the opening 20a by some film formation methods. For example, with a film formation method such as a sputtering method or a plasma CVD method used, a film deposited on a surface inclined or perpendicular to a substrate surface tends to be thinner than a film deposited on a surface parallel to the substrate surface. By contrast, a film formation method such as an atomic layer deposition (ALD) method or a thermal CVD method allows a film with a uniform thickness to be formed on a surface with any angle. The semiconductor layer 21 and the insulating layer 22 are preferably formed by an ALD method when the opening 20a in the insulating layer 41b has a sidewall angle θ of greater than or equal to 75°, greater than or equal to 80°, or greater than or equal to 85°, for example.

### [Components]

### <Substrate>

As a substrate where the transistor is formed, an insulator substrate, a semiconductor substrate, or a conductor substrate is used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate including silicon carbide, silicon germanium, gallium arsenide, indium phosphide, zinc oxide, gallium oxide, or gallium nitride. Another example is a semiconductor substrate having an insulator region in the semiconductor substrate described above, e.g., an SOI (Silicon On Insulator) substrate. Examples of the conductor substrate include a graphite substrate, a metal substrate, an alloy substrate, and a conductive resin substrate. Alternatively, a substrate including a nitride of a metal and a substrate including an oxide of a metal can be used. Other examples include an insulator substrate provided with a conductive layer or a semiconductor, a semiconductor substrate provided with a conductive layer or an insulating layer, and a conductor substrate provided with a semiconductor layer or an insulating layer. Alternatively, these substrates provided with elements may be used. Examples of the element provided for the substrate include a capacitor, a resistor, a switching element (including a transistor), a light-emitting element, and a memory element.

### <Semiconductor Layer>

The semiconductor layer 21 preferably includes a metal oxide (an oxide semiconductor).

Examples of the metal oxide that can be used for the semiconductor layer 21 include In oxide, Ga oxide, and Zn oxide. The metal oxide preferably contains at least In or Zn. The metal oxide preferably contains two or three selected from In, an element M, and Zn. Note that the element M is a metal element or a metalloid element that has a high binding energy with oxygen, such as a metal element or a metalloid element whose binding energy with oxygen is higher than that of indium, for example. Specific examples of the element M include Al, Ga, Sn, Y, Ti, V, Cr, Mn, Fe, Co, Ni, Zr, Mo, Hf, Ta, W, La, Ce, Nd, Mg, Ca, Sr, Ba, B, Si, Ge, and Sb. The element M included in the metal oxide is preferably one or more kinds of the above elements, and specifically, the element Mis preferably one or more kinds selected from Al, Ga, Y, and Sn, and is further preferably Ga. Hereinafter, a metal oxide containing In, M, and Zn is referred to as In-M-Zn oxide in some cases. In this specification and the like, a metal element and a metalloid element may be collectively referred to as a “metal element”, and a “metal element” in this specification and the like may refer to a metalloid element.

When the metal oxide is an In-M-Zn oxide, the proportion of the number of In atoms is preferably higher than or equal to that of the number of M atoms in the In-M-Zn oxide. Examples of the atomic ratio of the metal elements of such In-M-Zn oxide include In:M:Zn=1:1:1, In:M:Zn=1:1:1.2, In:M:Zn=2:1:3, In:M:Zn=3:1:2, In:M:Zn=4:2:3, In:M:Zn=4:2:4.1,In:M:Zn=5:1:3, In:M:Zn=5:1:6, In:M:Zn=5:1:7, In:M:Zn=5:1:8, In:M:Zn =6:1:6, and In:M:Zn=5:2:5 or a composition in the neighborhood thereof. Note that a composition in the neighborhood includes the range of ±30% of an intended atomic ratio. By increasing the atomic proportion of indium in the metal oxide, the on-state current, field-effect mobility, or the like of the transistor can be increased.

The proportion of the number of In atoms may be less than that of the number of M atoms in the In-M-Zn oxide. Examples of the atomic ratio of the metal elements in such an In-M-Zn oxide include In:M:Zn=1:3:2, In:M:Zn=1:3:3, In:M:Zn=1:3:4 or a composition in the neighborhood thereof. By increasing the atomic ratio of M in the metal oxide, generation of oxygen vacancies can be inhibited.

For the semiconductor layer 21, for example, In oxide, In—Zn oxide, In—Ga oxide, In—Sn oxide, In—Ti oxide, In—Ga—Al oxide, In—Ga—Sn oxide, In—Ga—Zn oxide, In—Sn—Zn oxide, In—Al—Zn oxide, In—Ti—Zn oxide, In—Ga—Sn—Zn oxide, or In—Ga—Al—Zn oxide can be used. Alternatively, Ga—Zn oxide may be used. A material that does not contain Zn like indium oxide is preferred in that it improves the compatibility with an LSI manufacturing process. By contrast, a material that contains Zn is preferred in that crystallinity can be easily increased.

Note that the metal oxide may contain, instead of or in addition to indium, one or more kinds of metal elements belonging to a period of a higher number in the periodic table. The larger the overlap between orbits of metal elements is, the more likely it is that the metal oxide will have high carrier conductivity. Thus, a transistor containing a metal element with a large period number can have high field-effect mobility in some cases. Examples of the metal element with a large period number include metal elements belonging to Period 5 and metal elements belonging to Period 6. Specific examples of the metal elements include Y, Zr, Ag, Cd, Sn, Sb, Ba, Pb, Bi, La, Ce, Pr, Nd, Pm, Sm, and Eu. Note that La, Ce, Pr, Nd, Pm, Sm, and Eu are referred to as light rare earth elements.

The metal oxide may contain one or more kinds of nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

A sputtering method or an atomic layer deposition (ALD) method can be suitably used to form the metal oxide. In particular, a film of the metal oxide is preferably formed by an ALD method, which enables good coverage. Note that in the case where the metal oxide is formed by a sputtering method, the composition of the deposited metal oxide may be different from the composition of a target. In particular, the content of the zinc in the deposited metal oxide may be reduced to approximately 50% of that of the target.

In this specification and the like, the content of a certain metal element in the metal oxide refers to the ratio of the number of atoms of the element to the total number of atoms of metal elements contained in the metal oxide. In the case where a metal oxide contains a metal element X, a metal element Y, and a metal element Z whose atomic numbers are respectively represented by A_{X}, A_{Y}, and A_{Z}, the content of the metal element X can be represented by A_{X}/(A_{X}+A_{Y}+A_{Z}). Moreover, in the case where the atomic ratio of the metal element X, the metal element Y, and the metal element Z contained in the metal oxide is represented by B_{X}:B_{Y}:B_{Z}, the content ratio of the metal element X can be represented by B_{X}/(B_{X}+B_{Y}+B_{Z}).

For example, in the case of the metal oxide containing In, higher content of In enables the transistor to have high on-state current.

With use of a metal oxide that does not contain Ga or has low Ga content in the semiconductor layer 21, the transistor can be highly reliable against positive bias application. That is, the amount of change in the threshold voltage of the transistor in the PBTS (positive bias temperature stress) test can be small. Meanwhile, with use of a metal oxide that contains Ga, the Ga content is preferably lower than the In content. Thus, the transistor with high mobility and high reliability can be achieved.

Meanwhile, the high content of Ga enables the transistor to be highly reliable against light. That is, the amount of change in the threshold voltage of the transistor in the NBTIS (negative bias temperature illumination stress) test can be small. Specifically, in a metal oxide in which the atomic ratio of Ga is higher than or equal to that of In, the band gap is increased and accordingly the amount of change in the threshold voltage of the transistor in the NBTIS test can be reduced.

Furthermore, a metal oxide having a high zinc content has high crystallinity whereby diffusion of impurities can be inhibited. Consequently, a change in electrical characteristics of the transistor can be inhibited, and the reliability of the transistor can be increased.

The semiconductor layer 21 may have a stacked-layer structure of two or more metal oxide layers. The two or more metal oxide layers included in the semiconductor layer 21 may have the same composition or substantially the same compositions. Employing a stacked-layer structure of metal oxide layers having the same composition can reduce the manufacturing cost because the metal oxide layers can be formed using the same sputtering target. Note that a stacked-layer structure including two or more oxide semiconductor layers having different compositions may be employed. The use of an ALD method can form a metal oxide layer with a composition that continuously changes in the thickness direction. This not only increases the range of choices for design without need for use of a film with a predetermined composition but also prevents generation of an interface state or the like between two layers with different compositions; thus, the electrical characteristics and reliability can be improved.

In the case where the semiconductor layer 21 has a two-layer structure, the second layer, i.e., the layer closer to the gate electrode, preferably includes a material with higher mobility (higher conductivity) than the first layer. This structure enables the transistor to have normally-off characteristics and a high on-state current. Consequently, both low power consumption and high performance can be achieved. Alternatively, the first layer, i.e., the layer in contact with the source electrode and the drain electrode, may include a material having higher mobility than the second layer. In that case, contact resistance between the semiconductor layer 21 and the source electrode or the drain electrode can be reduced and the parasitic resistance can be reduced accordingly, so that the transistor can have a high on-state current.

In the case where the semiconductor layer 21 has a three-layer structure, the second layer preferably includes a material having higher mobility than the first layer and the third layer. Accordingly, a transistor having a high on-state current and high reliability can be obtained.

The above-described differences in mobility and conductivity can be replaced with a difference in the indium content percentage, for example. In addition, the mobility and the conductivity are affected by whether or not an element that contributes to an improvement in conductivity is contained in addition to indium, by the content of the element, or the like. Examples of the high-mobility material include a material having an atomic ratio of In:Ga:Zn=4:3:2 or in the neighborhood thereof, a material having an atomic ratio of In:Zn=1:1 or in the neighborhood thereof, a material having an atomic ratio of In:Zn=4:1 or in the neighborhood thereof, and a material having an atomic ratio of In:Sn:Zn=40:X:10 (X is greater than or equal to 0.1 and less than or equal to 5, typically X=1) or in the neighborhood thereof. Examples of a material having lower mobility or conductivity than the above-described materials include a material having an atomic ratio of In:Ga:Zn=1:3:2 or in the neighborhood thereof, a material having an atomic ratio of In:Ga:Zn=1:3:4 or in the neighborhood thereof, a material having an atomic ratio of In:Ga:Zn=2:2:1 or in the neighborhood thereof, a material having an atomic ratio of In:Ga:Zn=1:1:1 or in the neighborhood thereof, and a material having an atomic ratio of In:Ga:Zn=1:1:2 or in the neighborhood thereof.

It is preferable to use a metal oxide layer having crystallinity as the semiconductor layer 21. For example, a metal oxide layer having a CAAC (c-axis aligned crystal) structure, a polycrystalline structure, a nano-crystal (nc) structure, or the like can be used. With the use of the metal oxide layer having crystallinity as the semiconductor layer 21, the density of defect states in the semiconductor layer 21 can be reduced, which enables the semiconductor device to have high reliability.

The higher the crystallinity of the metal oxide layer used as the semiconductor layer 21 is, the lower the density of defect states in the semiconductor layer 21 can be. By contrast, the use of a metal oxide layer having low crystallinity achieves a transistor through which a large amount of current can flow.

A transistor including an oxide semiconductor (hereinafter referred to as an OS transistor) has much higher field-effect mobility than a transistor including amorphous silicon. In addition, the OS transistor has an extremely low leakage current between a source and a drain in an off state (hereinafter also referred to as off-state current), and charge accumulated in a capacitance that is connected in series with the transistor can be held for a long period. Furthermore, the power consumption of the semiconductor device can be reduced with the OS transistor.

The semiconductor device of one embodiment of the present invention can be used for a display device, for example. To increase the emission luminance of a light-emitting device included in a pixel circuit in the display device, it is necessary to increase the amount of current flowing through the light-emitting device. To increase the amount of current, the source-drain voltage of a driving transistor included in the pixel circuit needs to be increased. Since the OS transistor has a higher withstand voltage between a source and a drain than a transistor using silicon (hereinafter, referred to as a Si transistor), a high voltage can be applied between the source and the drain of the OS transistor. Accordingly, when an OS transistor is used as the driving transistor included in the pixel circuit, the amount of current flowing through the light-emitting device can be increased, so that the emission luminance of the light-emitting device can be increased.

When a transistor operates in a saturation region, a change in source-drain current relative to a change in gate-source voltage can be smaller in an OS transistor than in a Si transistor. Accordingly, when an OS transistor is used as the driving transistor included in the pixel circuit, the amount of current flowing through the light-emitting device can be precisely controlled. Consequently, the number of gray levels in the pixel circuit can be increased. Moreover, current can be made flow stably even when the electrical characteristics (e.g., resistance) in the light-emitting device change or the electrical characteristics in the light-emitting device vary.

As described above, by using an OS transistor as the driving transistor included in the pixel circuit, it is possible to achieve “inhibition of black floating”, “increase in emission luminance”, “increase in the number of gray levels”, “inhibition of influence of a manufacturing variation in light-emitting devices”, and the like.

A change in electrical characteristics of an OS transistor due to radiation irradiation is small, i.e., an OS transistor has high tolerance to radiation; thus, an OS transistor can be suitably used even in an environment where radiation can enter. It can also be said that an OS transistor has high reliability against radiation. For example, an OS transistor can be suitably used for a pixel circuit of an X-ray flat panel detector. Moreover, an OS transistor can be suitably used for a semiconductor device used in space. Examples of radiation include electromagnetic radiation (e.g., X-rays and gamma rays) and particle radiation (e.g., alpha rays, beta rays, a proton beam, and a neutron beam).

Note that the semiconductor material that can be used for the semiconductor layer 21 is not limited to the oxide semiconductor. For example, a single-element semiconductor or a compound semiconductor can be used. Examples of the single-element semiconductor include silicon (such as single crystal silicon, polycrystalline silicon, microcrystalline silicon, and amorphous silicon) and germanium. Examples of the compound semiconductor include an organic semiconductor, a nitride semiconductor, and an oxide semiconductor. These semiconductor materials may include an impurity as a dopant.

Alternatively, the semiconductor layer 21 may contain a layered substance that functions as a semiconductor. The layered substance is a general term of a group of materials having a layered crystal structure. The layered crystal structure is a structure in which layers formed by covalent bonding or ionic bonding are stacked with bonding such as the Van der Waals bonding, which is weaker than covalent bonding or ionic bonding. The layered material has high electrical conductivity in a unit layer, that is, high two-dimensional electrical conductivity. When a material that functions as a semiconductor and has high two-dimensional electrical conductivity is used for a channel formation region, a transistor having a high on-state current can be provided.

Examples of the layered substances include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide which can be used for a semiconductor layer of a transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

There is no particular limitation on the crystallinity of a semiconductor material used for the semiconductor layer 21, and any of an amorphous semiconductor, a single crystal semiconductor, and a semiconductor having crystallinity other than single crystal (a polycrystalline semiconductor, a microcrystalline semiconductor, or a semiconductor partly including crystal regions) may be used. A semiconductor having crystallinity is preferably used, in which case degradation of the transistor characteristics can be inhibited.

### <Gate Insulating Layer>

The insulating layer 22 functions as a gate insulating layer of the transistor and can also be used as a dielectric layer of a capacitor. In the case where the semiconductor layer 21 is formed using an oxide semiconductor, an oxide insulating film is preferably used as at least a film of the insulating layer 22 that is in contact with the semiconductor layer 21. For example, one or more of silicon oxide, silicon oxynitride, aluminum oxide, aluminum oxynitride, hafnium oxide, hafnium oxynitride, gallium oxide, gallium oxynitride, yttrium oxide, yttrium oxynitride, and Ga—Zn oxide can be used. In addition, as the insulating layer 22, a nitride insulating film of silicon nitride, silicon nitride oxide, aluminum nitride, or aluminum nitride oxide can also be used. The insulating layer 22 may also have a stacked-layer structure, e.g., a stacked-layer structure including at least one oxide insulating film and at least one nitride insulating film.

Note that in this specification and the like, an oxynitride refers to a material that contains more oxygen than nitrogen. A nitride oxide refers to a material that contains more nitrogen than oxygen.

It is preferable for the insulating layer 22 to include stacked insulating materials formed of any of the high-k materials, and it is preferable to use a stacked-layer structure of a high relative permittivity (high-k) material and a material having a higher dielectric strength than the high-k material. For the insulating layer 22, an insulating film in which zirconium oxide, aluminum oxide, and zirconium oxide are stacked in this order (also referred to as ZAZ) can be used, for example. Alternatively, an insulating film in which zirconium oxide, aluminum oxide, zirconium oxide, and aluminum oxide are stacked in this order (also referred to as ZAZA) can be used, for example. Alternatively, an insulating film in which hafnium zirconium oxide, aluminum oxide, hafnium zirconium oxide, and aluminum oxide are stacked in this order can be used, for example. The use of stacked insulators with relatively high dielectric strength, such as aluminum oxide, can increase the dielectric strength and inhibit electrostatic breakdown of the capacitor.

Alternatively, a material that exhibits ferroelectricity may be used for the insulating layer 22. Examples of the material that exhibits ferroelectricity include metal oxides such as hafnium oxide, zirconium oxide, and HfZrO_{X} (X is a real number greater than 0).

### <Conductive Layer>

Each of the conductive layer 24 and the conductive layer 25 is in contact with the semiconductor layer 21. Here, when an oxide semiconductor is used for the semiconductor layer 21, a portion of the conductive layer 24 or the conductive layer 25 which is in contact with the semiconductor layer 21 is formed using, for example, a metal that is likely to be oxidized, such as aluminum, an insulating oxide (e.g., aluminum oxide) is formed between the conductive layer 24 or the conductive layer 25 and the semiconductor layer 21, which might prevent conduction between the conductive layer 24 or the conductive layer 25 and the semiconductor layer 21. Therefore, a conductive material that is less likely to be oxidized, a conductive material that maintains low electric resistance even after being oxidized, or an oxide conductive material is preferably used for at least the portions of the conductive layer 24 and the conductive layer 25 which are in contact with the semiconductor layer 21.

For example, it is preferable to use titanium, tantalum nitride, titanium nitride, a nitride containing titanium and aluminum, a nitride containing tantalum and aluminum, ruthenium, ruthenium oxide, ruthenium nitride, an oxide containing strontium and ruthenium, an oxide containing lanthanum and nickel, or the like as the conductive layer 24 and the conductive layer 25. These materials are preferable because they are conductive materials that are less likely to be oxidized or materials that maintain the conductivity even when oxidized.

Alternatively, a conductive oxide such as indium oxide, zinc oxide, In—Sn oxide, In—Zn oxide, In—W oxide, In—W—Zn oxide, In—Ti oxide, In—Ti—Sn oxide, In—Sn—Si oxide, Ga—Zn oxide, or the like can be used. A conductive oxide containing indium is particularly preferable because of its high conductivity. Alternatively, the above-described oxide material such as In—Ga—Zn oxide that can be used for the semiconductor layer 21 can be used for the conductive layer when the carrier concentration is increased.

Examples of the structures of the conductive layer 24 and the conductive layer 25 include a single-layer structure of the above conductive oxide film, a three-layer structure in which a titanium nitride film, a tungsten film, and a titanium nitride film are stacked in this order, a two-layer structure in which a ruthenium film or a ruthenium oxide film is stacked over tungsten, a two-layer structure in which a ruthenium film or a ruthenium oxide film is stacked over the above conductive oxide film, a two-layer structure in which the above conductive oxide film is stacked over a ruthenium film or a ruthenium oxide film. Note that ruthenium is a material that is not easily etched and thus is preferably as thin as possible when used; ruthenium used preferably has a thickness greater than or equal to 0.1 nm and less than or equal to 2 nm, for example.

The conductive layer 23 functions as a gate electrode and a variety of conductive materials can be used. For the conductive layer 23, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum, for example; an alloy containing any of the above metal elements as its component; or the like. It is also possible to use a nitride or an oxide of any of the above metals or the alloy. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. Alternatively, a semiconductor having high electrical conductivity, typified by polycrystalline silicon containing an impurity element such as phosphorus, or silicide such as nickel silicide may be used.

For the conductive layer 23, the nitride and the oxide that can be used for the conductive layer 24 and the conductive layer 25 may be used.

The conductive layer 23, the conductive layer 24, and the conductive layer 25 also serve as wirings and thus are preferably formed using stacked low-resistance conductive materials. For example, a low-resistance conductive material that can be used for the above-described conductive layer 23 can also be used for the lower layers in the conductive layer 24 and the conductive layer 25.

### <Insulating Layer>

The insulating layer 41b can be used as an interlayer insulating film. For example, the insulating layer 41b is preferably formed by a film formation method such as a sputtering method or a plasma CVD method. In particular, by a sputtering method as a film formation method that does not use a hydrogen gas for a deposition gas, a film with an extremely low hydrogen content can be formed. Consequently, supply of hydrogen to the semiconductor layer 21 is inhibited and the electrical characteristics of the transistor 10 can be stabilized.

The insulating layer 41b is in contact with the channel formation region of the semiconductor layer 21 and therefore is preferably formed using an oxide insulating film. In particular, an oxide insulating film from which oxygen is released by heating is preferably used as the insulating layer 41b. An oxide insulating film that can be used as the above-described gate insulating layer can be used as the insulating layer 41b.

Since the insulating layer 41b serves as an interlayer insulating layer, it is preferably formed by a film formation method that enables a higher film formation rate than those of the other insulating layers. For example, a film of TEOS (Tetra-Ethyl-Ortho-Silicate, chemical formula: Si(OC₂H₅)₄) formed by a plasma CVD method can also be used for the insulating layer 41. Thus, the productivity can be improved.

As each of the insulating layer 41a and the insulating layer 41c, a film through which hydrogen hardly diffuses is preferably used. The insulating layer 41a and the insulating layer 41c which do not easily allow diffusion of hydrogen are provided above and below the insulating layer 41b, respectively, thereby preventing entry of hydrogen from the outside into the insulating layer 41b in contact with the semiconductor layer 21.

As the insulating layer 41a and the insulating layer 41c, for example, one or more of silicon nitride, silicon nitride oxide, silicon oxynitride, aluminum oxide, aluminum oxynitride, aluminum nitride, hafnium oxide, and hafnium aluminate can be used. Silicon nitride and silicon nitride oxide can be particularly suitably used for the insulating layer 41a and the insulating layer 41c because the silicon nitride and the silicon nitride oxide release fewer impurities (e.g., water and hydrogen) and are less likely to transmit oxygen and hydrogen.

The insulating layer 11 functions as an interlayer insulating layer. For the insulating layer 11, an insulating material that can be used for the insulating layer 41b or an insulating material that can be used for the insulating layer 41a and the insulating layer 41c can be used as appropriate.

The above is the description of the components.

### Modification Examples

An example whose structure is partly different from the above-described structure example is described below. Note that description of the portions similar to the above is omitted in some cases.

### Modification Example 1

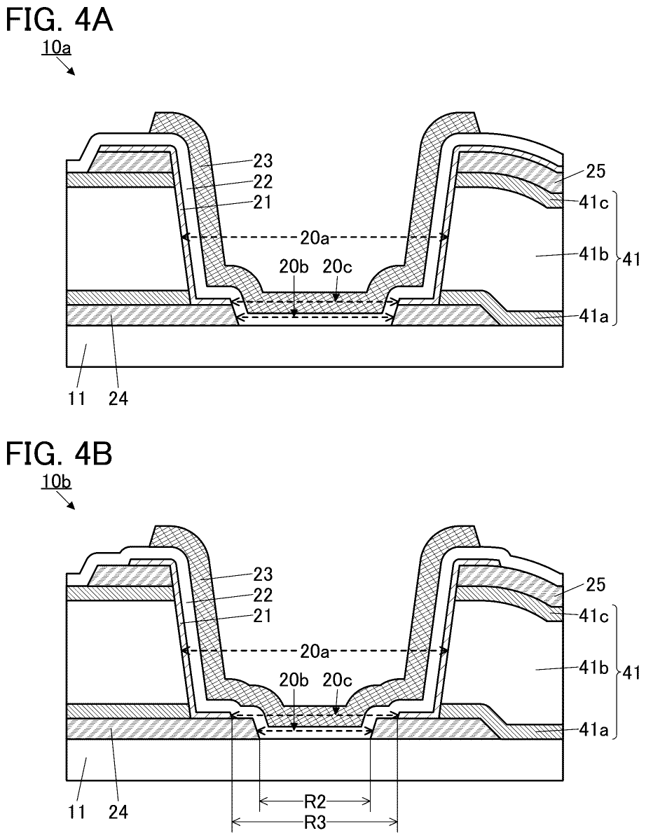

FIG. 4A is a schematic cross-sectional view of a transistor 10a described below as an example. The transistor 10a is different from the above-described transistor 10 mainly in the shape of the semiconductor layer 21.

In a portion of the semiconductor layer 21 positioned over the conductive layer 25, the end portions of the semiconductor layer 21 and the conductive layer 25 are substantially aligned with each other. With such a structure, the conductive layer 25 and the semiconductor layer 21 can be processed in the same step, so that the process can be simplified. Furthermore, since the conductive layer 25 is covered with the semiconductor layer 21, it is possible to prevent a reduction in conductivity of the conductive layer 25 due to damage to the conductive layer 25 in the etching step of the semiconductor layer 21, the formation step of the insulating layer 22, or the like.

### Modification Example 2

A transistor 10b illustrated in FIG. 4B is different from the above-described transistor 10 mainly in the structures of the conductive layer 24 and the semiconductor layer 21.

Inside the opening 20a, the end portion of the conductive layer 24 includes a portion protruding beyond the end portion of the semiconductor layer 21. The top surface of the conductive layer 24 includes a portion in contact with the semiconductor layer 21 and a portion in contact with the insulating layer 22. The diameter R2 of the opening 20b is smaller than the diameter R3 of the opening 20c. With such a structure, a step at the end portions of the semiconductor layer 21 and the conductive layer 24 is reduced as compared with the case where the end portions of the semiconductor layer 21 and the conductive layer 24 are substantially aligned with each other; thus, poor coverage of the insulating layer 22 can be prevented.

### Modification Example 3

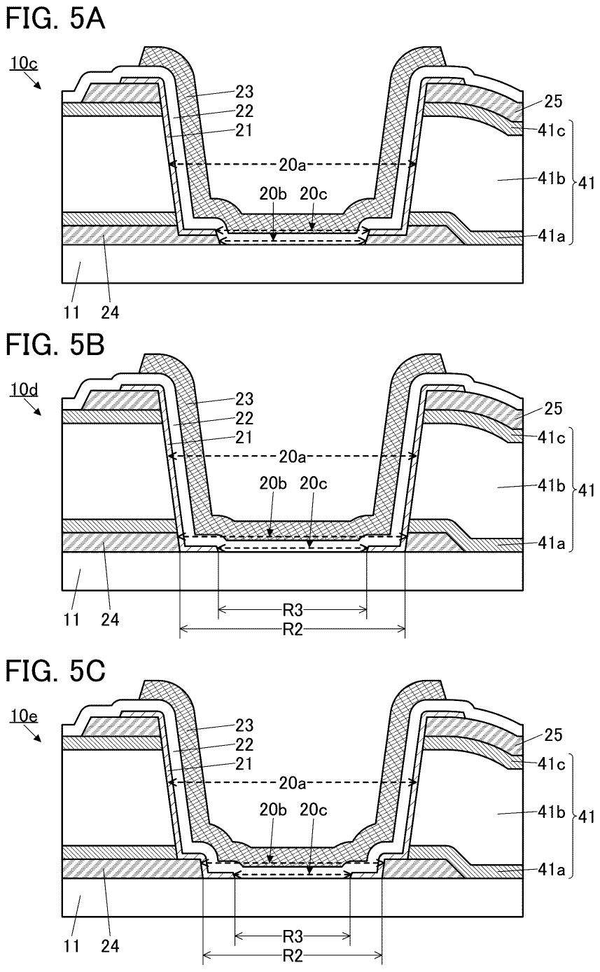

A transistor 10c illustrated in FIG. 5A is different from the above-described transistor 10 mainly in the shape of the conductive layer 24.

In the conductive layer 24, a thickness of a portion overlapping with the opening 20a is smaller than a portion overlapping with the insulating layer 41. For example, in the case where part of the conductive layer 24 is etched and thinned at the time of forming the opening 20a, the conductive layer 24 may have such a shape.

A transistor 10d illustrated in FIG. 5B is an example in which the conductive layer 24 is also etched at the time of forming the opening 20a. At this time, the semiconductor layer 21 is in contact with the side surface of the conductive layer 24.

With such a structure, a step in the opening 20a can be reduced, so that generation of poor coverage of the insulating layer 22 can be inhibited more effectively.

### Modification Example 4

A transistor 10e illustrated in FIG. 5C is an example in which the semiconductor layer 21 is provided to cover the end portion of the conductive layer 24 in the opening 20a.

In the transistor 10e, the opening 20c is positioned inside the opening 20b in a plan view. Thus, the diameter R3 of the opening 20c is smaller than the diameter R2 of the opening 20b.

With such a structure, a step in the opening 20a can be reduced, so that generation of poor coverage of the insulating layer 22 can be inhibited more effectively.

### Modification Example 5

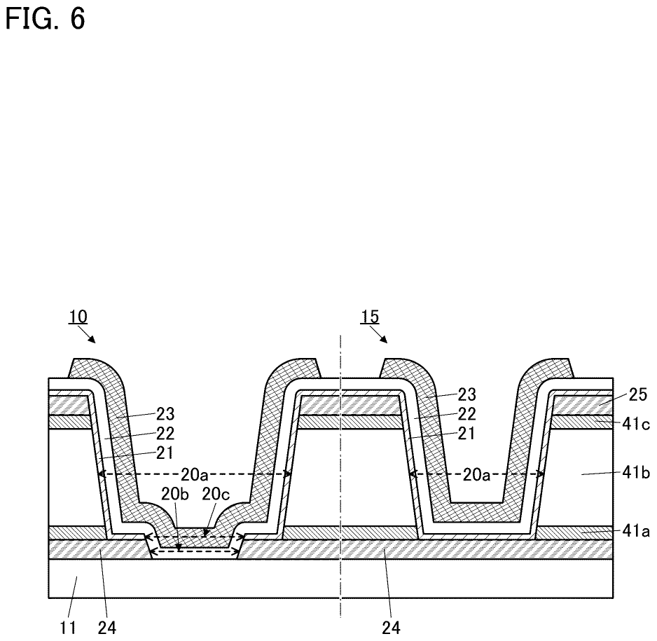

In FIG. 6, a cross section of a transistor 15 that can be formed on the same plane as and through the same process as the transistor 10 is illustrated side by side with the transistor 10.

The transistor 15 is a transistor in which neither the opening 20b in the conductive layer 24 nor the opening 20c in the semiconductor layer 21 is provided. The transistor 15 includes the semiconductor layer 21, the insulating layer 22, the conductive layer 23, the conductive layer 24, and the conductive layer 25. In the transistor 15, the insulating layer 22 is in contact with the semiconductor layer 21 inside the opening 20a and is in contact with neither the conductive layer 24 nor the insulating layer 11.

When neither the opening 20b nor the opening 20c is provided in the transistor 15, the diameter of the opening 20a provided in the insulating layer 41 can be smaller than that in the transistor 10. In other words, the transistor 15 can be a minute transistor compared with the transistor 10. For example, the transistor 10 and the transistor 15 can be used depending on requirements; the transistor 10 can be used for a transistor required to have small parasitic capacitance, and the transistor 15 can be used for a transistor required to have a small occupation area.

### Modification Example 6

A structure example of a transistor that has a structure suitable for miniaturization by employing an LSI process is described below.

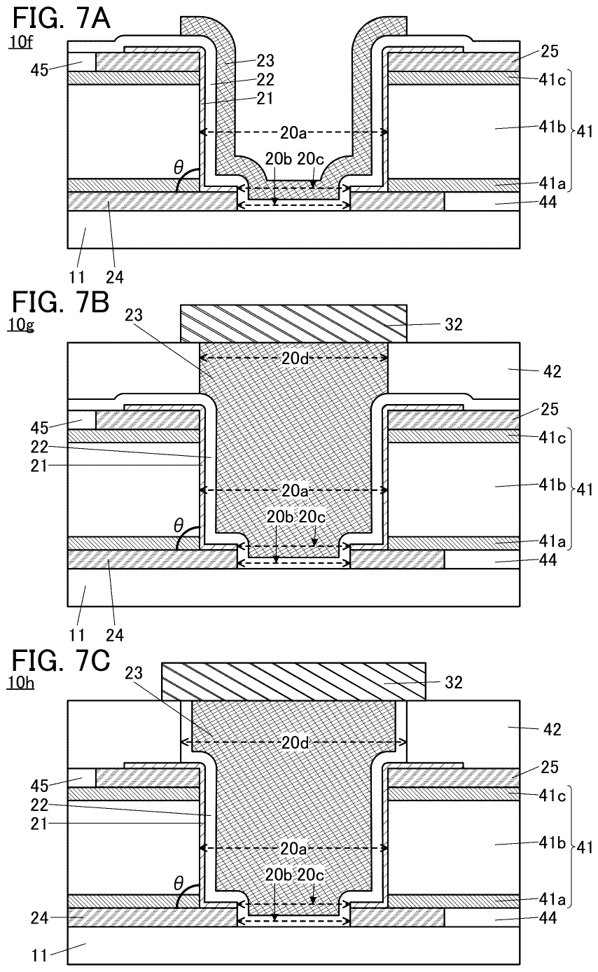

A transistor 10f illustrated in FIG. 7A is different from the above-described transistor 10 and the like mainly in that end portions of the layers are processed to be substantially perpendicular to the substrate.

The conductive layer 24 is embedded in an insulating layer 44. The insulating layer 41 is provided to cover the conductive layer 24 and the insulating layer 44. The conductive layer 25 is embedded in an insulating layer 45. The insulating layer 22 is provided to cover the insulating layer 45, the conductive layer 25, the semiconductor layer 21, and the like. The top surfaces of the insulating layer 44 and the conductive layer 24 are substantially level with each other by planarization, and the top surfaces of the insulating layer 45 and the conductive layer 25 are substantially level with each other by planarization.

The insulating layer 41a, the insulating layer 41b, and the insulating layer 41c each have a cross section substantially perpendicular to the substrate. That is, the angle θ of the sidewall of the opening 20a in the insulating layer 41 is approximately 90°. Since the end portion of the semiconductor layer 21 and the end portion of the conductive layer 24 are substantially aligned with each other in the opening 20a, the diameter of the opening 20c and the outline of the opening 20b are substantially aligned with each other.

Since the semiconductor layer 21, the insulating layer 22, and the conductive layer 23 are provided along the inner wall, which is substantially perpendicular to the substrate, of the opening 20a in the insulating layer 41, the semiconductor layer 21, the insulating layer 22, and the conductive layer 23 are preferably formed by a film formation method that provides high coverage, such as an ALD method.

A transistor 10g illustrated in FIG. 7B is an example in which the conductive layer 23 is provided to fill the opening 20a.

An insulating layer 42 is provided over the insulating layer 22, and an opening 20d overlapping with the opening 20a and reaching the insulating layer 22 is provided in the insulating layer 42. The conductive layer 23 is provided to fill the opening 20d and the opening 20a. The top surfaces of the conductive layer 23 and the insulating layer 42 are planarized, and a conductive layer 32 in contact with the top surface of the conductive layer 23 is provided over the insulating layer 42. The conductive layer 32 functions as agate wiring.

A transistor 10h illustrated in FIG. 7C is an example in which the insulating layer 22 is provided along the inner wall of the opening 20d.

The opening 20d is provided to reach the semiconductor layer 21, and the insulating layer 22 is provided to cover the sidewall of the opening 20d and the semiconductor layer 21. The conductive layer 23 is provided to fill the opening 20d and the opening 20a.

With the structures illustrated in FIG. 7A to FIG. 7C, an extremely minute transistor can be achieved. For example, when a transistor with such a structure is formed over a semiconductor substrate such as a silicon wafer, a display panel with a resolution higher than 3000 ppi or further higher than 5000 ppi can be achieved.

The above is the description of the modification examples.

### Manufacturing Method Example

Next, a method for manufacturing the semiconductor device of one embodiment of the present invention is described. Here, an example of a manufacturing method of the transistor 10 is described.

Thin films included in the semiconductor device (e.g., insulating films, semiconductor films, and conductive films) can be formed by a sputtering method, a chemical vapor deposition (CVD) method, a vacuum evaporation method, a pulsed laser deposition (PLD) method, an atomic layer deposition (ALD) method, or the like. Examples of a CVD method include a plasma-enhanced chemical vapor deposition (PECVD) method and a thermal CVD method. As an example of the thermal CVD method, a metal organic chemical vapor deposition (MOCVD) method is given.

Thin films included in the semiconductor device (e.g., insulating films, semiconductor films, and conductive films) can be formed by a method such as spin coating, dipping, spray coating, ink-jetting, dispensing, screen printing, offset printing, a doctor knife, slit coating, roll coating, curtain coating, or knife coating.

Examples of the sputtering method include an RF sputtering method in which a high-frequency power source is used as a sputtering power source, a DC sputtering method in which a DC power source is used, and a pulsed DC sputtering method in which voltage applied to an electrode is changed in a pulsed manner. An RF sputtering method is mainly used in the case where an insulating film is formed, and a DC sputtering method is mainly used in the case where a metal conductive film is formed. The pulsed DC sputtering method is mainly used in the case where a compound such as an oxide, a nitride, or a carbide is deposited by a reactive sputtering method.

Note that the CVD method can be classified into a plasma CVD (PECVD) method using plasma, a thermal CVD (TCVD) method using heat, a photo CVD method using light, and the like. Moreover, the CVD method can be classified into a metal CVD (MCVD) method and a metal organic CVD (MOCVD) method depending on a source gas to be used.

A high-quality film can be obtained at a relatively low temperature by a plasma CVD method. Furthermore, the thermal CVD method is a film formation method that does not use plasma and thus enables less plasma damage to an object to be processed. In addition, a thermal CVD method does not cause plasma damage during film formation, so that a film with few defects can be obtained.

As the ALD method, a thermal ALD method, in which a precursor and a reactant react with each other only by a thermal energy, a PEALD method, in which a reactant excited by plasma is used, and the like can be used.

Unlike a sputtering method, a CVD method and an ALD method are less likely to be influenced by the shape of an object to be processed and thus enable favorable step coverage. In particular, the ALD method enables excellent step coverage and excellent thickness uniformity and thus is suitable for covering a surface of an opening portion with a high aspect ratio, for example. On the other hand, the ALD method has a relatively low deposition rate, and thus is preferably used in combination with another film formation method with a high deposition rate, such as the CVD method, in some cases.

By the CVD method, a film with a certain composition can be deposited depending on the flow rate ratio of the source gases. For example, by the CVD method, a film whose composition is continuously changed can be deposited by changing the flow rate ratio of the source gases during deposition. In the case where the film is deposited while the flow rate ratio of the source gases is changed, as compared with the case where the film is deposited using a plurality of deposition chambers, the time taken for the deposition can be shortened because the time taken for transfer or pressure adjustment is not required. Thus, the productivity of the semiconductor device can be increased in some cases.

By the ALD method, a film with a certain composition can be deposited by concurrently introducing different kinds of precursors. In the case where different kinds of precursors are introduced, a film with a certain composition can be deposited by controlling the number of cycles for each of the precursors. Furthermore, a film whose composition is continuously changed can be formed as in the CVD method.

In processing thin films included in the semiconductor device, a photolithography method or the like can be employed. Alternatively, the thin films may be processed by a nanoimprinting method, a sandblasting method, a lift-off method, or the like. Alternatively, island-shaped thin films may be directly formed by a film formation method using a shielding mask such as a metal mask.

There are two typical examples of photolithography methods. In one of the methods, a resist mask is formed over a thin film to be processed, the thin film is processed by etching or the like, and then the resist mask is removed. In the other method, a photosensitive thin film is formed and then processed into a desired shape by light exposure and development.

As light for light exposure in a photolithography method, it is possible to use the i-line (wavelength: 365 nm), the g-line (wavelength: 436 nm), the h-line (wavelength: 405 nm), or light in which the i-line, the g-line, and the h-line are mixed. Alternatively, ultraviolet light, KrF laser light, ArF laser light, or the like can be used. In addition, light exposure may be performed by liquid immersion exposure technique. As the light for exposure, extreme ultraviolet (EUV) light or X-rays may also be used. Furthermore, instead of the light used for the exposure, an electron beam can also be used. Extreme ultraviolet light, X-rays, or an electron beam is preferably used, in which case extremely minute processing can be performed. Note that a photomask is not needed when the light exposure is performed by scanning with a beam such as an electron beam.

For etching of thin films, a dry etching method, a wet etching method, a sandblasting method, or the like can be used.

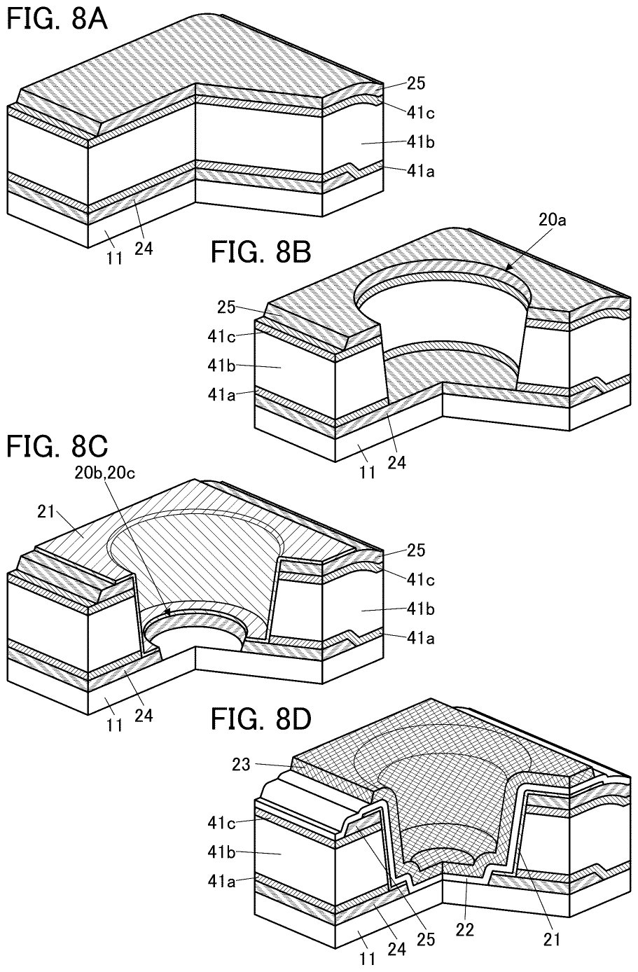

FIG. 8A to 8D are perspective views of steps in a manufacturing method of a semiconductor device described below.

First, a substrate (not illustrated) is prepared, and the insulating layer 11 is formed over the substrate.

As the substrate, a substrate having at least heat resistance high enough to withstand heat treatment performed later can be used. In the case where an insulating substrate is used as the substrate, a glass substrate, a quartz substrate, a sapphire substrate, a ceramics substrate, an organic resin substrate, or the like can be used. Alternatively, a single crystal semiconductor substrate or a polycrystalline semiconductor substrate using silicon, silicon carbide, or the like as a material, a compound semiconductor substrate of silicon germanium, gallium nitride, or the like, or a semiconductor substrate such as an SOI substrate can be used.

As the insulating layer 11, for example, an inorganic insulating film such as a silicon oxide film or a silicon oxynitride film can be used. The insulating layer 11 can be formed by a sputtering method, a CVD method, an MBE method, a PLD method, an ALD method, or the like. In the case where the formation surface of the insulating layer 11 is not flat, planarization treatment may be performed after the deposition of the insulating layer 11 so that the insulating layer 11 has a flat top surface.

Next, a conductive film is formed over the insulating layer 11, a resist mask is formed over the conductive film, and an unnecessary portion of the conductive film is removed by etching, whereby the conductive layer 24 is formed.

A film formation method such as a sputtering method, a CVD method, or an ALD method can be used for a conductive film to be the conductive layer 24.

Then, the insulating layer 41a, the insulating layer 41b, and the insulating layer 41c are formed over the conductive layer 24 and the insulating layer 11. The insulating layer 41a, the insulating layer 41b, and the insulating layer 41c can independently be formed by a sputtering method, a CVD method, an MBE method, a PLD method, an ALD method, or the like as appropriate.

Here, insulating films used for the insulating layer 41a and the insulating layer 41c preferably have compositions or constituent elements different from that of an insulating film used for the insulating layer 41b.

Furthermore, the thicknesses of the insulating layer 41a, the insulating layer 41b, and the insulating layer 41c affect the channel length of the transistor; thus, it is important to prevent a variation in the thickness of each of the insulating layer 41a, the insulating layer 41b, and the insulating layer 41c.

Since the insulating layer 41b is a film to be in contact with the semiconductor layer 21 later, an oxide film including the amount of oxygen large enough to be released by heating and including a small amount of hydrogen is preferably used. The insulating layer 41b can be formed by a film formation method such as a PECVD method, a sputtering method, or an ALD method, and is particularly preferably deposited by a sputtering method. In particular, without using a gas containing hydrogen and with using a gas containing oxygen as a deposition gas, the insulating layer 41b containing an extremely small amount of hydrogen and an excess amount of oxygen can be deposited. When the insulating layer 41b is deposited in this manner, oxygen can be supplied from the insulator 41b to the channel formation region of the semiconductor layer 21, so that oxygen vacancies therein can be reduced.

Next, after a conductive film is formed over the insulating layer 41c, an unnecessary portion is removed by etching, so that the conductive layer 25 is formed (FIG. 8A). The conductive film can be deposited by a film formation method such as a sputtering method, a CVD method, an MBE method, a PLD method, an ALD method as appropriate.

Next, the opening 20a reaching the conductive layer 24 is formed in the conductive layer 25, the insulating layer 41c, the insulating layer 41b, and the insulating layer 41a (FIG. 8B).

The conductive layer 25 may be used as a hard mask at the time of forming the opening 20a. At this time, first, an opening is formed in the conductive layer 25 using a resist mask. After that, the insulating layer 41c, the insulating layer 41b, and the insulating layer 41a are etched in this order with the conductive layer 25 as a mask, so that the opening 20a can be formed. Note that the resist mask may be removed after the etching of the conductive layer 25, may be removed during the etching of the insulating layer 41c, the insulating layer 41b, and the insulating layer 41a, or may be removed after the formation of the opening 20a.

For the etching of the conductive layer 25, the insulating layer 41c, the insulating layer 41b, and the insulating layer 41a, dry etching is used whereby the minute opening 20a can be formed. Without limitation to this, the layers may be processed by a combination of wet etching and dry etching, or wet etching.

The sidewall of the opening 20a preferably has a shape nearly perpendicular to the top surface of the conductive layer 24, in which case the area of the opening 20a can be reduced. This structure can reduce the area occupied by the transistor. The sidewall of the opening 20a may have a tapered shape. The tapered shape improves the coverage with a film formed in the opening 20a.

The maximum width of the opening 20a (the maximum diameter in the case where the opening 20a is circular in the plan view) is preferably as small as possible. For example, the maximum width of the opening 20a is preferably less than or equal to 2 μm, less than or equal to 1 μm, less than or equal to 500 nm, less than or equal to 300 nm, less than or equal to 150 nm, less than or equal to 100 nm, less than or equal to 60 nm, less than or equal to 50 nm, less than or equal to 40 nm, less than or equal to 30 nm, or less than or equal to 20 nm and greater than or equal to 5 nm. In particular, in order to process the opening 20a extremely finely, a lithography method using an electron beam or short-wavelength light such as EUV light is preferably used.

Next, heat treatment may be performed. The heat treatment is performed at higher than or equal to 250° C. and lower than or equal to 650° C., preferably higher than or equal to 300° C. and lower than or equal to 500° C., further preferably higher than or equal to 320° C. and lower than or equal to 450° C. Note that the heat treatment is performed in a nitrogen gas or inert gas atmosphere, or an atmosphere containing an oxidizing gas at higher than or equal to 10 ppm, higher than or equal to 1%, or higher than or equal to 10%. For example, in the case where the heat treatment is performed in a mixed atmosphere of a nitrogen gas and an oxygen gas, the proportion of the oxygen gas is approximately 20%. The heat treatment may be performed under reduced pressure. Alternatively, the heat treatment may be performed in an atmosphere containing an oxidizing gas at 10 ppm or more, 1% or more, or 10% or more in order to compensate for oxygen released, after heat treatment is performed in a nitrogen gas or inert gas atmosphere. By the above-described heat treatment, impurities such as water or hydrogen contained in the insulating layer 41 or the like can be reduced before formation of the oxide semiconductor film to be the semiconductor layer.

The gas used in the above heat treatment is preferably highly purified. For example, the amount of moisture contained in the gas used in the above heat treatment is less than or equal to 1 ppb, preferably less than or equal to 0.1 ppb, further preferably less than or equal to 0.05 ppb. The heat treatment using a highly purified gas can prevent entry of moisture or the like into the insulating layer 41 and the like as much as possible.

Next, a semiconductor film to be the semiconductor layer 21 is formed to cover the conductive layer 25, the insulating layer 41c, the opening 20a, and the like. After that, an unnecessary portion of the semiconductor film is removed by etching to form the semiconductor layer 21. Note that the opening 20c is not necessarily formed in the semiconductor layer 21 at this stage.

Next, part of the semiconductor layer 21 and part of the conductive layer 24 in a region overlapping with the opening 20a are etched, whereby the opening 20c and the opening 20b are formed in the semiconductor layer 21 and the conductive layer 24, respectively (FIG. 8C).

The opening 20b and the opening 20c are preferably formed using the same resist mask. Thus, the end portions of the semiconductor layer 21 and the conductive layer 24 can be substantially aligned with each other.

Note that the formation of the opening 20b and the opening 20c is not limited thereto, and the opening 20b and the opening 20c can be formed separately using different resist masks. The opening 20c and the opening 20b may be formed at the same time as processing the semiconductor layer 21. The opening 20b may be formed before the semiconductor film is formed, and the opening 20c may be formed separately after the semiconductor film is formed. The opening 20b may be formed at the same time as the formation of the opening 20a.

An oxide semiconductor film can be used as the semiconductor film. The oxide semiconductor film can be deposited by a sputtering method, a CVD method, an MBE method, a PLD method, an ALD method, or the like as appropriate. Here, the oxide semiconductor film is preferably formed in contact with the bottom portion and the sidewall of the opening 20a with a high aspect ratio. Thus, the oxide semiconductor film is preferably formed by a formation method with favorable coverage, and is further preferably formed by a CVD method, an ALD method, or the like. For example, an In—Ga—Zn oxide may be deposited by an ALD method as the oxide semiconductor film. In the case where the opening 20a has a tapered shape, the oxide semiconductor film can be formed by a sputtering method.

During or after the formation of the oxide semiconductor film, microwave treatment is preferably performed in an oxygen-containing atmosphere so that the impurity concentration in the oxide semiconductor film can be reduced. Specific examples of the impurity include hydrogen and carbon. The microwave treatment can increase the crystallinity of the oxide semiconductor film in some cases. Here, the microwave treatment refers to, for example, treatment using an apparatus including a power source that generates high-density plasma with use of a microwave.

The microwave treatment in an oxygen-containing atmosphere converts an oxygen gas into plasma using a high-frequency wave such as a microwave or RF and activates the oxygen plasma. The oxygen that works on the oxide semiconductor has any of a variety of forms such as an oxygen atom, an oxygen molecule, an oxygen ion, and an oxygen radical (also referred to as O radical, which is an atom, a molecule, or an ion having an unpaired electron). Note that the oxygen that works on the oxide semiconductor preferably has any one or more of the above forms; an oxygen radical is particularly preferable.

The above-described microwave treatment in an oxygen-containing atmosphere is preferably performed while the substrate is heated, in which case the impurity concentration in the oxide semiconductor film can be further reduced. The substrate heating temperature is higher than or equal to 100° C. and lower than or equal to 650° C., preferably higher than or equal to 200° C. and lower than or equal to 600° C., further preferably higher than or equal to 300° C. and lower than or equal to 450° C.

When the microwave treatment in an oxygen-containing atmosphere is performed while the substrate is heated, the carbon concentration in the oxide semiconductor film, which is measured by SIMS, can be lower than 1×10²⁰ atoms/cm³, preferably lower than 1×10¹⁹ atoms/cm³, further preferably lower than 1×10¹⁸ atoms/cm³.

Although the microwave treatment in an oxygen-containing atmosphere is performed on the oxide semiconductor film in the above-described example, one embodiment of the present invention is not limited thereto. For example, the microwave treatment in an oxygen-containing atmosphere may be performed on an insulating film, specifically a silicon oxide film, which is positioned in the vicinity of the oxide semiconductor film. In that case, hydrogen contained in the silicon oxide film can be released to the outside as H₂O. Release of hydrogen from the silicon oxide film positioned in the vicinity of the oxide semiconductor film enables formation of a highly reliable semiconductor device. For example, microwave treatment may be performed on the insulating layer 22 to be formed later in an oxygen-containing atmosphere.

In the case where the semiconductor layer 21 has a stacked-layer structure, the layers included in the semiconductor layer 21 may be formed by the same method or different methods. For example, in the case where the semiconductor layer 21 has a stacked-layer structure of two layers, the lower oxide semiconductor film may be deposited by a sputtering method and the upper oxide semiconductor film may be deposited by an ALD method. An oxide semiconductor film deposited by a sputtering method is likely to have crystallinity. Thus, when an oxide semiconductor film having crystallinity is provided as the lower oxide semiconductor film, the crystallinity of the upper oxide semiconductor film can be increased. Thus, even when a pinhole, disconnection, or the like is generated in the lower oxide semiconductor film deposited by a sputtering method, a portion overlapping with the pinhole, disconnection, or the like can be filled with the upper oxide semiconductor film that is deposited by an ALD method and has excellent coverage.

The semiconductor film is preferably formed by a sputtering method, for example, using a metal oxide target.

The semiconductor film is preferably a dense film with as few defects as possible. The semiconductor film is preferably a highly purified film in which impurities such as hydrogen and water are reduced as much as possible. It is particularly preferable to use a metal oxide film having crystallinity as the semiconductor film.

In addition, an oxygen gas and an inert gas (such as a helium gas, an argon gas, or a xenon gas) may be mixed in depositing the metal oxide film. Note that when the proportion of an oxygen gas in the whole deposition gas (hereinafter also referred to as an oxygen flow rate ratio) at the time of depositing the metal oxide film is higher, the crystallinity of the metal oxide film can be higher and a transistor with higher reliability can be obtained. By contrast, when the oxygen flow rate ratio is lower, the crystallinity of the metal oxide film is lower and a transistor with a high on-state current can be obtained.

In depositing the metal oxide film, as the substrate temperature becomes higher, a denser metal oxide film having higher crystallinity can be formed. On the other hand, as the substrate temperature is lower, a metal oxide film having lower crystallinity and a higher electrical conduction property can be formed.

The metal oxide film is formed under the deposition conditions where the substrate temperature is higher than or equal to room temperature and lower than or equal to 250° C., preferably higher than or equal to room temperature and lower than or equal to 200° C., further preferably higher than or equal to room temperature and lower than or equal to 140° C. For example, when the substrate temperature is higher than or equal to room temperature and lower than 140° C., high productivity is achieved, which is preferable. Furthermore, when the metal oxide film is deposited with the substrate temperature set at room temperature or without heating the substrate intentionally, the crystallinity can be made low.

In the case where an ALD method is used, a film formation method such as a thermal ALD (Atomic Layer Deposition) method or PEALD (Plasma Enhanced ALD) is preferably used. The thermal ALD method is preferable because of its capability of forming a film with extremely high step coverage. The PEALD method is preferable because of its capability of forming a film at low temperatures, in addition to its capability of forming a film with high step coverage.

For example, in the case where a metal oxide is used for the semiconductor layer 21, the semiconductor layer 21 can be deposited by an ALD method using a precursor containing a constituent metal element and an oxidizer.

For example, in the case where In—Ga—Zn oxide is formed, three precursors of a precursor containing indium, a precursor containing gallium, and a precursor containing zinc can be used. Alternatively, two precursors of a precursor containing indium and a precursor containing gallium and zinc may be used.

As the precursor containing indium, triethylindium, tris(2,2,6,6-tetramethyl-3,5-heptanedionato)indium, cyclopentadienylindium, indium(III) chloride, (3-(dimethylamino)propyl)dimethylindium, or the like can be used.

As the precursor containing gallium, trimethylgallium, triethylgallium, gallium trichloride, tris(dimethylamido)gallium, gallium(III) acetylacetonate, tris(2,2,6,6-tetramethyl-3,5-heptanedionato)gallium, dimethylchlorogallium, diethylchlorogallium, gallium(III) chloride, or the like can be used.

As the precursor containing zinc, dimethylzinc, diethylzinc, bis(2,2,6,6-tetramethyl-3,5-heptanedionato)zinc, zinc chloride, or the like can be used.

Ozone, oxygen, water, or the like can be used as the oxidizer, for example.

As an example of a method for controlling the composition of a film to be formed, adjusting the flow rate ratio, flowing time, flowing order, or the like of the source gases is given. By adjusting such conditions, a film whose composition is continuously changed can be formed. Furthermore, two or more films having different compositions can be formed successively.

After the deposition of the oxide semiconductor film, heat treatment is preferably performed. The heat treatment can be performed in a temperature range where the oxide semiconductor film does not become polycrystals, i.e., at higher than or equal to 250° C. and lower than or equal to 650° C., preferably higher than or equal to 400° C. and lower than or equal to 600° C. Note that the heat treatment is performed in a nitrogen gas or inert gas atmosphere, or an atmosphere containing an oxidizing gas at higher than or equal to 10 ppm, higher than or equal to 1%, or higher than or equal to 10%. For example, in the case where the heat treatment is performed in a mixed atmosphere of a nitrogen gas and an oxygen gas, the proportion of the oxygen gas is approximately 20%. The heat treatment may be performed under reduced pressure. Alternatively, the heat treatment may be performed in an atmosphere containing an oxidizing gas at 10 ppm or more, 1% or more, or 10% or more in order to compensate for oxygen released, after heat treatment is performed in a nitrogen gas or inert gas atmosphere.

The gas used in the above heat treatment is preferably highly purified. For example, the amount of moisture contained in the gas used in the above heat treatment is less than or equal to 1 ppb, preferably less than or equal to 0.1 ppb, further preferably less than or equal to 0.05 ppb. The heat treatment using a highly purified gas can prevent entry of moisture or the like into the oxide semiconductor film and the like as much as possible.

Then, the insulating layer 22 is formed to cover the semiconductor layer 21, the conductive layer 25, the insulating layer 41c, the conductive layer 24, the insulating layer 11, and the like. The insulating layer 22 can be formed by a sputtering method, a CVD method, an MBE method, a PLD method, an ALD method, or the like as appropriate.

The insulating layer 22 is preferably provided to have a thickness as uniform as possible on the side surface of the semiconductor layer 21 in the opening 20a. Thus, the insulating layer 22 is particularly preferably formed by an ALD method, which is a film formation method with extremely excellent coverage. In the case where the opening 20a has a sidewall with a tapered shape, the insulating layer 22 can be formed by a film formation method such as a sputtering method.

Next, a conductive film is formed to cover the insulating layer 22 and an unnecessary portion is removed by etching, so that the conductive layer 23 is formed (FIG. 8D).

Through the above process, the transistor 10 can be fabricated.

The above is the description of the manufacturing method example.

At least part of this embodiment can be implemented in combination with the other embodiments described in this specification as appropriate.

### Embodiment 2

One embodiment of the present invention has a structure in which the capacitance between the gate electrode and the first electrode is reduced at the bottom portion of the opening (the first opening) included in the insulating layer functioning as the spacer. In Embodiment 1, the structure in which the capacitance is reduced by providing the openings in the first electrode and the semiconductor layer positioned in the lower portion is described. In this embodiment, a structure example that is partly different from the structure example in Embodiment 1 will be described. Note that the description of portions similar to those described above is omitted below in some cases.

As a more specific example, the gate electrode includes an opening positioned inside the opening (first opening) in the insulating layer functioning as the spacer in a plan view. Thus, even when one or both of the semiconductor layer and the first electrode do not have an opening, a portion where the gate electrode overlaps with neither the first electrode nor the semiconductor layer can be provided. Thus, the capacitance between the gate electrode and the first electrode can be reduced.

More specific structure examples are described below with reference to drawings.

### Structure Example

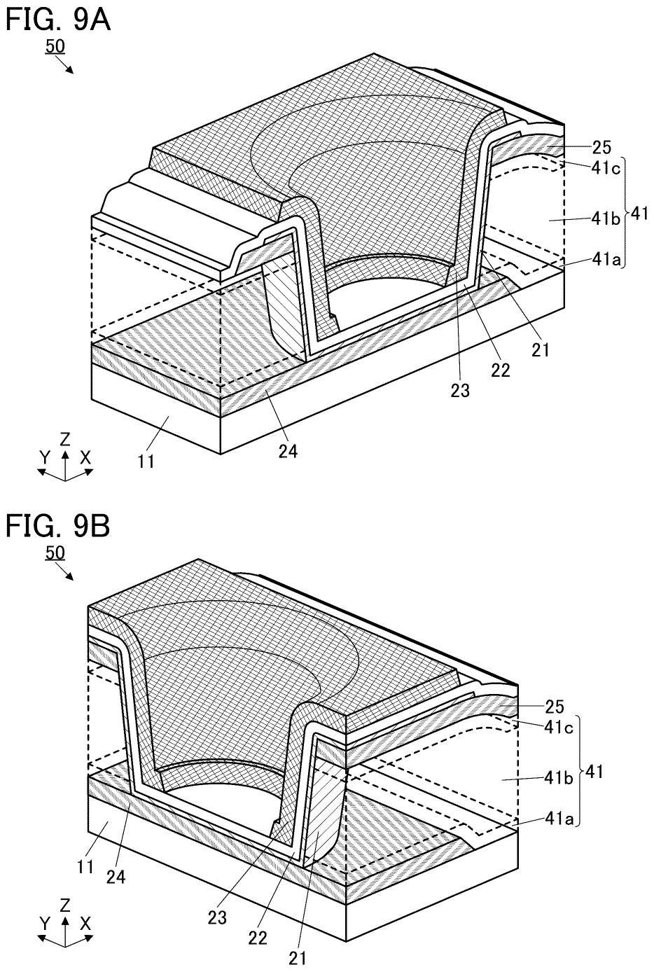

FIG. 9A and FIG. 9B are schematic perspective views of a transistor 50. FIG. 9A is a perspective view including a cross section cut along the X-Z plane, and FIG. 9B is a perspective view including a cross section cut along the Y-Z plane.

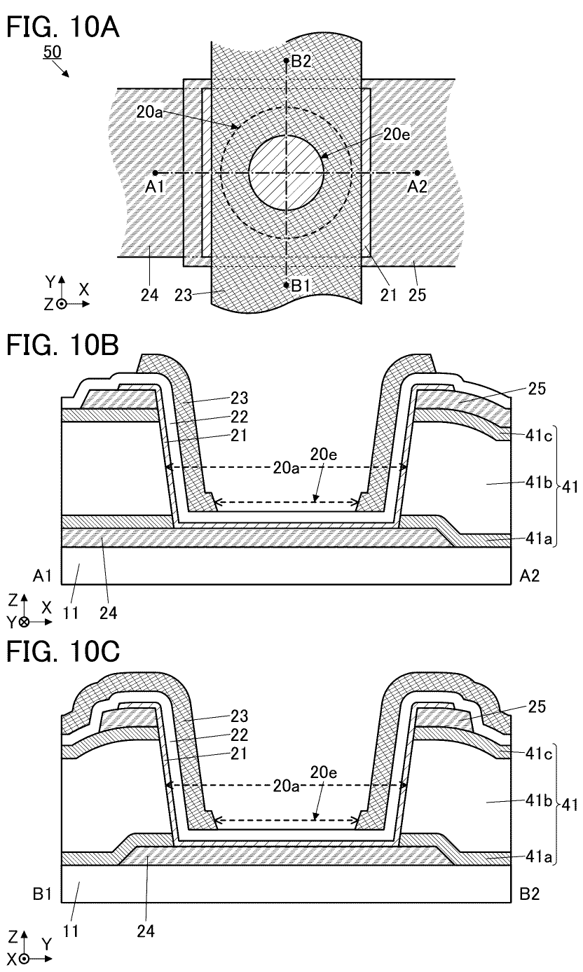

FIG. 10A is a plan view of the transistor 50, and FIG. 10B and FIG. 10C are schematic cross-sectional views along the cutting line A1-A2 and the cutting line B1-B2, respectively, in FIG. 10A.

Like the transistor 10, the transistor 50 is provided in and around the opening 20a provided in the insulating layer 41 and includes the semiconductor layer 21, the insulating layer 22, the conductive layer 23, the conductive layer 24, and the conductive layer 25.

The conductive layer 24 is provided over the insulating layer 11. The insulating layer 41 is provided to cover the conductive layer 24 and has an opening reaching the conductive layer 24. The conductive layer 25 is provided over the insulating layer 41. The semiconductor layer 21 includes a portion in contact with the top surface of the conductive layer 25, the top surface of the conductive layer 24, and the side surface of the insulating layer 41. The insulating layer 22 is provided to cover the semiconductor layer 21, and the conductive layer 23 is provided to cover the insulating layer 22.

Here, the conductive layer 23 includes an opening 20e reaching the insulating layer 22. The opening 20e is positioned inside the opening 20a in a plan view. Here, the case where the shape of the opening 20a in the insulating layer 41 and the shape of the opening 20e in the conductive layer 23 are both circular is illustrated.

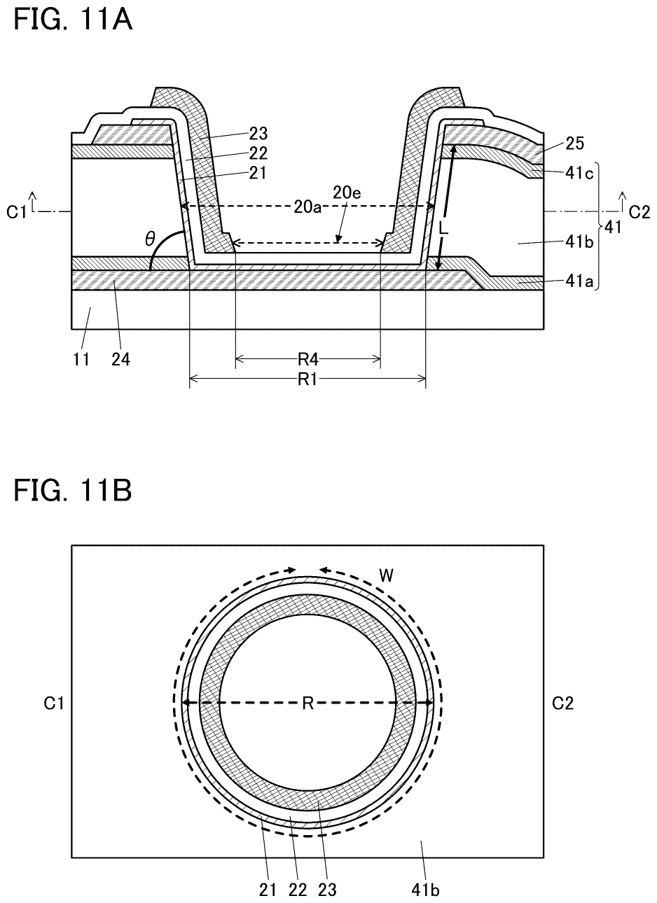

For the channel length L, the channel width W, and the like of the transistor 50, the description in Embodiment 1 can be referred to. FIG. 11A is a cross-sectional view of the transistor 50 similar to FIG. 10B, and FIG. 11B is a plan view seen in the Z direction of a cross section along the cutting line C1-C2 positioned at a height where the insulating layer 41b is provided in FIG. 11A.

As illustrated in FIG. 11A, a diameter of the opening 20e in the conductive layer 23 is R4. At this time, the diameter R4 of the opening 20e is smaller than the diameter R1 of the opening 20a. The larger R4 is, the larger the area of a portion where the conductive layer 23 overlaps with neither the conductive layer 24 nor the semiconductor layer 21 is; thus, the effect of reducing the parasitic capacitance can be enhanced. For example, the diameter R4 of the opening 20e is preferably greater than or equal to 50%, further preferably greater than or equal to 60%, still further preferably greater than or equal to 70%, yet still further preferably greater than or equal to 80%, yet still further preferably greater than or equal to 90% and less than 100% of the diameter R1 of the opening 20a.

There is no limitation on the shape of the opening 20e as long as the opening 20e is positioned inside the opening 20a regardless of the shape of the opening 20a. However, the opening 20e preferably has a similar shape of the opening 20a or the shape like the opening 20a, in which case a difference in area between the opening 20a and the opening 20e can be reduced.

The above is the description of the structure example.

### Modification Examples

Structure examples of a transistor whose structure is partly different from that of the above are described below.

### Modification Example 1

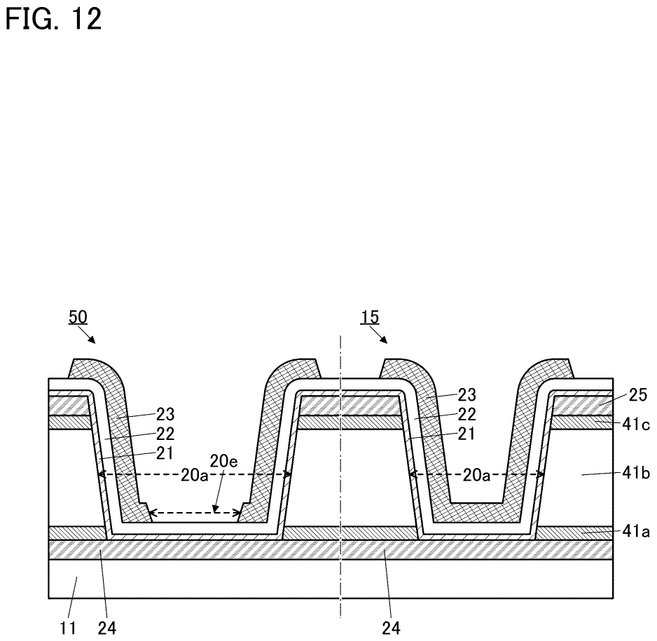

FIG. 12 is a cross-sectional view when the transistor 50 and the transistor 15 exemplified in Embodiment 1 are separately formed over the same plane.

Since the opening 20e does not need to be provided inside the opening 20a in the transistor 15, the opening 20a can be processed with a minimum feature size. Thus, the area occupied by the transistor 15 can be smaller than that of the transistor 50. Note that the diameters of the openings 20a in the transistor 15 and the transistor 50 can be changed as appropriate in accordance with the design.

The transistor 15 whose occupation area can be small and the transistor 50 whose parasitic capacitance can be reduced can be used depending on the application.

The transistor 50 and the transistor 15 can be formed separately without increasing the number of steps by using different mask patterns for processing the layers such as the conductive layer 23 and the opening 20a.

### Modification Example 2

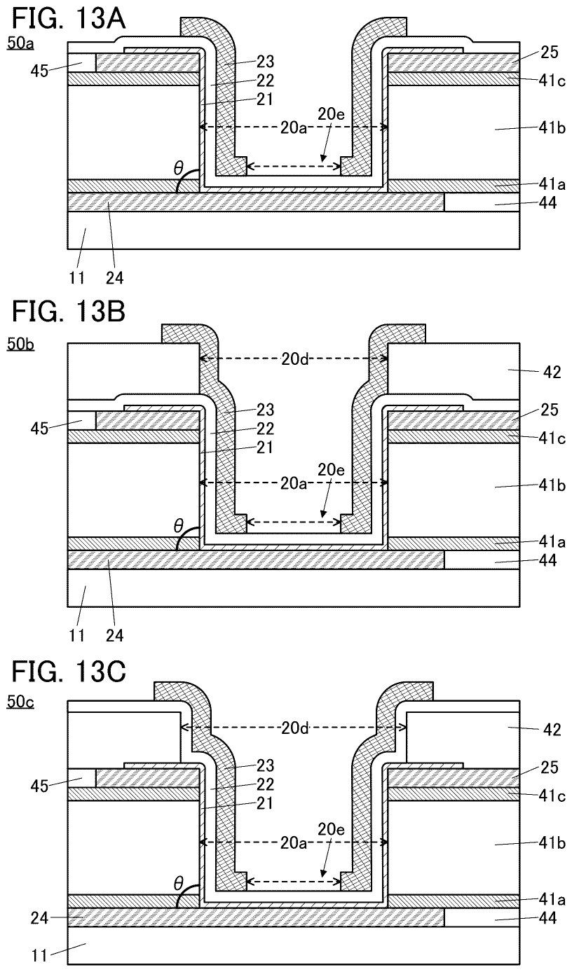

FIG. 13A illustrates a structure example of a transistor 50a that has a structure suitable for miniaturization by employing an LSI process.

The transistor 50a is different from the above-described transistor 50 mainly in that end portions of the layers are processed to be substantially perpendicular to the substrate. The conductive layer 24 is embedded in the insulating layer 44, and the conductive layer 25 is embedded in the insulating layer 45; the top surfaces of the layers are planarized to be level with each other.

Since the sidewall of the opening 20a is processed to be substantially perpendicular to the substrate, the semiconductor layer 21, the insulating layer 22, and the conductive layer 23 are preferably formed by a film formation method that provides high coverage.

A transistor 50b illustrated in FIG. 13B is an example in which the insulating layer 42 is provided over the insulating layer 22. The conductive layer 23 includes a portion provided along the sidewall of the opening 20d in the insulating layer 42.

A transistor 50c illustrated in FIG. 13C is different from the transistor 50b in the position of the insulating layer 22. The insulating layer 22 and the conductive layer 23 each include a portion provided along the sidewall of the opening 20d in the insulating layer 42.

Note that as illustrated in FIG. 7B and FIG. 7C, the conductive layer 23 may have a shape to fill the opening 20a. However, it is preferable to form the conductive layer 23 using a thin film as illustrated in FIG. 13A to FIG. 13C, in which case processing for forming the opening 20e in the conductive layer 23 is facilitated.

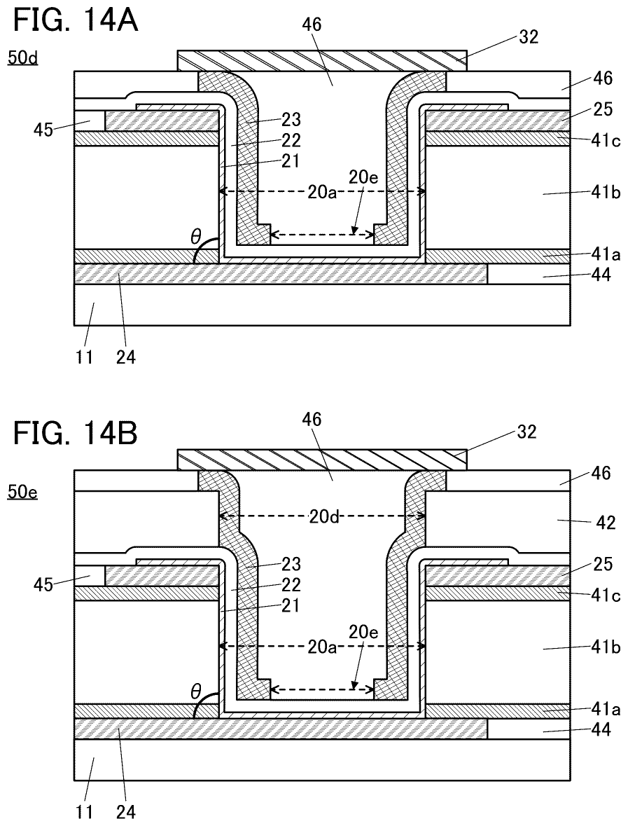

A transistor 50d illustrated in FIG. 14A is an example in which the conductive layer 32 functioning as a gate wiring is included.

An insulating layer 46 is provided to cover the insulating layer 22 and the conductive layer 23, and the conductive layer 32 is provided over the insulating layer 46. The top surface of the insulating layer 46 is planarized to be level with the top surface of the conductive layer 23. The conductive layer 32 is provided in contact with the top surface of the conductive layer 23 exposed from the insulating layer 46. The insulating layer 46 is also embedded in the opening 20a.

A transistor 50e illustrated in FIG. 14B is an example in which the insulating layer 46 and the conductive layer 32 are added to the transistor 50b illustrated in FIG. 13B. The insulating layer 46 is provided to fill the opening 20d.

Note that the insulating layer 46 and the conductive layer 32 can be added to the transistor 50c illustrated in FIG. 13C.

The above is the description of the modification examples.

At least part of this embodiment can be implemented in combination with the other embodiments described in this specification as appropriate.

### Embodiment 3

In this embodiment, a display device using the semiconductor device of one embodiment of the present invention will be described with reference to the drawings.

The display device of this embodiment can be a high-definition display device or a large-sized display device. Accordingly, the display device of this embodiment can be used for display portions of electronic devices such as a digital camera, a digital video camera, a digital photo frame, a mobile phone, a portable game console, a portable information terminal, and an audio reproducing device, in addition to display portions of electronic devices with a relatively large screen, such as a television device, a desktop or laptop personal computer, a monitor of a computer or the like, digital signage, and a large game machine such as a pachinko machine.

The display device of this embodiment can be a high-resolution display device. Accordingly, the display device of this embodiment can be used for display portions of information terminals (wearable devices) such as watch-type and bracelet-type information terminals and display portions of wearable devices capable of being worn on a head, such as a VR device like a head-mounted display (HMID) and a glasses-type AR device.

The semiconductor device of one embodiment of the present invention can be used for a display device or a module including the display device. Examples of the module including the display device include a module in which a connector such as a flexible printed circuit board (hereinafter referred to as an FPC) or a tape carrier package (TCP) is attached to the display device and a module in which the display device is mounted with an integrated circuit (IC) by a chip on glass (COG) method, a chip on film (COF) method, or the like.

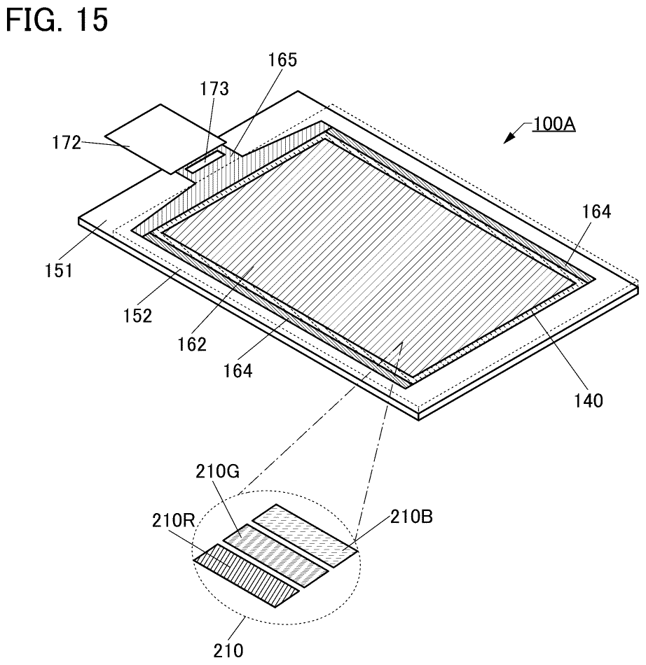

FIG. 15 is a perspective view of a display device 100A.

In the display device 100A, a substrate 152 and a substrate 151 are bonded to each other. In FIG. 15, the substrate 152 is indicated by a dashed line.

The display device 100A includes a display portion 162, a connection portion 140, a circuit portion 164, a wiring 165, and the like. FIG. 15 illustrates an example in which an IC 173 and an FPC 172 are implemented onto the display device 100A. Thus, the structure illustrated in FIG. 15 can be regarded as a display module including the display device 100A, the IC, and the FPC.

The connection portion 140 is provided outside the display portion 162. The connection portion 140 can be provided along one or more sides of the display portion 162. The number of connection portions 140 may be one or more. FIG. 15 illustrates an example where the connection portion 140 is provided to surround the four sides of the display portion 162. In the connection portion 140, a common electrode of a display element is electrically connected to a conductive layer so that a potential can be supplied to the common electrode.

The circuit portion 164 includes a scan line driver circuit (also referred to as a gate driver), for example. The circuit portion 164 may include both a scan line driver circuit and a signal line driver circuit (also referred to as a source driver).

The wiring 165 has a function of supplying a signal and power to the display portion 162 and the circuit portion 164. The signal and power are input to the wiring 165 from the outside through the FPC 172 or from the IC 173.

FIG. 15 illustrates an example where the IC 173 is provided on the substrate 151 by a COG method, a COF method, or the like. An IC including one or both of a scan line driver circuit and a signal line driver circuit can be used as the IC 173, for example. Note that the display device 100A and the display module are not necessarily provided with an IC. The IC may be mounted on the FPC by a COF method or the like.

The semiconductor device of one embodiment of the present invention can be used for one or both of the display portion 162 and the circuit portion 164 of the display device 100A, for example. The semiconductor device of one embodiment of the present invention can also be used for the IC 173.

When the semiconductor device of one embodiment of the present invention is used for a pixel circuit of the display device, the area occupied by the pixel circuit can be reduced and the display device can have high resolution, for example. When the semiconductor device of one embodiment of the present invention is used for a driver circuit (e.g., one or both of a gate line driver circuit and a source line driver circuit) of the display device, the area occupied by the driver circuit can be reduced and the display device can have a narrow bezel, for example. Since the semiconductor device of one embodiment of the present invention has favorable electrical characteristics, a display device can have increased reliability by using the semiconductor device.

The display portion 162 of the display device 100A is a region where an image is to be displayed, and includes a plurality of pixels 210 that are periodically arranged. FIG. 15 illustrates an enlarged view of one of the pixels 210.

There is no particular limitation on the arrangement of the pixels in the display device of this embodiment, and any of a variety of arrangements can be employed. Examples of the arrangement of the pixels include stripe arrangement, S-stripe arrangement, matrix arrangement, delta arrangement, Bayer arrangement, and PenTile arrangement.

The pixel 210 illustrated in FIG. 15 includes a subpixel 210R that emits red light, a subpixel 210G that emits green light, and a subpixel 210B that emits blue light.

Any of a variety of elements can be used as the display element, and a liquid crystal element or a light-emitting element can be used, for example. Alternatively, a MEMS (Micro Electro Mechanical Systems) shutter element, an optical interference type MEMS element, or a display element using a microcapsule method, an electrophoretic method, an electrowetting method, an Electronic Liquid Powder (registered trademark) method, or the like can be used. Alternatively, a QLED (quantum-dot LED) employing a light source and color conversion technology using quantum dot materials may be used.

Examples of a liquid crystal element include a transmissive liquid crystal element, a reflective liquid crystal element, and a transflective liquid crystal element.

Examples of light-emitting elements are self-luminous type light-emitting elements such as an LED (Light Emitting Diode), an OLED (Organic LED), and a semiconductor laser. As the LED, for example, a mini LED, a micro LED, or the like can be used.

Examples of a light-emitting substance included in the light-emitting element include a substance that emits fluorescent light (a fluorescent material), a substance that emits phosphorescent light (a phosphorescent material), a substance that exhibits thermally activated delayed fluorescence (a thermally activated delayed fluorescence (TADF) material), and an inorganic compound (e.g., a quantum dot material).

The light-emitting element can emit infrared, red, green, blue, cyan, magenta, yellow, or white light, for example. When the light-emitting element has a microcavity structure, higher color purity can be achieved.

One of the pair of electrodes of the light-emitting element functions as an anode, and the other electrode functions as a cathode. The display device of one embodiment of the present invention can have any of the following structures: a top-emission structure in which light is emitted in a direction opposite to the substrate where the light-emitting element is formed, a bottom-emission structure in which light is emitted toward the substrate where the light-emitting element is formed, and a dual-emission structure in which light is emitted toward both surfaces.

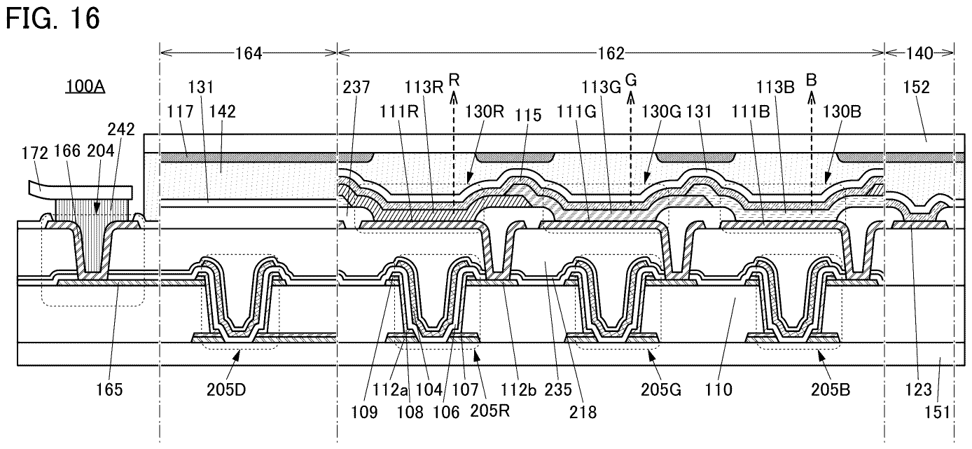

FIG. 16 illustrates an example of cross sections of part of a region including the FPC 172, part of the circuit portion 164, part of the display portion 162, part of the connection portion 140, and part of a region including the end portion of the display device 100A.

The display device 100A illustrated in FIG. 16 includes transistors 205D, 205R, 205G, and 205B, a light-emitting element 130R, a light-emitting element 130G, a light-emitting element 130B, and the like between the substrates 151 and the substrate 152. The light-emitting elements 130R, 130G, and 130B are display elements included in the subpixel 210R that emits red light, the subpixel 210G that emits green light, and the subpixel 210B that emits blue light, respectively.

The display device 100A employs an SBS structure. The SBS structure can optimize materials and structures of light-emitting elements and thus can extend freedom of choice of materials and structures, whereby the luminance and the reliability can be easily improved.

The display device 100A has a top-emission structure. The aperture ratio of pixels in a top-emission structure can be higher than that of pixels in a bottom-emission structure because a transistor and the like can be provided so as to overlap with a light-emitting region of a light-emitting element in the top-emission structure.

All of the transistors 205D, 205R, 205G, and 205B are formed over the substrate 151. These transistors can be manufactured using the same process.

In this embodiment of the present invention, an example is described in which transistors 205D, 205R, 205G, and 205B each use the transistor of one embodiment of the present invention, in which an oxide semiconductor is applied to the semiconductor and the parasitic capacitance is reduced. The transistors 205R, 205G, and 205B function as, for example, driving transistors controlling current flowing through the light-emitting elements. The transistor 205D provided in the circuit portion 164 form part of the driver circuit.

Specifically, each of the transistors 205D, 205R, 205G, and 205B includes a conductive layer 104 functioning as a gate, an insulating layer 106 functioning as a gate insulating layer, a conductive layer 109 functioning as one of a source electrode and a drain electrode, a conductive layer 107 functioning as the other of the source electrode and the drain electrode, a semiconductor layer 108, an insulating layer 110, and the like. The conductive layer 109 and the conductive layer 107 are in contact with the semiconductor layer 108. In addition, a conductive layer 112a in contact with the conductive layer 107 and a conductive layer 112b in contact with the conductive layer 109 are provided. Each of the conductive layer 112a and the conductive layer 112b includes a conductive material having lower resistance than the conductive layer 107 and the conductive layer 109 and serves as a wiring. Here, a plurality of layers obtained by processing one film are shown with the same hatching pattern.

As described above, the display device 100A includes any of the transistors of embodiments of the present invention in both the display portion 162 and the circuit portion 164. When the display portion 162 includes the transistor of one embodiment of the present invention, the pixel size can be reduced and high resolution can be achieved. When the circuit portion 164 includes the transistor of one embodiment of the present invention, the area occupied by the circuit portion 164 can be reduced and a narrower bezel can be achieved. When one or both of the display portion 162 and the circuit portion 164 include the transistors of one embodiment of the present invention, the load of wirings can be reduced; thus, a display device capable of high-speed operation, a large-sized display device, or a display device with high resolution (with a large number of pixels) can be achieved. The description in the above embodiment can be referred to for the transistor of one embodiment of the present invention.

Note that the transistor included in the display device of this embodiment is not limited to the transistor of one embodiment of the present invention. For example, the display device of this embodiment may include the transistor of one embodiment of the present invention and a transistor having another structure in combination.

The display device of this embodiment may include one or more of a planar transistor, a staggered transistor, and an inverted staggered transistor. A transistor included in the display device of this embodiment may have a top-gate structure or a bottom-gate structure. Gates may be provided above and below a semiconductor layer where a channel is formed.

A transistor including silicon in its channel formation region (a Si transistor) may be included in the display device of this embodiment. Examples of silicon include single crystal silicon, polycrystalline silicon, and amorphous silicon. In particular, a transistor containing LTPS in its semiconductor layer (hereinafter also referred to as an LTPS transistor) can be used. The LTPS transistor has high field-effect mobility and excellent frequency characteristics. The transistor containing amorphous silicon in the semiconductor layer, which can be uniformly formed over a large-area glass substrate, is excellent in productivity.

The display device of this embodiment may include a transistor using an oxide semiconductor (OS) typified by an In—Ga—Zn oxide (also referred to as IGZO) in the channel formation region (an OS transistor). For example, both a transistor containing silicon in its semiconductor where a channel is formed and a transistor containing an oxide semiconductor may be included in the display device.

The transistor included in the circuit portion 164 and the transistor included in the display portion 162 may have the same structure or different structures. One structure or two or more kinds of structures may be employed for a plurality of transistors included in the circuit portion 164. Similarly, one structure or two or more kinds of structures may be employed for a plurality of transistors included in the display portion 162.

All of the transistors included in the display portion 162 may be OS transistors or all of the transistors included in the display portion 162 may be Si transistors; alternatively, some of the transistors included in the display portion 162 may be OS transistors and the others may be Si transistors.

For example, when both an LTPS transistor and an OS transistor are used in the display portion 162, the display device can have low power consumption and high drive capability. Note that a structure in which an LTPS transistor and an OS transistor are used in combination is referred to as LTPO in some cases. As a favorable example, a structure is given in which an OS transistor is used as a transistor functioning as a switch for controlling electrical continuity and discontinuity between wirings and an LTPS transistor is used as a transistor for controlling a current.

For example, one transistor included in the display portion 162 functions as a transistor for controlling a current flowing through the light-emitting element and can also be referred to as a driving transistor. One of a source and a drain of the driving transistor is electrically connected to a pixel electrode of the light-emitting element.

By contrast, another transistor included in the display portion 162 functions as a switch for controlling selection or non-selection of a pixel and can also be referred to as a selection transistor. A gate of the selection transistor is electrically connected to a gate line, and one of a source and a drain thereof is electrically connected to a source line (signal line). An OS transistor is preferably used as the selection transistor. Accordingly, the gray level of the pixel can be maintained even with an extremely low frame frequency (e.g., lower than or equal to 1 fps); thus, power consumption can be reduced by stopping the driver in displaying a still image.

An insulating layer 218 is provided to cover the transistors 205D, 205R, 205G, and 205B and an insulating layer 235 is provided over the insulating layer 218.

The insulating layer 218 preferably functions as a protective layer of the transistors. A material that does not easily allow diffusion of impurities such as water and hydrogen is preferably used for the insulating layer 218. This is because the insulating layer 218 can function as a barrier layer. Such a structure can effectively inhibit diffusion of impurities into the transistors from the outside and increase the reliability of the display device.

The insulating layer 218 preferably includes one or more inorganic insulating films. Examples of the inorganic insulating film include an oxide insulating film, a nitride insulating film, an oxynitride insulating film, and a nitride oxide insulating film. Specific examples of these inorganic insulating films are as described above.

The insulating layer 235 preferably has a function of a planarization layer, and an organic insulating film is suitably used. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins. Alternatively, the insulating layer 235 may have a stacked-layer structure of an organic insulating film and an inorganic insulating film. The outermost layer of the insulating layer 235 preferably functions as an etching protective layer. In that case, the formation of a depression in the insulating layer 235 can be inhibited in processing pixel electrodes 111R, 111G, and 111B, for example. Alternatively, a depression may be formed in the insulating layer 235 in processing the pixel electrodes 111R, 111G, and 111B, for example.

The light-emitting elements 130R, 130G, and 130B are provided over the insulating layer 235.

The light-emitting element 130R includes the pixel electrode 111R over the insulating layer 235, an EL layer 113R over the pixel electrode 111R, and a common electrode 115 over the EL layer 113R. The light-emitting element 130R illustrated in FIG. 16 emits red light (R). The EL layer 113R includes a light-emitting layer that emits red light.

In a similar manner, the light-emitting element 130G includes the pixel electrode 111G, an EL layer 113G, and the common electrode 115. The light-emitting element 130G emits green light (G) and the EL layer 113G includes a light-emitting layer that emits green light.

In a similar manner, the light-emitting element 130B includes the pixel electrode 111B, an EL layer 113B, and the common electrode 115. The light-emitting element 130B emits blue light (B) and the EL layer 113B includes a light-emitting layer that emits blue light.

Although the EL layers 113R, 113G, and 113B have the same thickness in FIG. 16, the present invention is not limited thereto. The EL layers 113R, 113G, and 113B may have different thicknesses. For example, the thicknesses of the EL layers 113R, 113G, and 113B are preferably set to match an optical path length that intensifies light emitted from each EL layer. In that case, a microcavity structure is obtained, and the color purity of light emitted from each light-emitting element can be improved.

The pixel electrode 111R is electrically connected to the conductive layer 112b included in the transistor 205R through an opening provided in the insulating layer 106, the insulating layer 218, and the insulating layer 235. In a similar manner, the pixel electrode 111G is electrically connected to the conductive layer 112b included in the transistor 205G and the pixel electrode 111B is electrically connected to the conductive layer 112b included in the transistor 205B.

End portions of the pixel electrodes 111R, 111G, and 111B are covered with an insulating layer 237. The insulating layer 237 functions as a partition wall (also referred to as an embankment, a bank, or a spacer). The insulating layer 237 can have a single-layer structure or a stacked-layer structure including one or both of an inorganic insulating material and an organic insulating material. A material that can be used for the insulating layer 218 and a material that can be used for the insulating layer 235 can be used for the insulating layer 237, for example. The insulating layer 237 can electrically isolate the pixel electrode and the common electrode. Furthermore, the insulating layer 237 can electrically isolate light-emitting elements adjacent to each other.

The common electrode 115 is one continuous film shared by the light-emitting elements 130R, 130G, and 130B. The common electrode 115 shared by the light-emitting elements is electrically connected to a conductive layer 123 provided in the connection portion 140. The conductive layer 123 is preferably formed using a conductive layer formed using the same material through the same process as the pixel electrodes 111R, 111G, and 111B.

In the display device of one embodiment of the present invention, a conductive film that transmits visible light is used for the electrode through which light is extracted, which is either the pixel electrode or the common electrode. A conductive film reflecting visible light is preferably used for the electrode through which light is not extracted.

A conductive film that transmits visible light may be used also for the electrode through which light is not extracted. In that case, this electrode is preferably provided between a reflective layer and the EL layer. In other words, light emitted by the EL layer may be reflected by the reflective layer to be extracted from the display device.

As the material of the pair of electrodes of the light-emitting element, a metal, an alloy, an electrically conductive compound, a mixture thereof, or the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include indium tin oxide (also referred to as In—Sn oxide or ITO), In—Si—Sn oxide (also referred to as ITSO), indium zinc oxide (In—Zn oxide), and In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium (Mg—Ag) and an alloy of silver, palladium, and copper (also referred to as Ag—Pd—Cu or APC). Other examples of the material include an element belonging to Group 1 or Group 2 of the periodic table that is not described above (e.g., lithium, cesium, calcium, or strontium), a rare earth metal such as europium or ytterbium, an alloy containing an appropriate combination of any of these elements, and graphene.

The light-emitting element preferably employs a microcavity structure. Therefore, one of the pair of electrodes of the light-emitting element is preferably an electrode having properties of transmitting and reflecting visible light (a transflective electrode), and the other is preferably an electrode having a property of reflecting visible light (a reflective electrode). When the light-emitting element has a microcavity structure, light obtained from the light-emitting layer can be resonated between the electrodes, whereby light emitted from the light-emitting element can be intensified.

The transparent electrode has a light transmittance higher than or equal to 40%. For example, an electrode having a visible light (light with wavelengths greater than or equal to 400 nm and less than 750 nm) transmittance higher than or equal to 40% is preferably used as the transparent electrode of the light-emitting element. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity lower than or equal to 1×10⁻² Ωcm.

The EL layers 113R, 113G, and 113B are each provided to have an island shape. In FIG. 16, an end portion of the EL layer 113R and an end portion of the EL layer 113G adjacent to each other overlap with each other, an end portion of the EL layer 113G and an end portion of the EL layer 113B adjacent to each other overlap with each other, and an end portion of the EL layer 113R and an end portion of the EL layer 113B adjacent to each other overlap with each other. When island-shaped EL layers are formed using a fine metal mask, end portions of the EL layers adjacent to each other may overlap with each other as illustrated in FIG. 16; however, the present invention is not limited thereto. That is, it is also possible that the EL layers adjacent to each other do not overlap with each other and are apart from each other. It is also possible that the display device includes both a portion where the EL layers adjacent to each other overlap with each other and a portion where the EL layers adjacent to each other do not overlap with each other and are apart from each other.

Each of the EL layers 113R, 113G, and 113B includes at least a light-emitting layer. The light-emitting layer contains one or more kinds of light-emitting substances. As the light-emitting substance, a substance whose emission color is blue, violet, bluish violet, green, yellowish green, yellow, orange, red, or the like is appropriately used. Alternatively, as the light-emitting substance, a substance that emits near-infrared light can be used.

Examples of the light-emitting substance include a fluorescent material, a phosphorescent material, a TADF material, and a quantum dot material.

The light-emitting layer may contain one or more kinds of organic compounds (e.g., a host material or an assist material) in addition to the light-emitting substance (a guest material). As one or more kinds of organic compounds, one or both of a substance with a high hole-transport property (a hole-transport material) and a substance with a high electron-transport property (an electron-transport material) can be used. As the one or more kinds of organic compounds, a substance with a bipolar property (also referred to as a substance with a high electron-transport property and a high hole-transport property or a bipolar material) or a TADF material may be used.

The light-emitting layer preferably includes a phosphorescent material and a combination of a hole-transport material and an electron-transport material that easily forms an exciplex, for example. With such a structure, light emission can be efficiently obtained by ExTET (Exciplex-Triplet Energy Transfer), which is energy transfer from the exciplex to the light-emitting substance (phosphorescent material). When a combination of materials is selected so as to form an exciplex that emits light whose wavelength overlaps with the wavelength of a lowest-energy-side absorption band of the light-emitting substance, energy can be transferred smoothly and light emission can be obtained efficiently. With this structure, high efficiency, low-voltage driving, and a long lifetime of the light-emitting element can be achieved at the same time.

In addition to the light-emitting layer, the EL layer can include one or more of a layer containing a substance having a high hole-injection property (a hole-injection layer), a layer containing a hole-transport material (a hole-transport layer), a layer containing a substance having a high electron-blocking property (an electron-blocking layer), a layer containing a substance having a high electron-injection property (an electron-injection layer), a layer containing an electron-transport material (an electron-transport layer), and a layer containing a substance having a high hole-blocking property (a hole-blocking layer). The EL layer may further include one or both of a bipolar material and a TADF material.

Either a low molecular compound or a high molecular compound can be used in the light-emitting element, and an inorganic compound may also be included. Each layer included in the light-emitting element can be formed by any of the following methods: an evaporation method (including a vacuum evaporation method), a transfer method, a printing method, an inkjet method, a coating method, and the like.

The light-emitting element may employ a single structure (a structure including only one light-emitting unit) or a tandem structure (a structure including a plurality of light-emitting units). The light-emitting unit includes at least one light-emitting layer. In a tandem structure, a plurality of light-emitting units are connected in series with a charge-generation layer therebetween. The charge-generation layer has a function of injecting electrons into one of two light-emitting units and injecting holes to the other when a voltage is applied between the pair of electrodes. A tandem structure enables a light-emitting element capable of emitting light with high luminance. Furthermore, the amount of current needed for obtaining a predetermined luminance can be smaller in a tandem structure than in a single structure; thus, a tandem structure enables higher reliability. A tandem structure may be referred to as a stack structure.

In the case of using a tandem light-emitting element in FIG. 16, the EL layer 113R preferably includes a plurality of light-emitting units that emit red light, the EL layer 113G preferably includes a plurality of light-emitting units that emit green light, and the EL layer 113B preferably includes a plurality of light-emitting units that emit blue light.

A protective layer 131 is provided over the light-emitting elements 130R, 130G, and 130B. The protective layer 131 and the substrate 152 are bonded to each other with an adhesive layer 142. The substrate 152 is provided with a light-blocking layer 117. A solid sealing structure, a hollow sealing structure, or the like can be employed to seal the light-emitting elements. In FIG. 16, a solid sealing structure is employed, in which a space between the substrate 152 and the substrate 151 is filled with the adhesive layer 142. Alternatively, a hollow sealing structure may be employed, in which the space is filled with an inert gas (e.g., nitrogen or argon). In that case, the adhesive layer 142 may be provided not to overlap with the light-emitting element. Furthermore, the space may be filled with a resin other than the frame-shaped adhesive layer 142.

The protective layer 131 is provided at least in the display portion 162, and preferably provided to cover the entire display portion 162. By providing the protective layer 131 over the light-emitting elements 130R, 130G, and 130B, the reliability of the light-emitting elements can be increased. The protective layer 131 is preferably provided to cover not only the display portion 162 but also the connection portion 140 and the circuit portion 164. It is also preferable that the protective layer 131 be provided to extend to an end portion of the display apparatus 100A. Meanwhile, a connection portion 204 has a portion not provided with the protective layer 131 so that the FPC 172 and a conductive layer 166 are electrically connected to each other.

The protective layer 131 may have a single-layer structure or a stacked-layer structure of two or more layers. There is no limitation on the conductivity of the protective layer 131. For the protective layer 131, at least one of an insulating film, a semiconductor film, and a conductive film can be used. The protective layer 131 including an inorganic film can inhibit deterioration of the light-emitting elements by preventing oxidation of the common electrode 115 and inhibiting entry of impurities (e.g., moisture and oxygen) into the light-emitting elements, for example; thus, the reliability of the display device can be improved. For the protective layer 131, an inorganic insulating film such as an oxide insulating film, a nitride insulating film, an oxynitride insulating film, or a nitride oxide insulating film can be used, for example. Specific examples of these inorganic insulating films are as described above. In particular, the protective layer 131 preferably includes a nitride insulating film or a nitride oxide insulating film, and further preferably includes a nitride insulating film.

An inorganic film containing ITO, In—Zn oxide, Ga—Zn oxide, Al—Zn oxide, IGZO, or the like can be used for the protective layer 131. The inorganic film preferably has high resistance, specifically, higher resistance than the common electrode 115. The inorganic film may further contain nitrogen.

When light emitted from the light-emitting element is extracted through the protective layer 131, the protective layer 131 preferably has a good visible-light-transmitting property. For example, ITO, IGZO, and aluminum oxide are preferable because they are inorganic materials having a good visible-light-transmitting property.

The protective layer 131 can be, for example, a stack of an aluminum oxide film and a silicon nitride film over the aluminum oxide film, or a stack of an aluminum oxide film and an IGZO film over the aluminum oxide film. Such a stacked-layer structure can inhibit entry of impurities (e.g., water and oxygen) into the EL layer side.

Furthermore, the protective layer 131 may include an organic film. For example, the protective layer 131 may include both an organic film and an inorganic film. Examples of an organic film that can be used for the protective layer 131 include organic insulating films that can be used for the insulating layer 235.

The connection portion 204 is provided in a region of the substrate 151 not overlapping with the substrate 152. In the connection portion 204, the wiring 165 is electrically connected to the FPC 172 through the conductive layer 166 and a connection layer 242. In this example, the wiring 165 is a single conductive layer obtained by processing the same conductive film as the conductive layer 112b. In this example, the conductive layer 166 is a single conductive layer obtained by processing the same conductive film as the pixel electrodes 111R, 111G, and 111B. On the top surface of the connection portion 204, the conductive layer 166 is exposed. Thus, the connection portion 204 and the FPC 172 can be electrically connected to each other through the connection layer 242.

The display apparatus 100A has a top-emission structure. Light from the light-emitting element is emitted toward the substrate 152. For the substrate 152, a material having a good visible-light-transmitting property is preferably used. The pixel electrodes 111R, 111G, and 111B contain a material that reflects visible light, and the counter electrode (the common electrode 115) contains a material that transmits visible light.

The light-blocking layer 117 is preferably provided on the surface of the substrate 152 on the substrate 151 side. The light-blocking layer 117 can be provided between adjacent light-emitting elements, in the connection portion 140, in the circuit portion 164, and the like.

A coloring layer such as a color filter may be provided on the surface of the substrate 152 on the substrate 151 side or over the protective layer 131. When the color filter is provided so as to overlap with the light-emitting element, the color purity of light emitted from the pixel can be increased.

Moreover, a variety of optical members can be provided on the outer surface of the substrate 152 (the surface opposite to the substrate 151). Examples of the optical members include a polarizing plate, a retardation plate, a light diffusion layer (e.g., a diffusion film), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be provided as a surface protective layer on the outer surface of the substrate 152. For example, a glass layer or a silica layer (SiOₓ layer) is preferably provided as the surface protective layer to inhibit the surface contamination and damage. For the surface protective layer, DLC (diamond-like carbon), aluminum oxide (AlOₓ), a polyester-based material, a polycarbonate-based material, or the like may be used. The surface protective layer is preferably formed using a material having high visible light transmittance. The surface protective layer is preferably formed using a material with high hardness.

For each of the substrate 151 and the substrate 152, glass, quartz, ceramics, sapphire, a resin, a metal, an alloy, a semiconductor, or the like can be used. For the substrate on the side from which light from the light-emitting element is extracted, a material that transmits the light is used. When the substrate 151 and the substrate 152 are formed using a flexible material, the flexibility of the display device can be increased and a flexible display can be achieved. Furthermore, a polarizing plate may be used as at least one of the substrate 151 and the substrate 152.

For each of the substrate 151 and the substrate 152, a polyester resin such as polyethylene terephthalate (PET) or polyethylene naphthalate (PEN), a polyacrylonitrile resin, an acrylic resin, a polyimide resin, a polymethyl methacrylate resin, a polycarbonate (PC) resin, a polyether sulfone (PES) resin, a polyamide resin (e.g., nylon or aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, or cellulose nanofiber can be used, for example. Glass that is thin enough to have flexibility may be used for at least one of the substrate 151 and the substrate 152.

In the case where a circularly polarizing plate overlaps with the display device, a highly optically isotropic substrate is preferably used as the substrate included in the display device. A highly optically isotropic substrate has a low birefringence (in other words, a small amount of birefringence). Examples of the film having high optical isotropy include a triacetyl cellulose (TAC, also referred to as cellulose triacetate) film, a cycloolefin polymer (COP) film, a cycloolefin copolymer (COC) film, and an acrylic film.

As the adhesive layer 142, any of a variety of curable adhesives such as a reactive curable adhesive, a thermosetting curable adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. A two-component-mixture-type resin may be used. An adhesive sheet or the like may be used.

As the connection layer 242, an anisotropic conductive film (ACF), an anisotropic conductive paste (ACP), or the like can be used.

### [Display Device 100B]

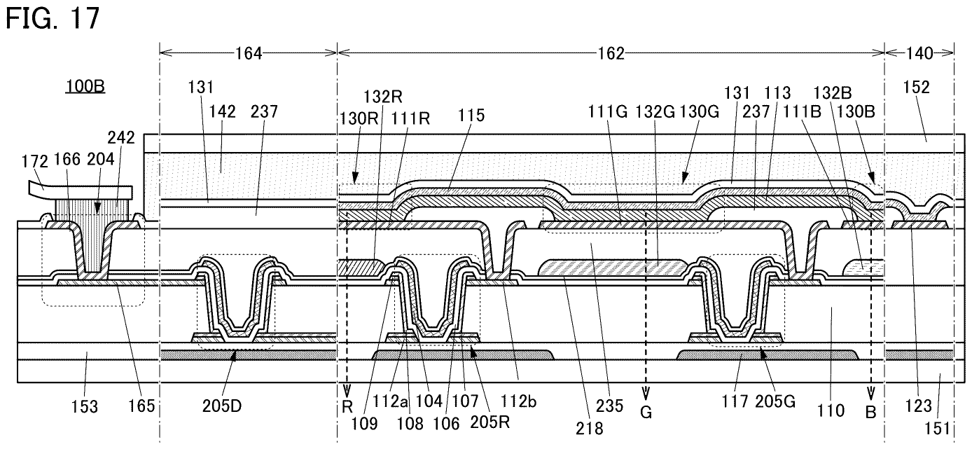

A display device 100B illustrated in FIG. 17 is different from the display device 100A mainly in a bottom-emission display device and in including an EL layer 113 shared by the light-emitting elements and coloring layers (color filters or the like) in the subpixels of different colors. Note that in the following description of display devices, the description of portions similar to those of the above-described display device may be omitted.

Light from the light-emitting element is emitted toward the substrate 151. For the substrate 151, a material having a good visible-light-transmitting property is preferably used. By contrast, there is no limitation on the light-transmitting property of a material used for the substrate 152.

In the display device 100B illustrated in FIG. 17, the transistor 205D, the transistor 205R, the transistor 205G, the transistor 205B (not illustrated), the light-emitting elements 130R, 130G, and 130B, a coloring layer 132R transmitting red light, a coloring layer 132G transmitting green light, a coloring layer 132B transmitting blue light, and the like are provided between the substrate 151 and the substrate 152.

The light-emitting element 130R includes the pixel electrode 111R, the EL layer 113 over the pixel electrode 111R, and the common electrode 115 over the EL layer 113. Light emitted from the light-emitting element 130R is extracted as red light to the outside of the display device 100B through the coloring layer 132R.

The light-emitting element 130G includes the pixel electrode 111G, the EL layer 113 over the pixel electrode 111G, and the common electrode 115 over the EL layer 113. Light emitted from the light-emitting element 130G is extracted as green light to the outside of the display device 100B through the coloring layer 132G.

The light-emitting element 130B includes the pixel electrode 111B, the EL layer 113 over the pixel electrode 111B, and the common electrode 115 over the EL layer 113. Light emitted from the light-emitting element 130B is extracted as blue light to the outside of the display device 100B through the coloring layer 132B.

The EL layer 113 and the common electrode 115 are shared between the light-emitting elements 130R, 130G, and 130B. The number of manufacturing processes can be smaller in the case where the EL layer 113 is shared between the subpixels of different colors than the case where the subpixels of different colors include different EL layers.

The light-emitting elements 130R, 130G, and 130B illustrated in FIG. 17 emit white light, for example. When white light emitted from the light-emitting elements 130R, 130G, and 130B passes through the coloring layers 132R, 132G, and 132n, light of desired colors can be obtained.

The light-blocking layer 117 is preferably formed between the substrate 151 and the transistor. FIG. 17 illustrates an example where the light-blocking layer 117 are provided over the substrate 151, an insulating layer 153 is provided over the light-blocking layer 117, and the transistor 205D, the transistor 205R, the transistor 205G, the transistor 205B (not illustrated), and the like are provided over the insulating layer 153. In addition, the coloring layer 132R, the coloring layer 132G, and the coloring layer 132B are provided over the insulating layer 218 and the insulating layer 235 is provided over the coloring layer 132R, the coloring layer 132G, and the coloring layer 132B.

A material having a high visible-light-transmitting property is used for each of the pixel electrodes 111R, 111G, and 111B. A material that reflects visible light is preferably used for the common electrode 115. In the bottom-emission display device, a metal or the like having low resistance can be used for the common electrode 115; thus, a voltage drop due to the resistance of the common electrode 115 can be suppressed and the display quality can be high.

The transistor of one embodiment of the present invention can be miniaturized and the area occupied by the transistor can be reduced, so that the aperture ratio of the pixel can be increased or the pixel size can be reduced in the display device having a bottom-emission structure.

In the case of employing a microcavity structure, the light-emitting elements 130R, 130G, and 130B each emit light with a specific wavelength, which is intensified, in white light emitted from the EL layer 113. Here, even with such a microcavity structure, a light-emitting element including an EL layer that emits white light is referred to as a white-light-emitting element.

In the light-emitting element that emits white light, two or more light-emitting layers are preferably included. When two light-emitting layers are used to obtain white light, two light-emitting layers that emit light of complementary colors are selected. For example, when the emission colors of the first light-emitting layer and the second light-emitting layer are made complementary, the light-emitting element can be configured to emit white light as a whole. In the case where three or more light-emitting layers are used to obtain white light, the light-emitting element is configured to emit white light as a whole by combining emission colors of the three or more light-emitting layers.

For example, the EL layer 113 preferably includes a light-emitting layer containing a light-emitting substance that emits blue light and a light-emitting layer containing a light-emitting substance that emits visible light having a longer wavelength than blue light. The EL layer 113 preferably includes a light-emitting layer that emits yellow light and a light-emitting layer that emits blue light, for example. Alternatively, the EL layer 113 preferably includes a light-emitting layer that emits red light, a light-emitting layer that emits green light, and a light-emitting layer that emits blue light, for example.

A light-emitting element that emits white light preferably has a tandem structure. Specific examples include a two-unit tandem structure including a light-emitting unit that emits yellow light and a light-emitting unit that emits blue light; a two-unit tandem structure including a light-emitting unit that emits red light and green light and a light-emitting unit that emits blue light; a three-unit tandem structure in which a light-emitting unit that emits blue light, a light-emitting unit that emits yellow, yellow-green, or green light, and a light-emitting unit that emits blue light are stacked in this order; and a three-unit tandem structure in which a light-emitting unit that emits blue light, a light-emitting unit that emits yellow, yellow-green, or green light and red light, and a light-emitting unit that emits blue light are stacked in this order. Examples of the number of stacked light-emitting units and the order of colors from the anode side include a two-unit structure of B and Y; a two-unit structure of B and a light-emitting unit X; a three-unit structure of B, Y, and B; and a three-unit structure of B, X, and B. Examples of the number of light-emitting layers stacked in the light-emitting unit X and the order of colors from an anode side include a two-layer structure of R and Y; a two-layer structure of R and G; a two-layer structure of G and R; a three-layer structure of G, R, and G; and a three-layer structure of R, G, and R. Another layer may be provided between two light-emitting layers.

Alternatively, the light-emitting elements 130R, 130G, and 130B illustrated in FIG. 17 may emit blue light, for example. In this case, the EL layer 113 includes one or more light-emitting layers that emit blue light. In the subpixel 210B that emits blue light, blue light emitted from the light-emitting element 130B can be extracted. In each of the subpixel 210R that emits red light and the subpixel 210G that emits green light, a color conversion layer is provided between the light-emitting element 130R or 130G and the substrate 151 so that blue light emitted from the light-emitting element 130R or 130G is converted into light with a longer wavelength, whereby red light or green light can be extracted. Furthermore, it is preferable that the coloring layer 132R be provided between the color conversion layer and the substrate 151 on an optical path of light emitted by the light-emitting element 130R, and the coloring layer 132G be provided between the color conversion layer and the substrate 151 on an optical path of light emitted by the light-emitting element 130G. In some cases, part of light emitted from the light-emitting element is transmitted through the color conversion layer without being converted. When light transmitted through the color conversion layer is extracted through the coloring layer, light other than light of the intended color can be absorbed by the coloring layer, and color purity of light exhibited by a subpixel can be improved.

### [Display Device 100C]

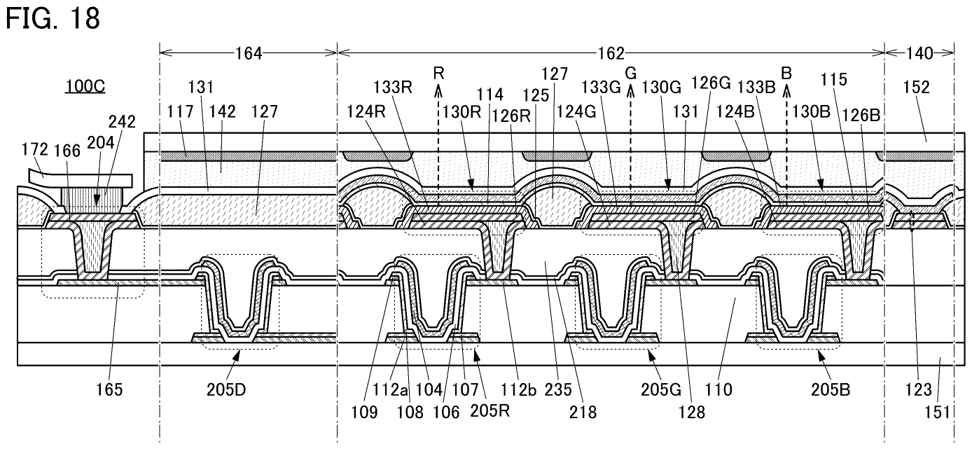

A display device 100C illustrated in FIG. 18 is an example of a display device having an MML (metal maskless) structure. In other words, the display device 100C includes a light-emitting element that is formed without using a fine metal mask. The stacked-layer structure from the substrate 151 to the insulating layer 235 and the stacked-layer structure from the protective layer 131 to the substrate 152 are similar to those in the display device 100A; therefore, description thereof is omitted.

In FIG. 18, the light-emitting elements 130R, 130G, and 130B are provided over the insulating layer 235.

The light-emitting element 130R includes a conductive layer 124R over the insulating layer 235, a conductive layer 126R over the conductive layer 124R, a layer 133R over the conductive layer 126R, a common layer 114 over the layer 133R, and the common electrode 115 over the common layer 114. The light-emitting element 130R illustrated in FIG. 18 emits red light (R). The layer 133R includes a light-emitting layer that emits red light. In the light-emitting element 130R, the layer 133R and the common layer 114 can be collectively referred to as an EL layer. One or both of the conductive layer 124R and the conductive layer 126R can be referred to as a pixel electrode.

In a similar manner, the light-emitting element 130G includes a conductive layer 124G over the insulating layer 235, a conductive layer 126G over the conductive layer 124G, a layer 133G over the conductive layer 126G, the common layer 114 over the layer 133G, and the common electrode 115 over the common layer 114. The light-emitting element 130G illustrated in FIG. 18 emits green light (G). The layer 133G includes a light-emitting layer that emits green light.

In a similar manner, the light-emitting element 130B includes a conductive layer 124B over the insulating layer 235, a conductive layer 126B over the conductive layer 124B, a layer 133B over the conductive layer 126B, the common layer 114 over the layer 133B, and the common electrode 115 over the common layer 114. The light-emitting element 130B illustrated in FIG. 18 emits blue light (B). The layer 133B includes a light-emitting layer that emits blue light.

In this specification and the like, in the EL layers included in the light-emitting elements, the island-shaped layer provided in each light-emitting element is referred to as the layer 133B, the layer 133G, or the layer 133R, and the layer shared by the light-emitting elements is referred to as the common layer 114. Note that in this specification and the like, only the layer 133R, the layer 133G, and the layer 133B are sometimes referred to as island-shaped EL layers, EL layers formed in an island shape, or the like, in which case the common layer 114 is not included in the EL layer.

The layer 133R, the layer 133G, and the layer 133B are isolated from each other. When the EL layer is provided to have an island shape for each light-emitting element, a leakage current between adjacent light-emitting elements can be inhibited. This can prevent crosstalk due to unintended light emission, so that a display apparatus with extremely high contrast can be obtained.

Although the layers 133R, 133G, and 133B have the same thickness in FIG. 18, the present invention is not limited thereto. The layers 133R, 133G, and 133B may have different thicknesses.

The conductive layer 124R is electrically connected to the conductive layer 112b included in the transistor 205R through an opening provided in the insulating layer 106, the insulating layer 218, and the insulating layer 235. In a similar manner, the conductive layer 124G is electrically connected to the conductive layer 112b included in the transistor 205G and the conductive layer 124B is electrically connected to the conductive layer 112b included in the transistor 205B.

The conductive layers 124R, 124G, and 124B are formed to cover the openings provided in the insulating layer 235. A layer 128 is embedded in each of the depressions of the conductive layers 124R, 124G, and 124B.

The layer 128 has a function of filling the depressions of the conductive layers 124R, 124G, and 124B. The conductive layers 126R, 126G, and 126B electrically connected to the conductive layers 124R, 124G, and 124B, respectively, are provided over the conductive layers 124R, 124G, and 124B and the layer 128. Thus, regions overlapping with the depressions of the conductive layers 124R, 124G, and 124B can also be used as the light-emitting regions, increasing the aperture ratio of the pixels. The conductive layer 124R and the conductive layer 126R each preferably include a conductive layer functioning as a reflective electrode.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. For the layer 128, an organic insulating material that can be used for the insulating layer 237 can be used, for example.

Although FIG. 18 illustrates an example where the top surface of the layer 128 includes a flat portion, the shape of the layer 128 is not particularly limited. The top surface of the layer 128 may include at least one of a convex surface, a concave surface, and a flat surface.

The level of the top surface of the layer 128 and the level of the top surface of the conductive layer 124R may be the same or substantially the same, or may be different from each other. For example, the level of the top surface of the layer 128 may be either lower or higher than the level of the top surface of the conductive layer 124R.

An end portion of the conductive layer 126R may be aligned with an end portion of the conductive layer 124R or may cover the side surface of the end portion of the conductive layer 124R. The end portions of the conductive layer 124R and the conductive layer 126R each preferably have a tapered shape. Specifically, the end portions of the conductive layer 124R and the conductive layer 126R each preferably have a tapered shape with a taper angle less than 90°. In the case where the end portions of the pixel electrodes have a tapered shape, the layer 133R provided along the side surfaces of the pixel electrodes has an inclined portion. When the side surface of the pixel electrode has a tapered shape, coverage with an EL layer provided along the side surface of the pixel electrode can be improved.

Since the conductive layers 124G and 126G and the conductive layers 124B and 126B are similar to the conductive layers 124R and 126R, the detailed description thereof is omitted.

The top surface and side surface of the conductive layer 126R are covered with the layer 133R. Similarly, the top surface and side surface of the conductive layers 126G are covered with the layer 133G, and the top surface and side surface of the conductive layers 126B are covered with the layer 133B. Accordingly, regions provided with the conductive layers 126R, 126G, and 126B can be entirely used as the light-emitting regions of the light-emitting elements 130R, 130G, and 130B, thereby increasing the aperture ratio of the pixels.

The side surface and part of the top surface of each of the layer 133R, the layer 133G, and the layer 133B are covered with insulating layers 125 and 127. The common layer 114 is provided over the layer 133R, the layer 133G, the layer 133B, the insulating layer 125, and the insulating layer 127, and the common electrode 115 is provided over the common layer 114. The common layer 114 and the common electrode 115 are each a continuous film provided to be shared by a plurality of light-emitting elements.

In FIG. 18, the insulating layer 237 illustrated in FIG. 16 or the like is not provided between the conductive layer 126R and the layer 133R. That is, an insulating layer (also referred to as a partition wall, a bank, a spacer, or the like) in contact with the pixel electrode and covering an upper end portion of the pixel electrode is not provided in the display device 100C. Thus, the interval between adjacent light-emitting elements can be extremely shortened. Accordingly, the display device can have high resolution or high definition. In addition, a mask for forming the insulating layer is not needed, which leads to a reduction in manufacturing cost of the display device.

As described above, the layer 133R, the layer 133G, and the layer 133B each include the light-emitting layer. The layer 133R, the layer 133G, and the layer 133B each preferably include the light-emitting layer and a carrier-transport layer (an electron-transport layer or a hole-transport layer) over the light-emitting layer. Alternatively, the layer 133R, the layer 133G, and the layer 133B each preferably include a light-emitting layer and a carrier-blocking layer (a hole-blocking layer or an electron-blocking layer) over the light-emitting layer. Alternatively, the layer 133R, the layer 133G, and the layer 133B each preferably include a light-emitting layer, a carrier-blocking layer over the light-emitting layer, and a carrier-transport layer over the carrier-blocking layer. Since surfaces of the layer 133R, the layer 133G, and the layer 133B are exposed in the manufacturing process of the display device, providing one or both of the carrier-transport layer and the carrier-blocking layer over the light-emitting layer inhibits the light-emitting layer from being exposed on the outermost surface, so that damage to the light-emitting layer can be reduced. Thus, the reliability of the light-emitting element can be increased.

The common layer 114 includes, for example, an electron-injection layer or a hole-injection layer. Alternatively, the common layer 114 may be a stack of an electron-transport layer and an electron-injection layer, or may be a stack of a hole-transport layer and a hole-injection layer. The common layer 114 is shared by the light-emitting elements 130R, 130G, and 130B.

The side surfaces of the layer 133R, the layer 133G, and the layer 133B are each covered with the insulating layer 125. The insulating layer 127 covers the side surfaces of the layer 133R, the layer 133G, and the layer 133B with the insulating layer 125 therebetween.

The side surface and part of the top surface of each of the layer 133R, the layer 133G, and the layer 133B are covered with at least one of the insulating layer 125 and the insulating layer 127, so that the common layer 114 (or the common electrode 115) can be inhibited from being in contact with the side surfaces of the pixel electrodes and the layers 133R, 133G, and 133B, leading to inhibition of a short circuit of the light-emitting elements. Thus, the reliability of the light-emitting element can be increased.

The insulating layer 125 is preferably in contact with the side surfaces of the layer 133R, the layer 133G, and the layer 133B. The insulating layer 125 in contact with the layer 133R, the layer 133G, and the layer 133B can prevent film separation of the layer 133R, the layer 133G, and the layer 133B, whereby the reliability of the light-emitting element can be increased.

The insulating layer 127 is provided over the insulating layer 125 to fill a depression of the insulating layer 125. The insulating layer 127 preferably covers at least part of the side surface of the insulating layer 125.

The insulating layers 125 and the insulating layer 127 can fill a gap between adjacent island-shaped layers, whereby the formation surface of the layers (e.g., the carrier-injection layer and the common electrode) provided over the island-shaped layers can have higher flatness with small unevenness. Consequently, coverage with the carrier-injection layer, the common electrode, and the like can be improved.

The common layer 114 and the common electrode 115 are provided over the layer 133R, the layer 133G, the layer 133B, the insulating layer 125, and the insulating layer 127. Before the insulating layer 125 and the insulating layer 127 are provided, a step is generated due to a level difference between a region where the pixel electrode and the island-shaped EL layer are provided and a region where neither the pixel electrode nor the island-shaped EL layer is provided (a region between the light-emitting elements). In the display device of one embodiment of the present invention, the step can be eliminated with the insulating layer 125 and the insulating layer 127, and the coverage with the common layer 114 and the common electrode 115 can be improved. Thus, poor connection caused by step disconnection can be inhibited. In addition, an increase in electric resistance, which is caused by local thinning of the common electrode 115 due to the step, can be inhibited.

The top surface of the insulating layer 127 preferably has a shape with high flatness. The top surface of the insulating layer 127 may include at least one of a flat surface, a convex surface, and a concave surface. For example, the top surface of the insulating layer 127 preferably has a smooth convex shape with high flatness.

The insulating layer 125 can be formed using an inorganic material. For the insulating layer 125, an inorganic insulating film such as an oxide insulating film, a nitride insulating film, an oxynitride insulating film, or a nitride oxide insulating film can be used, for example. Specific examples of these inorganic insulating films are as described above. The insulating layer 125 may have a single-layer structure or a stacked-layer structure. In particular, aluminum oxide is preferable because it has high selectivity with respect to the EL layer in etching and has a function of protecting the EL layer in formation of the insulating layer 127. In particular, when an inorganic insulating film such as an aluminum oxide film, a hafnium oxide film, or a silicon oxide film is formed by an ALD method as the insulating layer 125, the insulating layer 125 can have few pinholes and an excellent function of protecting the EL layer. The insulating layer 125 may have a stacked-layer structure of a film formed by an ALD method and a film formed by a sputtering method. The insulating layer 125 may have a stacked-layer structure of an aluminum oxide film formed by an ALD method and a silicon nitride film formed by a sputtering method, for example.

The insulating layer 125 preferably has a function of a barrier insulating layer against at least one of water and oxygen. The insulating layer 125 preferably has a function of inhibiting diffusion of at least one of water and oxygen. Alternatively, the insulating layer 125 preferably has a function of capturing or fixing (also referred to as gettering) at least one of water and oxygen.

Note that in this specification and the like, a barrier insulating layer refers to an insulating layer having a barrier property. A barrier property in this specification and the like refers to a function of inhibiting diffusion of a targeted substance (also referred to as having low permeability). Alternatively, a barrier property refers to a function of capturing or fixing (also referred to as gettering) a targeted substance.

When the insulating layer 125 has a function of the barrier insulating layer or a gettering function, entry of impurities (typically, at least one of water and oxygen) that would be diffused into the light-emitting elements from the outside can be inhibited. With this structure, a highly reliable light-emitting element and a highly reliable display device can be provided.

The insulating layer 125 preferably has a low impurity concentration. Accordingly, degradation of the EL layer, which is caused by entry of impurities into the EL layer from the insulating layer 125, can be inhibited. In addition, when the impurity concentration is reduced in the insulating layer 125, a barrier property against at least one of water and oxygen can be increased. For example, the insulating layer 125 preferably has a sufficiently low hydrogen concentration or a sufficiently low carbon concentration, and further preferably has both a sufficiently low hydrogen concentration and a sufficiently low carbon concentration.

The insulating layer 127 provided over the insulating layer 125 has a function of filling large unevenness of the insulating layer 125, which is formed between the adjacent light-emitting elements. In other words, the insulating layer 127 has an effect of improving the planarity of the formation surface of the common electrode 115.

As the insulating layer 127, an insulating layer containing an organic material can be favorably used. As the organic material, a photosensitive organic resin is preferably used, and for example, a photosensitive resin composite containing an acrylic resin is preferably used. Note that in this specification and the like, an acrylic resin refers to not only a polymethacrylic acid ester or a methacrylic resin, but also all the acrylic polymer in a broad sense in some cases.

Alternatively, the insulating layer 127 may be formed using an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like. The insulating layer 127 may be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin. A photoresist may be used as the photosensitive organic resin. As the photosensitive organic resin, either a positive-type material or a negative-type material may be used.

The insulating layer 127 may be formed using a material absorbing visible light. When the insulating layer 127 absorbs light emitted from the light-emitting element, light leakage (stray light) from the light-emitting element to the adjacent light-emitting element through the insulating layer 127 can be suppressed. Thus, the display quality of the display device can be improved. Since no polarizing plate is required to improve the display quality of the display device, the weight and thickness of the display device can be reduced.

Examples of the material absorbing visible light include a material containing a pigment of black or any other color, a material containing a dye, a light-absorbing resin material (e.g., polyimide), and a resin material that can be used for color filters (a color filter material). Using a resin material obtained by stacking or mixing color filter materials of two or three or more colors is particularly preferred to enhance the effect of blocking visible light. In particular, mixing color filter materials of three or more colors enables the formation of a black or nearly black resin layer.

### [Display Device 100D]

Light-emitting elements are used as display elements in the above-described example, whereas the following example below shows a liquid crystal display device where liquid crystal elements are used as display elements.

Any of elements with various structures can be used as the liquid crystal elements included in the display device. Typically, a transmissive liquid crystal element employing a vertical alignment (VA) mode, a fringe field switching (FFS) mode, an in-plane switching (IPS) mode, or the like can be used. Instead of a transmissive liquid crystal element, a reflective liquid crystal element or a transflective liquid crystal element may be used as the liquid crystal element. The display device is preferably a normally black liquid crystal display device.

Examples of the VA mode include a multi-domain vertical alignment (MVA) mode, a patterned vertical alignment (PVA) mode, and an advanced super view (ASV) mode.

As the liquid crystal element, a liquid crystal element employing any of a variety of modes can be used. A liquid crystal element can employ, for example, a TN (Twisted Nematic) mode, an ASM (Axially Symmetric aligned Micro-cell) mode, an OCB (Optically Compensated Birefringence) mode, an FLC (Ferroelectric Liquid Crystal) mode, an AFLC (AntiFerroelectric Liquid Crystal) mode, an ECB (Electrically Controlled Birefringence) mode, a guest-host mode, or the like in addition to a VA mode, an FFS mode, and an IPS mode.

Here, the liquid crystal display device is a display device that controls transmission and non-transmission of light by utilizing polarized light and an optical modulation action of a liquid crystal. The optical modulation action of the liquid crystal is controlled by an electric field applied to the liquid crystal (including a horizontal electric field, a vertical electric field, and an oblique electric field). As a liquid crystal that can be used for the liquid crystal element, a thermotropic liquid crystal, a low-molecular liquid crystal, a high-molecular liquid crystal, a polymer dispersed liquid crystal (PDLC), a polymer network liquid crystal (PNLC), a ferroelectric liquid crystal, an anti-ferroelectric liquid crystal, and the like can be used. These liquid crystal materials exhibit a cholesteric phase, a smectic phase, a cubic phase, a chiral nematic phase, an isotropic phase, or the like depending on conditions. As the liquid crystal material, either a positive liquid crystal or a negative liquid crystal may be used, and an appropriate liquid crystal material can be used depending on the mode or design to be used.

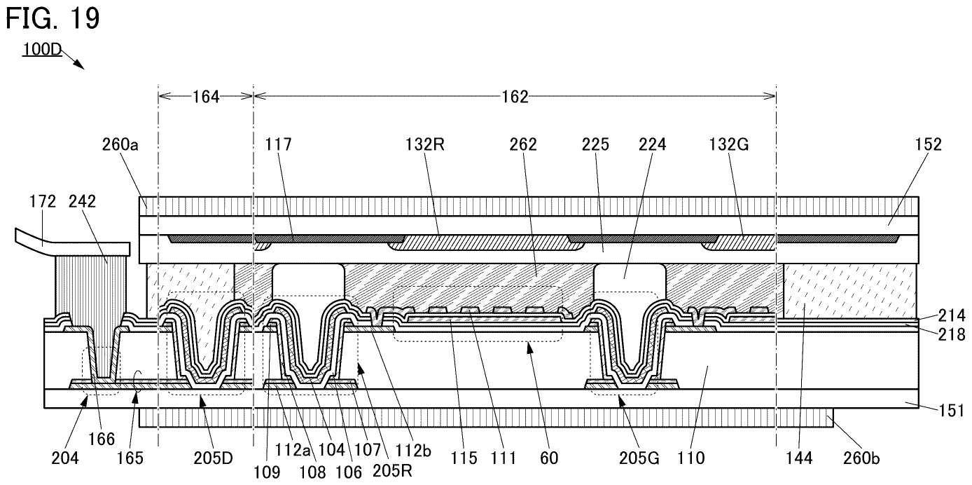

A display device 100D illustrated in FIG. 19 is a liquid crystal display device in an FFS mode.

The substrate 151 and the substrate 152 are bonded to each other with an adhesive layer 144. A liquid crystal 262 is sealed in a region that is surrounded by the substrate 151, the substrate 152, and the adhesive layer 144. A polarizing plate 260a is positioned on the outer surface of the substrate 152, and a polarizing plate 260b is positioned on the outer surface of the substrate 151. Although not illustrated, a backlight can be provided outside the polarizing plate 260a or the polarizing plate 260b.

The substrate 151 is provided with the transistor 205D, the transistor 205R, the transistor 205G, the transistor 205B (not illustrated), the connection portion 204, a spacer 224, and the like. The transistor 205D is provided in the circuit portion 164, and the transistors 205R and 205G are provided in the display portion 162. The conductive layers 112b included in the transistors 205R and 205G are electrically connected to a pixel electrode 111 of a liquid crystal element 60.

The substrate 152 is provided with the coloring layers 132R and 132G, the light-blocking layer 117, an insulating layer 225, and the like.

The transistors 205D, 205R, and 205G each include the conductive layer 112a, the conductive layer 112b, the semiconductor layer 108, the conductive layer 107, the conductive layer 109, the insulating layer 106, the conductive layer 104, and the like. The conductive layer 112a functions as one of a source electrode and a drain electrode and the conductive layer 112b functions as the other. The conductive layer 107 functions as one of a source electrode and a drain electrode and the conductive layer 109 functions as the other. The conductive layer 104 functions as a gate electrode. Part of the insulating layer 106 functions as a gate insulating layer.

The transistors 205D, 205R, and 205G are covered with the insulating layer 218. The insulating layer 218 has a function of a protective layer of the transistors 205D, 205R, and 205G.

A subpixel included in the display portion 162 includes a transistor, the liquid crystal element 60, and a coloring layer. For example, a subpixel that emits red light includes the transistor 205R, the liquid crystal element 60, and the coloring layer 132R that transmits red light. A subpixel that emits green light includes the transistor 205G, the liquid crystal element 60, and the coloring layer 132G that transmits green light. Similarly, although not illustrated, a subpixel that emits blue light includes a transistor, the liquid crystal element 60, and a coloring layer that transmits blue light.

The liquid crystal element 60 includes the common electrode 115, the pixel electrode 111, and the liquid crystal 262. The common electrode 115 is provided over the insulating layer 218, and an insulating layer 214 is provided over the common electrode 115. The pixel electrode 111 is provided over the insulating layer 214.

The pixel electrode 111 and the common electrode 115 transmit visible light. That is, the liquid crystal element 60 can be a transmissive liquid crystal element. For example, in the case where a backlight is provided on the substrate 151 side, light from the backlight which is polarized by the polarizing plate 260b passes through the substrate 151, the liquid crystal element 60, and the substrate 152, and then reaches the polarizing plate 260a. In this case, optical modulation of the light can be controlled by controlling the alignment of the liquid crystal 262 with a voltage applied between the pixel electrode 111 and the common electrode 115. In other words, the intensity of light emitted through the polarizing plate 260a can be controlled. Light other than one in a particular wavelength region of the incident light is absorbed by the coloring layer, and thus, extracted light is red light, for example.

Here, as the polarizing plate 260a, a linear polarizing plate may be used or a circularly polarizing plate can also be used. An example of a circularly polarizing plate is a stack including a linear polarizing plate and a quarter-wave retardation plate. Reflection of external light can be inhibited with a circularly polarizing plate used as the polarizing plate 260a.

Note that in the case where a circularly polarizing plate is used as the polarizing plate 260a, a circularly polarizing plate or a general linear polarizing plate may be used as the polarizing plate 260b. The cell gap, alignment, driving voltage, and the like of the liquid crystal element used as the liquid crystal element 60 are adjusted in accordance with the kinds of polarizing plates used as the polarizing plate 260a and the polarizing plate 260b so that desirable contrast is obtained.

The connection portion 204 is provided in a region near an end portion of the substrate 151. In the connection portion 204, the wiring 165 is electrically connected to the FPC 172 through the conductive layer 166 and the connection layer 242. The wiring 165 is connected to the wiring 165 through an opening provided in the insulating layer 110. In the structure example illustrated in FIG. 19, the wiring 165 is formed using the same material in the same process as the conductive layer 112a and the conductive layer 107, and the conductive layer 166 is formed using the same material in the same process as the conductive layer 112b.

In a plan view, the pixel electrode 111 has a comb-like shape or a shape with a slit. The pixel electrode 111 is provided to overlap with the common electrode 115. There is a portion where the pixel electrode 111 is not provided over the common electrode 115 in a region overlapping with the coloring layer.

Note that in the liquid crystal element 60, both the pixel electrode 111 and the common electrode 115 may have comb-like top-view shapes. Meanwhile, as in the display device 100D, only one of the pixel electrode 111 and the common electrode 115 in the liquid crystal element 60 has a comb-like top-view shape, whereby the pixel electrode 111 and the common electrode 115 partly overlap with each other. This allows capacitance between the pixel electrode 111 and the common electrode 115 to be used as a storage capacitance, and thus another capacitor does not need to be provided. Accordingly, the aperture ratio of the display device can be increased.

The insulating layer 225 is provided on the substrate 152 side to cover the coloring layers 132R and 132G and the light-blocking layer 117. The insulating layer 225 functions as an overcoat that prevents diffusion of components contained in the coloring layers 132R and 132G and the like into the liquid crystal 262. The insulating layer 225 may have a function of a planarization film. The insulating layer 225 can be formed using a light-transmitting organic resin.

Alignment films for controlling the alignment of the liquid crystal 262 may be provided on surfaces of the pixel electrode 111, the insulating layer 214, the insulating layer 225, and the like which are in contact with the liquid crystal 262.

The above is the description of the structure example of the display device.

### Manufacturing Method Example of Display Device

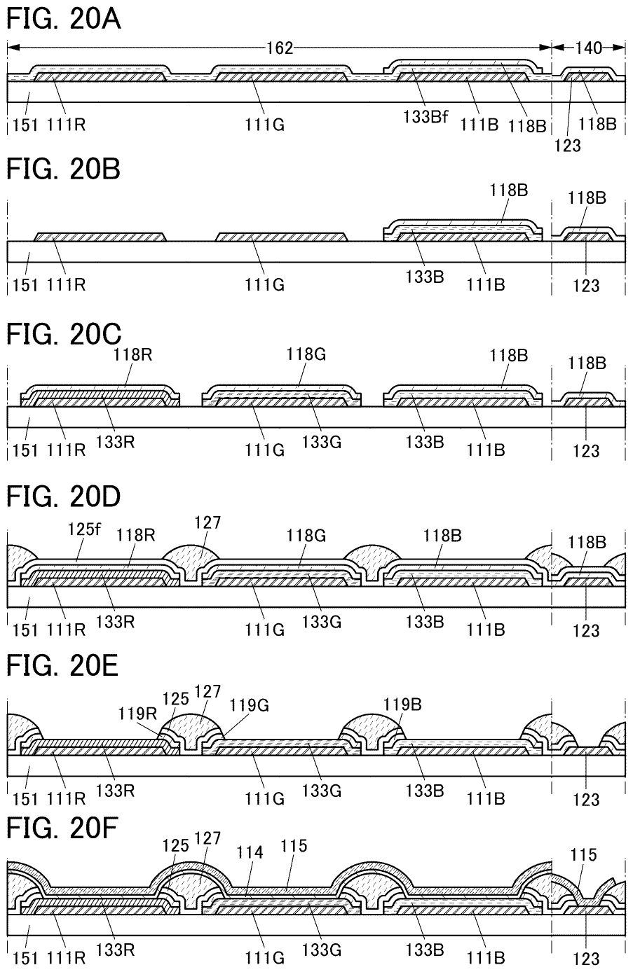

A method for manufacturing a display device having an MML (metal maskless) structure will be described below. Here, processes of manufacturing light-emitting elements without using a fine metal mask will be described in detail. In FIG. 20, cross-sectional views of three light-emitting elements included in the display portion 162 and the connection portion 140 in the manufacturing steps are illustrated.

For manufacture of the light-emitting elements, a vacuum process such as an evaporation method and a solution process such as a spin coating method or an inkjet method can be used. Examples of an evaporation method include physical vapor deposition methods (PVD methods) such as a sputtering method, an ion plating method, an ion beam evaporation method, a molecular beam evaporation method, and a vacuum evaporation method, and a chemical vapor deposition method (CVD method). Specifically, functional layers (e.g., a hole-injection layer, a hole-transport layer, a hole-blocking layer, a light-emitting layer, an electron-blocking layer, an electron-transport layer, an electron-injection layer, and a charge-generation layer) included in the EL layer can be formed by a method such as an evaporation method (e.g., a vacuum evaporation method), a coating method (e.g., a dip coating method, a die coating method, a bar coating method, a spin coating method, or a spray coating method), or a printing method (e.g., an inkjet method, a screen printing (stencil) method, an offset printing (planography) method, a flexography (relief printing) method, a gravure printing method, or a micro-contact printing method).

In the method described below for manufacturing the display device, the island-shaped layer (the layer including the light-emitting layer) is formed not by using a fine metal mask but by forming a light-emitting layer on the entire surface and processing the light-emitting layer by a photolithography method. Accordingly, a high-resolution display device or a display device with a high aperture ratio, which has been difficult to be formed so far, can be obtained. Moreover, light-emitting layers can be formed separately for the respective colors, enabling the display device to perform extremely clear display with high contrast and high display quality. Moreover, providing a sacrificial layer over the light-emitting layer can reduce damage to the light-emitting layer in the manufacturing process of the display device, resulting in an increase in reliability of the light-emitting element.

For example, in the case where the display device includes three kinds of light-emitting elements, which are a light-emitting element that emits blue light, a light-emitting element that emits green light, and a light-emitting element that emits red light, three kinds of island-shaped light-emitting layers can be formed by repeating formation of a light-emitting layer and processing by photolithography three times.

First, the pixel electrodes 111R, 111G, and 111B and the conductive layer 123 are formed over the substrate 151 provided with the transistors 205R, 205G, and 205B (not illustrated) and the like (FIG. 20A).

A conductive film to be the pixel electrodes can be formed by a sputtering method or a vacuum evaporation method, for example. A resist mask is formed over the conductive film by a photolithography process, and then the conductive film is processed, whereby the pixel electrodes 111R, 111G, and 111B and the conductive layer 123 can be formed. For the processing of the conductive film, a wet etching method and/or a dry etching method can be used.

Next, a film 133Bf to be the layer 133B later is formed over the pixel electrodes 111R, 111G, and 111B (FIG. 20A). The film 133Bf (to be the layer 133B later) includes a light-emitting layer that emits blue light.

In an example described in this embodiment, an island-shaped EL layer included in the light-emitting element that emits blue light is formed first, and then island-shaped EL layers included in the light-emitting elements that emit light of the other colors are formed.

In the formation process of the island-shaped EL layers, the pixel electrode of the light-emitting element of the color formed second or later is sometimes damaged by the preceding process. In this case, the driving voltage of the light-emitting element of the color formed second or later might be high.

In view of this, in manufacture of the display device of one embodiment of the present invention, it is preferable that an island-shaped EL layer of a light-emitting element that emits light with the shortest wavelength (e.g., the blue-light-emitting element) be formed first. For example, it is preferable that the island-shaped EL layers be formed for the blue-, green-, and red-light-emitting elements in this order or the blue-, red-, and green-light-emitting elements in this order.

This enables the blue-light-emitting element to keep the favorable state of the interface between the pixel electrode and the EL layer and to be inhibited from having an increased driving voltage. In addition, the blue-light-emitting element can have a longer lifetime and higher reliability. Note that the red-light-emitting element and the green-light-emitting element have a smaller increase in driving voltage or the like than the blue-light-emitting element, resulting in a lower driving voltage and higher reliability of the whole display device.

Note that the formation order of the island-shaped EL layers is not limited to the above; for example, the island-shaped EL layers may be formed for the red-, green-, and blue-light-emitting elements in this order.

As illustrated in FIG. 20A, the film 133Bf is not formed over the conductive layer 123. The film 133Bf can be formed only in a desired region using an area mask, for example. Employing a film formation process using an area mask and a processing process using a resist mask enables a light-emitting element to be manufactured by a relatively easy process.

The heat resistance temperature of the compounds contained in the film 133Bf is preferably higher than or equal to 100° C. and lower than or equal to 180° C., further preferably higher than or equal to 120° C. and lower than or equal to 180° C., still further preferably higher than or equal to 140° C. and lower than or equal to 180° C. Thus, the reliability of the light-emitting element can be increased. In addition, the upper limit of the temperature that can be applied in the manufacturing process of the display device can be increased. Therefore, the range of choices of the materials and the manufacturing method of the display device can be widened, thereby improving the manufacturing yield and the reliability.

Examples of the heat resistance temperature include the glass transition point, the softening point, the melting point, the thermal decomposition temperature, and the 5% weight loss temperature, and the lowest one among the temperatures is preferable.

The film 133Bf can be formed by an evaporation method, specifically a vacuum evaporation method, for example. The film 133Bf may be formed by a transfer method, a printing method, an inkjet method, a coating method, or the like.

Next, a sacrificial layer 118B is formed over the film 133Bf and the conductive layer 123 (FIG. 20A). A resist mask is formed over a film to be the sacrificial layer 118B by a photolithography process, and then the film is processed, whereby the sacrificial layer 118B can be formed.

Providing the sacrificial layer 118B over the film 133Bf can reduce damage to the film 133Bf in the manufacturing process of the display device, resulting in an increase in reliability of the light-emitting element.

The sacrificial layer 118B is preferably provided to cover the end portions of the pixel electrodes 111R, 111G, and 111B. Accordingly, the end portion of the layer 133B formed in a later process is positioned outward from the end portion of the pixel electrode 111B. The entire top surface of the pixel electrode 111B can be used as a light-emitting region, so that the aperture ratio of the pixel can be increased. The end portion of the layer 133B might be damaged in a process after the formation of the layer 133B, and thus is preferably positioned outward from the end portion of the pixel electrode 111B, i.e., not used as the light-emitting region. This can suppress a variation in the characteristics of the light-emitting elements and can improve reliability.

When the layer 133B covers the top surface and side surface of the pixel electrode 111B, the processes after the formation of the layer 133B can be performed without exposing the pixel electrode 111B. When the end portion of the pixel electrode 111B is exposed, corrosion might occur in the etching process or the like. When corrosion of the pixel electrode 111B is inhibited, the yield and characteristics of the light-emitting element can be improved.

The sacrificial layer 118B is preferably provided also at a position overlapping with the conductive layer 123. This can inhibit the conductive layer 123 from being damaged during the manufacturing process of the display device.

As the sacrificial layer 118B, a film that is highly resistant to the process conditions for the film 133Bf, specifically, a film having high etching selectivity with respect to the film 133Bf is used.

The sacrificial layer 118B is formed at a temperature lower than the heat resistance temperature of each compound included in the film 133Bf. The typical substrate temperature in the formation of the sacrificial layer 118B is lower than or equal to 200° C., preferably lower than or equal to 150° C., further preferably lower than or equal to 120° C., still further preferably lower than or equal to 100° C., yet still further preferably lower than or equal to 80° C.

The heat resistance temperature of the compound included in the film 133Bf is preferably high, in which case the film formation temperature of the sacrificial layer 118B can be high. For example, the substrate temperature in formation of the sacrificial layer 118B can be higher than or equal to 100° C., higher than or equal to 120° C., or higher than or equal to 140° C. An inorganic insulating film formed at a higher temperature can be denser and have a better barrier property. Therefore, forming the sacrificial layer at such a temperature can further reduce damage to the film 133Bf and improve the reliability of the light-emitting element.

Note that the same can be applied to the film formation temperature of another layer formed over the film 133Bf (e.g., an insulating film 125f).

The sacrificial layer 118B can be formed by a sputtering method, an ALD method (including a thermal ALD method and a PEALD method), a CVD method, or a vacuum evaporation method, for example. Alternatively, the sacrificial layer 118B may be formed by the above-described wet process.

The sacrificial layer 118B (or a layer that is in contact with the film 133Bf in the case where the sacrificial layer 118B has a stacked-layer structure) is preferably formed by a formation method that causes less damage to the film 133Bf. For example, the sacrificial layer 118B is preferably formed by an ALD method or a vacuum evaporation method rather than a sputtering method.

The sacrificial layer 118B can be processed by a wet etching method or a dry etching method. The sacrificial layer 118B is preferably processed by anisotropic etching.

In the case of employing a wet etching method, damage to the film 133Bf in processing of the sacrificial layer 118B can be reduced as compared to the case of employing a dry etching method. In the case of employing a wet etching method, it is preferable to use a developer, a tetramethylammonium hydroxide (TMAH) aqueous solution, dilute hydrofluoric acid, oxalic acid, phosphoric acid, acetic acid, nitric acid, or a chemical solution containing a mixed solution of two or more of these acids, for example. In the case of employing a wet etching method, a mixed acid chemical solution containing water, phosphoric acid, diluted hydrofluoric acid, and nitric acid may be used. A chemical solution used for the wet etching treatment may be alkaline or acid.

As the sacrificial layer 118B, one or more of a metal film, an alloy film, a metal oxide film, a semiconductor film, an inorganic insulating film, and an organic insulating film can be used, for example.

For the sacrificial layer 118B, a metal material such as gold, silver, platinum, magnesium, nickel, tungsten, chromium, molybdenum, iron, cobalt, copper, palladium, titanium, aluminum, yttrium, zirconium, or tantalum or an alloy material containing the metal material can be used, for example.

The sacrificial layer 118B can be formed using a metal oxide such as In—Ga—Zn oxide, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or indium tin oxide containing silicon.

In addition, in place of gallium described above, the element M (Mis one or more of aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used.

For example, a semiconductor material such as silicon or germanium can be used as a material with excellent compatibility with the semiconductor manufacturing process. Alternatively, an oxide or a nitride of the semiconductor material can be used. Alternatively, a non-metallic material such as carbon or a compound thereof can be used. Alternatively, a metal such as titanium, tantalum, tungsten, chromium, or aluminum, or an alloy containing one or more of these metals can be used. Alternatively, an oxide containing the above-described metal, such as titanium oxide or chromium oxide, or a nitride such as titanium nitride, chromium nitride, or tantalum nitride can be used.

For the sacrificial layer 118B, any of a variety of inorganic insulating films that can be used as the protective layer 131 can be used. In particular, an oxide insulating film is preferable because its adhesion to the film 133Bf is higher than that of a nitride insulating film. For example, an inorganic insulating material such as aluminum oxide, hafnium oxide, or silicon oxide can be used for the sacrificial layer 118B. For the sacrificial layer 118B, an aluminum oxide film can be formed by an ALD method, for example. An ALD method is preferably used, in which case damage to a base (in particular, the film 133Bf) can be reduced.

For example, a stacked-layer structure of an inorganic insulating film (e.g., an aluminum oxide film) formed by an ALD method and an inorganic film (e.g., an In—Ga—Zn oxide film, a silicon film, or a tungsten film) formed by a sputtering method can be employed for the sacrificial layer 118B.

Note that the same inorganic insulating film can be used for both the sacrificial layer 118B and the insulating layer 125 that is to be formed later. For example, an aluminum oxide film formed by an ALD method can be used for both the sacrificial layer 118B and the insulating layer 125. For the sacrificial layer 118B and the insulating layer 125, the same film formation condition may be used or different film formation conditions may be used. For example, when the sacrificial layer 118B is formed under conditions similar to those of the insulating layer 125, the sacrificial layer 118B can be an insulating layer having a high barrier property against at least one of water and oxygen. Meanwhile, since the sacrificial layer 118B is a layer a large part or the whole of which is to be removed in a later process, it is preferable that the processing of the sacrificial layer 118B be easy. Therefore, the sacrificial layer 118B is preferably formed with a substrate temperature lower than that for formation of the insulating layer 125.

An organic material may be used for the sacrificial layer 118B. For example, as the organic material, a material that can be dissolved in a solvent chemically stable with respect to at least the uppermost film of the film 133Bf may be used. Specifically, a material that is dissolved in water or alcohol can be suitably used. In forming a film of such a material, it is preferable to apply the material dissolved in a solvent such as water or alcohol by a wet process and then perform heat treatment for evaporating the solvent. At this time, the heat treatment is preferably performed under a reduced-pressure atmosphere, in which case the solvent can be removed at a low temperature in a short time and thermal damage to the film 133Bf can be accordingly reduced.

The sacrificial layer 118B may be formed using an organic resin such as polyvinyl alcohol (PVA), polyvinyl butyral, polyvinylpyrrolidone, polyethylene glycol, polyglycerin, pullulan, water-soluble cellulose, an alcohol-soluble polyamide resin, or a fluororesin like perfluoropolymer.

For example, a stacked-layer structure of an organic film (e.g., a PVA film) formed by an evaporation method or the above wet process, and an inorganic film (e.g., a silicon nitride film) formed by a sputtering method can be employed for the sacrificial layer 118B.

Note that in the display device of one embodiment of the present invention, part of the sacrificial film remains as the sacrificial layer in some cases.

Then, the film 133Bf is processed using the sacrificial layer 118B as a hard mask, so that the layer 133B is formed (FIG. 20B).

Accordingly, as illustrated in FIG. 20B, the stacked-layer structure of the layer 133B and the sacrificial layer 118B remains over the pixel electrode 111B. In addition, the pixel electrode 111R and the pixel electrode 111G are exposed. In a region corresponding to the connection portion 140, the sacrificial layer 118B remains over the conductive layer 123.

The film 133Bf is preferably processed by anisotropic etching. Anisotropic dry etching is particularly preferable. Alternatively, wet etching may be employed.

After that, steps similar to the formation step of the film 133Bf, the formation step of the sacrificial layer 118B, and the formation step of the layer 133B are repeated twice under the condition where at least light-emitting substances are changed, whereby a stacked-layer structure of the layer 133R and a sacrificial layer 118R is formed over the pixel electrode 111R and a stacked-layer structure of the layer 133G and a sacrificial layer 118G is formed over the pixel electrode 111G (FIG. 20C). Specifically, the layer 133R is formed to include a light-emitting layer that emits red light, and the layer 133G is formed to include a light-emitting layer that emits green light. The sacrificial layers 118R and 118G can be formed using a material that can be used for the sacrificial layer 118B. The sacrificial layers 118R and 118G may be formed using the same material or different materials.

Note that the side surfaces of the layer 133B, the layer 133G, and the layer 133R are preferably perpendicular or substantially perpendicular to their formation surfaces. For example, the angle between the formation surfaces and these side surfaces is preferably greater than or equal to 60° and less than or equal to 90°.

As described above, the distance between two adjacent layers among the layer 133B, the layer 133G, and the layer 133R formed by a photolithography method can be shortened to less than or equal to 8 μm, less than or equal to 5 μm, less than or equal to 3 μm, less than or equal to 2 μm, or less than or equal to 1 μm. Here, the distance can be determined by, for example, the distance between opposite end portions of two adjacent layers among the layer 133B, the layer 133G, and the layer 133R. When the distance between the island-shaped EL layers is shortened in this manner, a high-resolution display device with a high aperture ratio can be provided.

Next, the insulating film 125f to be the insulating layer 125 later is formed to cover the pixel electrodes, the layer 133B, the layer 133G, the layer 133R, the sacrificial layer 118B, the sacrificial layer 118G, and the sacrificial layer 118R, and then the insulating layer 127 is formed over the insulating film 125f (FIG. 20D).

The insulating film 125f is preferably formed to have a thickness greater than or equal to 3 nm, greater than or equal to 5 nm, or greater than or equal to 10 nm, and less than or equal to 200 nm, less than or equal to 150 nm, less than or equal to 100 nm, or less than or equal to 50 nm.

The insulating film 125f is preferably formed by an ALD method, for example. An ALD method is preferably used, in which case damage during film formation is reduced and a film with good coverage can be formed. As the insulating film 125f, an aluminum oxide film is preferably formed by an ALD method, for example.

Alternatively, the insulating film 125f may be formed by a sputtering method, a CVD method, or a plasma CVD method that provides a higher film formation rate than an ALD method. In this case, a highly reliable display device can be manufactured with high productivity.

For example, the insulating film to be the insulating layer 127 is preferably formed by the aforementioned wet process (e.g., spin coating) using a photosensitive resin composite containing an acrylic resin. After the formation, heat treatment (also referred to as pre-baking) is preferably performed to eliminate a solvent contained in the insulating film. Next, part of the insulating film is irradiated with visible light or ultraviolet rays as light exposure. Next, the region of the insulating film exposed to light is removed by development. Then, heat treatment (also referred to as post-baking) is performed. Accordingly, the insulating layer 127 illustrated in FIG. 20D can be formed. Note that the shape of the insulating layer 127 is not limited to the shape illustrated in FIG. 20D. For example, the top surface of the insulating layer 127 can include one or more of a convex surface, a concave surface, and a flat surface. The insulating layer 127 may cover the side surface of an end portion of at least one of the insulating layer 125, the sacrificial layer 118B, the sacrificial layer 118G, and the sacrificial layer 118R.

Next, as illustrated in FIG. 20E, etching treatment is performed using the insulating layer 127 as a mask to remove the insulating film 125f and parts of the sacrificial layers 118B, 118G, and 118R. Consequently, openings are formed in the sacrificial layers 118B, 118G, and 118R, and the top surfaces of the layer 133G, the layer 133G, the layer 133R, and the conductive layer 123 are exposed. Note that portions of the sacrificial layers 118B, 118G, and 118R may remain in positions overlapping with the insulating layer 127 and the insulating layer 125 (see sacrificial layers 119B, 119G, and 119R).

The etching treatment can be performed by dry etching or wet etching. Note that the insulating film 125f is preferably formed using a material similar to that for the sacrificial layers 118B, 118G, and 118R, in which case etching treatment can be performed collectively.

As described above, by providing the insulating layer 127, the insulating layer 125, the sacrificial layer 118B, the sacrificial layer 118G, and the sacrificial layer 118R, poor connection due to a disconnected portion and an increase in electric resistance due to a locally thinned portion can be inhibited from occurring in the common layer 114 and the common electrode 115 between the light-emitting elements. Thus, the display device of one embodiment of the present invention can have improved display quality.

Next, the common layer 114 and the common electrode 115 are formed in this order over the insulating layer 127, the layer 133B, the layer 133G, and the layer 133R (FIG. 20F).

The common layer 114 can be formed by an evaporation method (including a vacuum evaporation method), a transfer method, a printing method, an inkjet method, a coating method, or the like.

The common electrode 115 can be formed by a sputtering method or a vacuum evaporation method, for example. Alternatively, a film formed by an evaporation method and a film formed by a sputtering method may be stacked.

As described above, in the method for manufacturing the display device of one embodiment of the present invention, the island-shaped layer 133B, the island-shaped layer 133G, and the island-shaped layer 133R are formed not by using a fine metal mask but by forming a film on the entire surface and processing the film; thus, the island-shaped layers can be formed to have a uniform thickness. Consequently, a high-resolution display device or a display device with a high aperture ratio can be obtained. Furthermore, even when the resolution or the aperture ratio is high and the distance between the subpixels is extremely short, the layer 133B, the layer 133G, and the layer 133R can be inhibited from being in contact with each other in the adjacent subpixels. As a result, generation of a leakage current between the subpixels can be inhibited. This can prevent crosstalk due to unintended light emission, so that a display apparatus with extremely high contrast can be obtained.

The insulating layer 127 having a tapered end portion and being provided between adjacent island-shaped EL layers can prevent step disconnection and a locally thinned portion to be formed in the common electrode 115 at the time of forming the common electrode 115. Thus, poor connection due to a disconnected portion and an increase in electric resistance due to a locally thinned portion can be inhibited from occurring in the common layer 114 and the common electrode 115. Hence, the display device of one embodiment of the present invention achieves both high resolution and high display quality.

The above is the description of the example of the method for manufacturing the display device.

At least part of this embodiment can be implemented in combination with the other embodiments described in this specification as appropriate.

### Embodiment 4

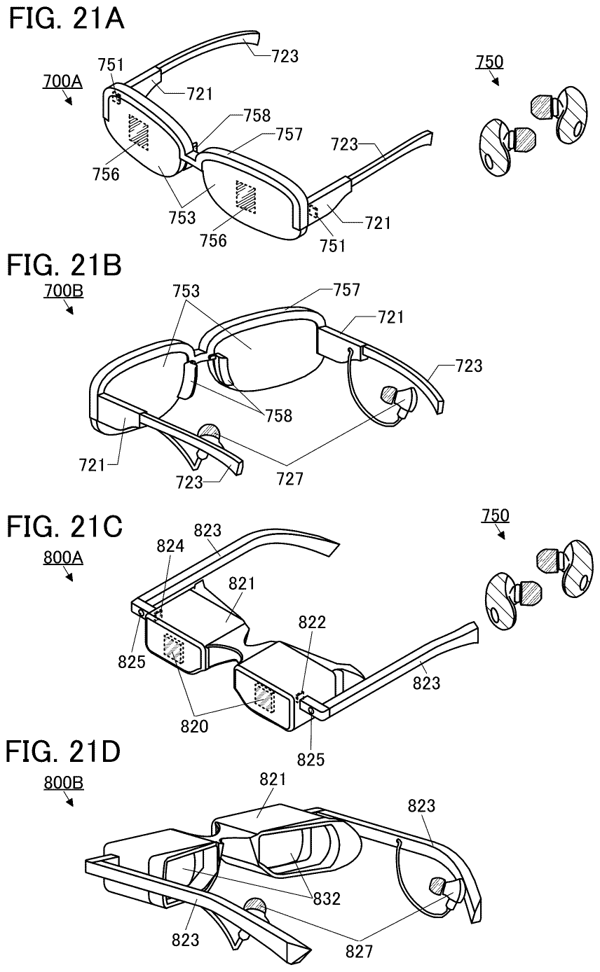

In this embodiment, electronic devices of one embodiment of the present invention will be described with reference to FIG. 21 to FIG. 23.

Electronic devices in this embodiment each include the display device of one embodiment of the present invention in a display portion. The display device of one embodiment of the present invention can be easily increased in resolution and definition. Thus, the display device of one embodiment of the present invention can be used for a display portion of a variety of electronic devices.

A semiconductor device of one embodiment of the present invention can also be applied to any other portion of an electronic device than a display portion. For example, the semiconductor device of one embodiment of the present invention is preferably used for a control portion or the like of an electronic device to enable lower power consumption.

Examples of the electronic devices include a digital camera, a digital video camera, a digital photo frame, a mobile phone, a portable game console, a portable information terminal, and an audio reproducing device, in addition to electronic devices with a relatively large screen, such as a television device, desktop and laptop personal computers, a monitor of a computer and the like, digital signage, and a large game machine such as a pachinko machine.

In particular, the display device of one embodiment of the present invention can have a high resolution, and thus can be favorably used for an electronic device having a relatively small display portion. Examples of such an electronic device include watch-type and bracelet-type information terminal devices (wearable devices) and wearable devices capable of being worn on a head, such as a VR device like a head-mounted display, a glasses-type AR device, and an MR device.

The definition of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, a definition of 4K, 8K, or higher is preferable. The pixel density (resolution) of the display device of one embodiment of the present invention is preferably 100 ppi or higher, further preferably 300 ppi or higher, still further preferably 500 ppi or higher, yet still further preferably 1000 ppi or higher, yet still further preferably 2000 ppi or higher, yet still further preferably 3000 ppi or higher, yet still further preferably 5000 ppi or higher, yet still further preferably 7000 ppi or higher. The use of the display device having one or both of such high definition and high resolution can further increase realistic sensation, sense of depth, and the like. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device in this embodiment can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of wearable devices that can be worn on a head are described using FIG. 21A to FIG. 21D. The wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables the user to feel a higher level of immersion.

An electronic device 700A illustrated in FIG. 21A and an electronic device 700B illustrated in FIG. 21B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used for the display panels 751. Thus, the electronic devices are capable of performing ultrahigh-resolution display.

The electronic device 700A and the electronic device 700B can each project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic device 700A and the electronic device 700B are electronic devices capable of AR display.

In the electronic device 700A and the electronic device 700B, a camera capable of capturing images of the front side may be provided as the image capturing portion. Furthermore, when the electronic device 700A and the electronic device 700B are provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Instead of or in addition to the wireless communication device, a connector that can be connected to a cable for supplying a video signal and a power supply potential may be provided.

The electronic device 700A and the electronic device 700B are each provided with a battery so that they can be charged wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables various types of processing. For example, a video can be paused or restarted by a tap operation, and can be fast-forwarded or fast-reversed by a slide operation. When the touch sensor module is provided in each of the two housings 721, the range of the operation can be increased.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion element can be used as a light-receiving element. One or both of an inorganic semiconductor and an organic semiconductor can be used for an active layer of the photoelectric conversion element.

An electronic device 800A illustrated in FIG. 21C and an electronic device 800B illustrated in FIG. 21D each include a pair of display portions 820, a housing 821, a communication portion 822, a pair of wearing portions 823, a control portion 824, a pair of image capturing portions 825, and a pair of lenses 832.

The display device of one embodiment of the present invention can be used in the display portions 820. Thus, the electronic devices are capable of performing ultrahigh-resolution display. Such electronic devices provide a high sense of immersion to the user.

The display portions 820 are positioned inside the housing 821 so as to be seen through the lenses 832. When the pair of display portions 820 display different images, three-dimensional display using parallax can be performed.

Each of the electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B each preferably include a mechanism for adjusting the lateral positions of the lenses 832 and the display portions 820 so that the lenses 832 and the display portions 820 are positioned optimally in accordance with the positions of the user's eyes. In addition, a mechanism for adjusting focus by changing the distance between the lenses 832 and the display portions 820 is preferably included.

The electronic device 800A or the electronic device 800B can be mounted on the user's head with the wearing portions 823. FIG. 21C and the like illustrate examples where the wearing portion has a shape like a temple of glasses; however, one embodiment of the present invention is not limited thereto. The wearing portion 823 may have any shape with which the user can wear the electronic device, such as a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Note that although an example where the image capturing portion 825 is included is illustrated here, a range sensor that is capable of measuring the distance to an object (hereinafter such a sensor is also referred to as a sensing portion) is provided. In other words, the image capturing portion 825 is one embodiment of the sensing portion. For the sensing portion, an image sensor or a distance image sensor such as LIDAR (Light Detection and Ranging) can be used, for example. By using images obtained by a camera and images obtained by the distance image sensor, more pieces of information can be obtained and a gesture operation with higher accuracy is possible.

The electronic device 800A may include a vibration mechanism that functions as a bone-conduction earphone. For example, at least one of the display portion 820, the housing 821, and the wearing portion 823 can include the vibration mechanism. Thus, without additionally requiring an audio device such as headphones, earphones, or a speaker, the user can enjoy images and sound only by wearing the electronic device 800A.

The electronic device 800A and the electronic device 800B may each include an input terminal. To the input terminal, a cable for supplying a video signal from a video output device or the like, power for charging the battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A illustrated in FIG. 21A has a function of transmitting information to the earphones 750 with the wireless communication function. As another example, the electronic device 800A illustrated in FIG. 21C has a function of transmitting information to the earphones 750 with the wireless communication function.

The electronic device may include an earphone portion. The electronic device 700B illustrated in FIG. 21B includes earphone portions 727. For example, the earphone portion 727 can be connected to the control portion by wire. Part of a wiring that connects the earphone portion 727 and the control portion may be positioned inside the housing 721 or the wearing portion 723.

Similarly, the electronic device 800B illustrated in FIG. 21D includes earphone portions 827. For example, the earphone portion 827 can be connected to the control portion 824 by wire. Part of a wiring that connects the earphone portion 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of a headset by including the audio input mechanism.

As described above, both the glasses-type device (the electronic device 700A, the electronic device 700B, or the like) and the goggles-type device (the electronic device 800A, the electronic device 800B, or the like) are suitable as the electronic device of one embodiment of the present invention.

The electronic device of one embodiment of the present invention can transmit information to earphones by wire or wirelessly.

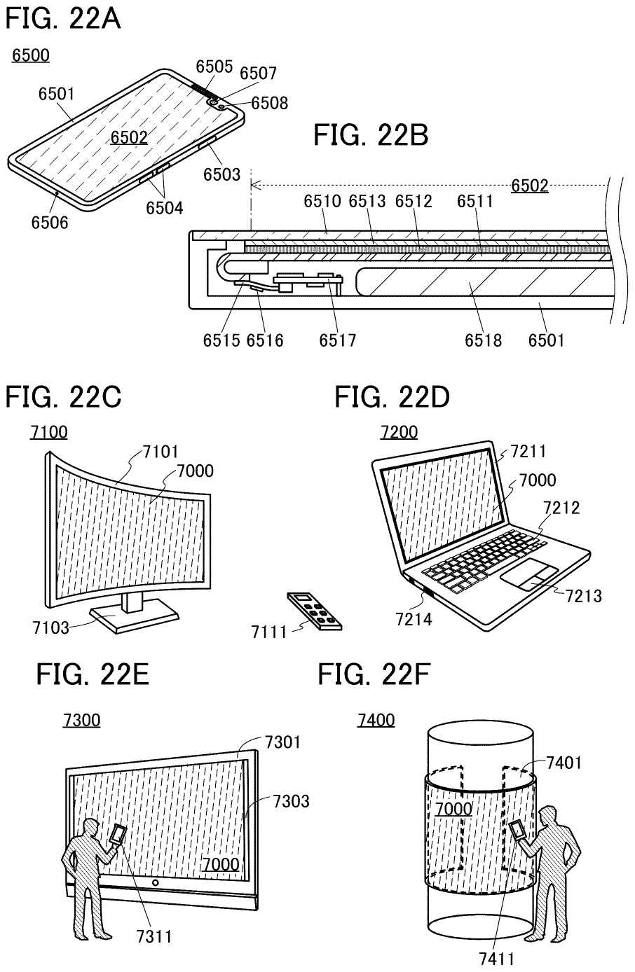

An electronic device 6500 illustrated in FIG. 22A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502.

FIG. 22B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. In that case, an extremely lightweight electronic device can be obtained. Since the display panel 6511 is extremely thin, the battery 6518 with high capacity can be mounted without an increase in the thickness of the electronic device. Moreover, part of the display panel 6511 is folded back so that a connection portion with the FPC 6515 is provided on the back side of the pixel portion, whereby an electronic device with a narrow bezel can be obtained.

FIG. 22C illustrates an example of a television device. In a television device 7100, a display portion 7000 is incorporated in a housing 7101. Here, the housing 7101 is supported by a stand 7103.

The display device of one embodiment of the present invention can be used in the display portion 7000.

Operations of the television device 7100 illustrated in FIG. 22C can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may be provided with a display portion for displaying information output from the remote control 7111. With operation keys or a touch panel provided in the remote control 7111, channels and volume can be controlled and videos displayed on the display portion 7000 can be controlled.

Note that the television device 7100 includes a receiver, a modem, and the like. A general television broadcast can be received with the receiver. When the television device is connected to a communication network by wire or wirelessly via the modem, one-way (from a transmitter to a receiver) or two-way (between a transmitter and a receiver or between receivers, for example) data communication can be performed.

FIG. 22D illustrates an example of a laptop personal computer. A laptop personal computer 7200 includes a housing 7211, a keyboard 7212, a pointing device 7213, an external connection port 7214, and the like. The display portion 7000 is incorporated in the housing 7211.

The display device of one embodiment of the present invention can be used in the display portion 7000.

FIG. 22E and FIG. 22F illustrate examples of digital signage.

Digital signage 7300 illustrated in FIG. 22E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 22F is digital signage 7400 attached to a cylindrical pillar 7401. The digital signage 7400 includes the display portion 7000 provided along a curved surface of the pillar 7401.

The display device of one embodiment of the present invention can be used for the display portion 7000 in each of FIG. 22E and FIG. 22F.

A larger area of the display portion 7000 can increase the amount of information that can be provided at a time. The larger display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 22E and FIG. 22F, it is preferable that the digital signage 7300 or the digital signage 7400 can work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

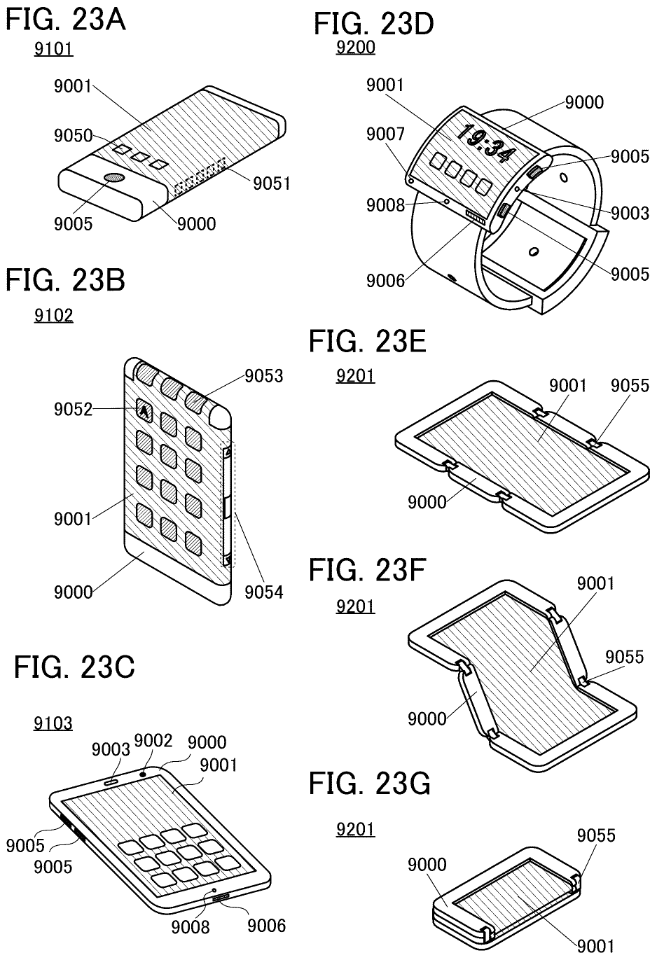

Electronic devices illustrated in FIG. 23A to FIG. 23G each include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, a position, speed, acceleration, angular velocity, rotational frequency, distance, light, liquid, magnetism, temperature, a chemical substance, sound, time, hardness, an electric field, current, voltage, power, radiation, flow rate, humidity, a gradient, oscillation, odor, or infrared rays), a microphone 9008, and the like.

The display device of one embodiment of the present invention can be used for the display portion 9001 in FIG. 23A to FIG. 23G.

The electronic devices illustrated in FIG. 23A to FIG. 23G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may include a plurality of display portions. The electronic devices may be provided with a camera or the like and have a function of capturing a still image or a moving image, a function of storing the captured image in a storage medium (an external storage medium or a storage medium incorporated in the camera), a function of displaying the captured image on the display portion, and the like.

The electronic devices illustrated in FIG. 23A to FIG. 23G are described in detail below.

FIG. 23A is a perspective view illustrating a portable information terminal 9101. The portable information terminal 9101 can be used as a smartphone, for example. The portable information terminal 9101 may include the speaker 9003, the connection terminal 9006, the sensor 9007, or the like. The portable information terminal 9101 can display text and image information on its plurality of surfaces. FIG. 23A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 23B is a perspective view illustrating a portable information terminal 9102. The portable information terminal 9102 has a function of displaying information on three or more surfaces of the display portion 9001. Here, information 9052, information 9053, and information 9054 are displayed on different surfaces. For example, the user of the portable information terminal 9102 can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 23C is a perspective view illustrating a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 23D is a perspective view illustrating a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIG. 23E to FIG. 23G are perspective views illustrating a foldable portable information terminal 9201. In addition, FIG. 23E is a perspective view of an opened state of the portable information terminal 9201, FIG. 23G is a perspective view of a folded state thereof, and FIG. 23F is a perspective view of a state in the middle of change from one of FIG. 23E and FIG. 23G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

At least part of this embodiment can be implemented in combination with the other embodiments described in this specification as appropriate.

### REFERENCE NUMERALS

10: transistor, 10a: transistor, 10b: transistor, 10c: transistor, 10d: transistor, 10e: transistor, 10f: transistor, 10g: transistor, 10h: transistor, 11: insulating layer, 15: transistor, 20a: opening, 20b: opening, 20c: opening, 20d: opening, 20e: opening, 21: semiconductor layer, 22: insulating layer, 23: conductive layer, 24: conductive layer, 25: conductive layer, 32: conductive layer, 41: insulating layer, 41a: insulating layer, 41b: insulating layer, 41c: insulating layer, 42: insulating layer, 44: insulating layer, 45: insulating layer, 46: insulating layer, 50: transistor, 50a: transistor, 50b: transistor, 50c: transistor, 50d: transistor, 50e: transistor

1. (canceled)

2. A semiconductor device comprising:
a base insulating layer;
a first conductive layer over the base insulating layer;
a first insulating layer over the first conductive layer, the first insulating layer comprising a first opening;
a second conductive layer over the first insulating layer;
a semiconductor layer in contact with the first conductive layer, the second conductive layer, and a side surface of the first insulating layer inside the first opening, the semiconductor layer comprising a channel of a transistor;
a second insulating layer covering the semiconductor layer in the first opening; and
a third conductive layer covering the second insulating layer in the first opening,
wherein the first conductive layer comprises a second opening,
wherein the semiconductor layer comprises a third opening,
wherein each of the second opening and the third opening is inside the first opening in a plan view, and
wherein the second insulating layer is in contact with the base insulating layer in a region overlapping with the second opening and the third opening.

3. The semiconductor device according to claim 2,
wherein the second opening is smaller than the third opening,
wherein the second opening is inside the third opening in the plan view, and
wherein the second insulating layer is in contact with a top surface of the first conductive layer and a side surface of the first conductive layer in the second opening.

4. The semiconductor device according to claim 2,
wherein the third opening is smaller than the second opening,
wherein the third opening is inside the second opening in the plan view, and
wherein the semiconductor layer is in contact with a top surface of the first conductive layer, a side surface of the first conductive layer in the second opening, and the base insulating layer.

5. A semiconductor device comprising:
a first conductive layer;
a first insulating layer over the first conductive layer, the first insulating layer comprising a first opening;
a second conductive layer over the first insulating layer;
a semiconductor layer in contact with the first conductive layer, the second conductive layer, and a side surface of the first insulating layer inside the first opening, the semiconductor layer comprising a channel of a transistor;
a second insulating layer covering the semiconductor layer in the first opening; and
a third conductive layer covering the second insulating layer in the first opening,
wherein the third conductive layer comprises a second opening, and
wherein the second opening is inside the first opening in a plan view.

6. The semiconductor device according to claim 5,
wherein an angle formed between the side surface of the first insulating layer in the first opening and a bottom surface of the first insulating layer is greater than or equal to 75° and less than or equal to 90°.

7. The semiconductor device according to claim 5,
wherein the semiconductor layer comprises a metal oxide,
wherein the first insulating layer has a stacked-layer structure in which a first insulating film, a second insulating film, and a third insulating film are stacked in this order,
wherein the first insulating film and the third insulating film each comprise a nitride, and
wherein the second insulating film comprises an oxide.

8. The semiconductor device according to claim 7,
wherein the first insulating film and the third insulating film each comprise silicon nitride, and
wherein the second insulating film comprises silicon oxide.

9. The semiconductor device according to claim 5, further comprising a third insulating layer over the second conductive layer,
wherein the third conductive layer comprises a portion overlapping with the second conductive layer with the third insulating layer therebetween.

10. The semiconductor device according to claim 9, further comprising a fourth conductive layer over the third insulating layer,
wherein the fourth conductive layer is electrically connected to the third conductive layer and is configured as a wiring.
